(19) United States
(12) Patent Application Publication
(10) Pub. No.: US 2021/0242207 A1
(43) Pub. Date: Aug. 5, 2021

(54) SEMICONDUCTOR DEVICE AND METHOD FOR MANUFACTURING THE SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Daigo ITO, Isehara (JP); Ryota HODO, Atsugi (JP); Yoshinori ANDO, Atsugi (JP); Tetsuya KAKEHATA, Isehara (JP)

(21) Appl. No.: 17/052,589

(22) PCT Filed: May 8, 2019
(86) PCT No.: PCT/IB2019/053757

§ 371 Date: Nov. 3, 2020

(30) Foreign Application Priority Data
May 18, 2018 (JP) 2018-095850
May 18, 2018 (JP) 2018-095917

(51) Int. Cl. H01L 27/108

(52) U.S. Cl. CPC H01L 27/10805; H01L 27/10847

(57) ABSTRACT

A semiconductor device that can be miniaturized or highly integrated is provided.

A first conductor to a fourth conductor, a first insulator and a second insulator, and a first oxide and a second oxide are included, the first insulator is positioned over the first conductor, the first oxide is positioned over the first insulator, a first opening that reaches the first conductor is provided in the first insulator and the first oxide, the second conductor and the third conductor isolated from each other are positioned over the first oxide, at least part of the third conductor overlaps with the first opening and is in contact with a top surface of the first conductor, the second oxide is positioned over the first oxide so as to at least partly overlap with a region between the second conductor and the third conductor, the second insulator is positioned over the second oxide, and the fourth conductor is positioned over the second insulator.

### TECHNICAL FIELD

One embodiment of the present invention relates to a semiconductor device and a method for manufacturing the semiconductor device. Another embodiment of the present invention relates to a semiconductor wafer, a module, and an electronic device.

Note that in this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

Note that one embodiment of the present invention is not limited to the above technical field. One embodiment of the invention disclosed in this specification and the like relates to an object, a method, or a manufacturing method. Another embodiment of the present invention relates to a process, a machine, manufacture, or a composition of matter.

### BACKGROUND ART

A silicon-based semiconductor material is widely known as a semiconductor thin film that can be used in a transistor, and as another material, an oxide semiconductor has attracted attention. As the oxide semiconductor, not only single-component metal oxides, such as indium oxide and zinc oxide, but also multi-component metal oxides are known. Among the multi-component metal oxides, in particular, an In—Ga—Zn oxide (hereinafter also referred to as IGZO) has been actively studied.

From the studies on IGZO, a CAAC (c-axis aligned crystalline) structure and an nc (nanocrystalline) structure, which are not single crystal nor amorphous, have been found in an oxide semiconductor (see Non-Patent Document 1 to Non-Patent Document 3). In Non-Patent Document 1 and Non-Patent Document 2, a technique for manufacturing a transistor using an oxide semiconductor having a CAAC structure is also disclosed. Moreover, Non-Patent Document 4 and Non-Patent Document 5 show that a fine crystal is included even in an oxide semiconductor which has lower crystallinity than an oxide semiconductor having the CAAC structure or the nc structure.

In addition, a transistor that uses IGZO for an active layer has an extremely low off-state current (see Non-Patent Document 6), and an LSI and a display utilizing the characteristics have been reported (see Non-Patent Document 7 and Non-Patent Document 8).

### REFERENCES

### Non-Patent Documents

[Non-Patent Document 1] S. Yamazaki et al., “SID Symposium Digest of Technical Papers”, 2012, volume 43, issue 1, pp. 183-186.
[Non-Patent Document 2] S. Yamazaki et al., “Japanese Journal of Applied Physics”, 2014, volume 53, Number 4S, pp. 04ED18-1-04ED18-10.
[Non-Patent Document 3] S. Ito et al., “The Proceedings of AM-FPD'13 Digest of Technical Papers”, 2013, pp. 151-154.
[Non-Patent Document 4] S. Yamazaki et al., “ECS Journal of Solid State Science and Technology”, 2014, volume 3, issue 9, pp. Q3012-Q3022.
[Non-Patent Document 5] S. Yamazaki, “ECS Transactions”, 2014, volume 64, issue 10, pp. 155-164.
[Non-Patent Document 6] K. Kato et al., “Japanese Journal of Applied Physics”, 2012, volume 51, pp. 021201-1-021201-7.
[Non-Patent Document 7] S. Matsuda et al., “2015 Symposium on VLSI Technology Digest of Technical Papers”, 2015, pp. T216-T217.
[Non-Patent Document 8] S. Amano et al., “SID Symposium Digest of Technical Papers”, 2010, volume 41, issue 1, pp. 626-629.

### SUMMARY OF THE INVENTIONS

### Problems to be Solved by the Invention

An object of one embodiment of the present invention is to provide a semiconductor device that can be miniaturized or highly integrated. Alternatively, an object of one embodiment of the present invention is to provide a semiconductor device having favorable electrical characteristics. Alternatively, an object of one embodiment of the present invention is to provide a semiconductor device having a high on-state current. Alternatively, an object of one embodiment of the present invention is to provide a semiconductor device having excellent frequency characteristics. Alternatively, an object of one embodiment of the present invention is to provide a semiconductor device having favorable reliability. Alternatively, an object of one embodiment of the present invention is to provide a semiconductor device having high productivity.

An object of one embodiment of the present invention is to provide a semiconductor device capable of retaining data for a long time. An object of one embodiment of the present invention is to provide a semiconductor device capable of high-speed data writing. An object of one embodiment of the present invention is to provide a semiconductor device having high design flexibility. An object of one embodiment of the present invention is to provide a semiconductor device in which power consumption can be reduced. An object of one embodiment of the present invention is to provide a novel semiconductor device.

Note that the description of these objects does not preclude the existence of other objects. Note that one embodiment of the present invention does not necessarily achieve all of these objects. Objects other than these will be apparent from the description of the specification, the drawings, the claims, and the like, and objects other than these can be derived from the description of the specification, the drawings, the claims, and the like.

### Means for Solving the Problems

One embodiment of the present invention is a semiconductor device including a first conductor to a fourth conductor, a first insulator and a second insulator, and a first oxide and a second oxide, in which the first insulator is positioned over the first conductor, the first oxide is positioned over the first insulator, a first opening that reaches the first conductor is provided in the first insulator and the first oxide, the second conductor and the third conductor isolated from each other are positioned over the first oxide, at least part of the third conductor overlaps with the first opening and is in contact with a top surface of the first conductor, the second oxide is positioned over the first oxide so as to at least partly overlap with a region between the second conductor and the third conductor, the second insulator is positioned over the second oxide, and the fourth conductor is positioned over the second insulator.

Another embodiment of the present invention is a semiconductor device including a first conductor to a fifth conductor, a first insulator and a second insulator, and a first oxide and a second oxide, in which the first insulator is positioned over the first conductor, the first oxide is positioned over the first insulator, a first opening that reaches the first conductor is provided in the first insulator and the first oxide, the second conductor and the third conductor isolated from each other are positioned over the first oxide, at least part of the third conductor overlaps with the first opening and is in contact with a top surface of the first conductor, the second oxide is positioned over the first oxide so as to at least partly overlap with a region between the second conductor and the third conductor, the second insulator is positioned over the second oxide, the fourth conductor is positioned over the second insulator, and the fifth conductor is positioned over the third conductor so as to at least partly overlap with the first opening and the first conductor.

In the above, a third insulator, which is positioned over the first insulator, the second conductor, and the third conductor, and a fourth insulator, which is positioned in contact with a top surface of the third insulator, a top surface of the second oxide, a top surface of the second insulator, and atop surface of the fourth conductor, may be further included; and the second oxide, the second insulator, and the fourth conductor are preferably positioned between the second conductor and the third conductor.

In the above, the third conductor is preferably in contact with a side surface of the first oxide in the first opening. In the above, the thickness of the third conductor in a portion in contact with the side surface of the first oxide may be smaller than the thickness of the third conductor in a portion in contact with a top surface of the first oxide. In the above, a top surface of the fifth conductor is preferably substantially level with a top surface of the third conductor.

In the above, a fifth insulator positioned between the third insulator and the second conductor and between the third insulator and the third conductor may be further included. In the above, a second opening that overlaps with the first opening may be provided in the third insulator and the fifth insulator, and the fifth conductor may be positioned so as to fill the first opening and the second opening.

In the above, the fifth conductor is preferably a stacked-layer film of titanium nitride and tungsten over the titanium nitride.

In the above, a sixth conductor positioned below the first insulator so as to at least partly overlap with the fourth conductor may be further included.

In the above, it is preferable that the second conductor and the third conductor be not in contact with the side surface of the first oxide except in the first opening.

In the above, the first oxide and the second oxide preferably contain In, an element M (M is A1, Ga, Y, or Sn), and Zn.

In the above, a capacitor may be provided below the first conductor, and one electrode of the capacitor is preferably electrically connected to the first conductor.

In the above, a transistor formed in a silicon substrate may be provided below the capacitor.

Another embodiment of the present invention is a method for manufacturing a semiconductor device including a first conductor to a fourth conductor, a first insulator to a third insulator, and a first oxide and a second oxide; in the method for manufacturing a semiconductor device, the first conductor is formed, the first insulator and a first oxide film are deposited over the first conductor in this order, a first opening that reaches the first conductor is formed in the first insulator and the first oxide film, a first conductive film is deposited over the first oxide film by a sputtering method, the first oxide film and the first conductive film are processed into island shapes to form the first oxide and an island-shaped first conductive film, the third insulator is deposited over the first insulator, the first oxide, and the island-shaped first conductive film, a second opening that reaches the island-shaped first conductive film is formed in the third insulator, a region of the island-shaped first conductive film overlapping with the second opening is removed to form the second conductor and the third conductor, a second oxide film, a first insulating film, and a third conductive film are deposited over the first oxide and the third insulator in this order, and part of the second oxide film, part of the first insulating film, and part of the third conductive film are removed until a top surface of the third insulator is exposed to form the second oxide, the second insulator, and the fourth conductor.

Another embodiment of the present invention is a method for manufacturing a semiconductor device including a first conductor to a fifth conductor, a first insulator to a third insulator, and a first oxide and a second oxide; in the method for manufacturing a semiconductor device, the first conductor is formed, the first insulator and a first oxide film are deposited over the first conductor in this order, a first opening that reaches the first conductor is formed in the first insulator and the first oxide film, a first conductive film is deposited over the first oxide film by a sputtering method, a second conductive film is deposited over the first conductive film by an ALD method or a CVD method, part of the second conductive film is removed until a top surface of the first conductive film is exposed to form the fifth conductor, the first oxide film and the first conductive film are processed into island shapes to form the first oxide and an island-shaped first conductive film, the third insulator is deposited over the first insulator, the first oxide, and the island-shaped first conductive film, a second opening that reaches the island-shaped first conductive film is formed in the third insulator, a region of the island-shaped first conductive film overlapping with the second opening is removed to form the second conductor and the third conductor, a second oxide film, a first insulating film, and a third conductive film are deposited over the first oxide and the third insulator in this order, and part of the second oxide film, part of the first insulating film, and part of the third conductive film are removed until a top surface of the third insulator is exposed to form the second oxide, the second insulator, and the fourth conductor.

In the above, the second conductive film is preferably formed by depositing titanium nitride by an ALD method and then depositing tungsten by a CVD method. In the above, dry etching treatment is preferably performed and then CMP (Chemical Mechanical Polishing) treatment is preferably performed when the part of the second conductive film is removed.

### Effect of the Invention

According to one embodiment of the present invention, a semiconductor device that can be miniaturized or highly integrated can be provided. Alternatively, according to one embodiment of the present invention, a semiconductor device having favorable electrical characteristics can be provided. Alternatively, according to one embodiment of the present invention, a semiconductor device having a high on-state current can be provided. Alternatively, according to one embodiment of the present invention, a semiconductor device having excellent frequency characteristics can be provided. Alternatively, according to one embodiment of the present invention, a semiconductor device having favorable reliability can be provided. Alternatively, according to one embodiment of the present invention, a semiconductor device having high productivity can be provided.

Alternatively, a semiconductor device capable of retaining data for a long time can be provided. Alternatively, a semiconductor device capable of high-speed data writing can be provided. Alternatively, a semiconductor device having high design flexibility can be provided. Alternatively, a semiconductor device in which power consumption can be reduced can be provided. Alternatively, a novel semiconductor device can be provided.

Note that the description of these effects does not preclude the existence of other effects. Note that one embodiment of the present invention does not necessarily have all of these effects. Effects other than these will be apparent from the description of the specification, the drawings, the claims, and the like, and effects other than these can be derived from the description of the specification, the drawings, the claims, and the like.

### BRIEF DESCRIPTION OF THE DRAWINGS

FIG. 1 (A)-(D) A top view and cross-sectional views of a semiconductor device of one embodiment of the present invention.

FIG. 2 A cross-sectional view of a semiconductor device of one embodiment of the present invention.

FIG. 3 (A)-(D) A top view and cross-sectional views illustrating a method for manufacturing a semiconductor device of one embodiment of the present invention.

FIG. 4 (A)-(D) A top view and cross-sectional views illustrating a method for manufacturing a semiconductor device of one embodiment of the present invention.

FIG. 5 (A)-(D) A top view and cross-sectional views illustrating a method for manufacturing a semiconductor device of one embodiment of the present invention.

FIG. 6 (A)-(D) A top view and cross-sectional views illustrating a method for manufacturing a semiconductor device of one embodiment of the present invention.

FIG. 7 (A)-(D) A top view and cross-sectional views illustrating a method for manufacturing a semiconductor device of one embodiment of the present invention.

FIG. 8 (A)-(D) A top view and cross-sectional views illustrating a method for manufacturing a semiconductor device of one embodiment of the present invention.

FIG. 9 (A)-(D) A top view and cross-sectional views illustrating a method for manufacturing a semiconductor device of one embodiment of the present invention.

FIG. 10 (A)-(D) A top view and cross-sectional views illustrating a method for manufacturing a semiconductor device of one embodiment of the present invention.

FIG. 11 (A)-(D) A top view and cross-sectional views illustrating a method for manufacturing a semiconductor device of one embodiment of the present invention.

FIG. 12 (A)-(D) A top view and cross-sectional views of a semiconductor device of one embodiment of the present invention.

FIG. 13 (A)-(D) A top view and cross-sectional views illustrating a method for manufacturing a semiconductor device of one embodiment of the present invention.

FIG. 14 (A)-(D) A top view and cross-sectional views illustrating a method for manufacturing a semiconductor device of one embodiment of the present invention.

FIG. 15 (A)-(D) A top view and cross-sectional views illustrating a method for manufacturing a semiconductor device of one embodiment of the present invention.

FIG. 16 (A)-(D) A top view and cross-sectional views of a semiconductor device of one embodiment of the present invention.

FIG. 17 (A)-(D) A top view and cross-sectional views of a semiconductor device of one embodiment of the present invention.

FIG. 18 (A)-(D) A top view and cross-sectional views illustrating a method for manufacturing a semiconductor device of one embodiment of the present invention.

FIG. 19 (A)-(D) A top view and cross-sectional views illustrating a method for manufacturing a semiconductor device of one embodiment of the present invention.

FIG. 20 A cross-sectional view illustrating a structure of a memory device of one embodiment of the present invention.

FIG. 21 A cross-sectional view illustrating a structure of a memory device of one embodiment of the present invention.

FIG. 22 A cross-sectional view illustrating a structure of a memory device of one embodiment of the present invention.

FIG. 23 A cross-sectional view illustrating a structure of a memory device of one embodiment of the present invention.

FIG. 24 A cross-sectional view illustrating a structure of a memory device of one embodiment of the present invention.

FIG. 25 A cross-sectional view illustrating a structure of a memory device of one embodiment of the present invention.

FIG. 26 A cross-sectional view illustrating a structure of a memory device of one embodiment of the present invention.

FIG. 27 A cross-sectional view illustrating a structure of a memory device of one embodiment of the present invention.

FIG. 28 A cross-sectional view illustrating a structure of a memory device of one embodiment of the present invention.

FIG. 29 A cross-sectional view illustrating a structure of a memory device of one embodiment of the present invention.

FIG. 30 A cross-sectional view illustrating a structure of a memory device of one embodiment of the present invention.

FIG. 31 (A), (B) A block diagram and a schematic diagram illustrating a structure example of a memory device of one embodiment of the present invention.

FIG. 32 (A)-(H) Circuit diagrams illustrating configuration examples of a memory device of one embodiment of the present invention.

FIG. 33 (A), (B) A schematic diagram and a block diagram of a semiconductor device of one embodiment of the present invention.

FIG. 34 (A)-(E) Schematic diagrams of memory devices of one embodiment of the present invention.

FIG. 35 A diagram illustrating a product image applicable to a semiconductor device of one embodiment of the present invention.

FIG. 36 (A)-(H) Diagrams illustrating electronic devices of one embodiment of the present invention.

### MODE FOR CARRYING OUT THE INVENTION

Hereinafter, embodiments will be described with reference to drawings. However, the embodiments can be implemented with many different modes, and it will be readily appreciated by those skilled in the art that modes and details thereof can be changed in various ways without departing from the spirit and scope thereof. Thus, the present invention should not be interpreted as being limited to the following description of the embodiments.

In the drawings, the size, the layer thickness, or the region is exaggerated for clarity in some cases. Therefore, the size, the layer thickness, or the region is not limited to the scale. Note that the drawings are schematic views showing ideal examples, and embodiments of the present invention are not limited to shapes, values, or the like shown in the drawings. For example, in the actual manufacturing process, a layer, a resist mask, or the like might be unintentionally reduced in size by treatment such as etching, which is not reflected in the drawings in some cases for easy understanding. Note that in drawings, the same reference numerals are used, in different drawings, for the same portions or portions having similar functions, and repeated description thereof is omitted in some cases. Furthermore, the same hatch pattern is used for the portions having similar functions, and the portions are not denoted by reference numerals in some cases.

Furthermore, especially in a top view (also referred to as a “plan view”), a perspective view, or the like, the description of some components might be omitted for easy understanding of the invention. Furthermore, the description of some hidden lines and the like might be omitted.

Note that in this specification and the like, the ordinal numbers such as first and second are used for convenience and do not denote the order of steps or the stacking order of layers. Therefore, for example, description can be made even when “first” is replaced with “second”, “third”, or the like, as appropriate. In addition, the ordinal numbers in this specification and the like do not correspond to the ordinal numbers which are used to specify one embodiment of the present invention in some cases.

In this specification and the like, terms for describing arrangement, such as “over” and “under”, are used for convenience in describing a positional relationship between components with reference to drawings. Furthermore, the positional relationship between components is changed as appropriate in accordance with a direction in which each component is described. Thus, without limitation to terms described in this specification, the description can be changed appropriately depending on the situation.

In the case where there is an explicit description, X and Y are connected, in this specification and the like, for example, the case where X and Y are electrically connected, the case where X and Y are functionally connected, and the case where X and Y are directly connected are disclosed in this specification and the like. Accordingly, without being limited to a predetermined connection relationship, for example, a connection relationship shown in drawings or texts, a connection relationship other than one shown in drawings or texts is disclosed in the drawings or the texts.

Here, X and Y denote an object (e.g., a device, an element, a circuit, a wiring, an electrode, a terminal, a conductive film, or a layer).

Functions of a source and a drain might be switched when a transistor of opposite polarity is employed or a direction of current is changed in circuit operation. Therefore, the terms “source” and “drain” can be interchanged with each other in this specification and the like in some cases.

Note that in this specification and the like, depending on transistor structures, a channel width in a region where a channel is actually formed (hereinafter, referred to as an “effective channel width”) is different from a channel width shown in a top view of a transistor (hereinafter, referred to as an “apparent channel width”) in some cases. For example, when a gate electrode covers a side surface of a semiconductor, an effective channel width is greater than an apparent channel width, and its influence cannot be ignored in some cases. For example, in a miniaturized transistor having a gate electrode covering a side surface of a semiconductor, the proportion of a channel formation region formed in the side surface of the semiconductor is increased in some cases. In that case, an effective channel width is greater than an apparent channel width.

In such a case, an effective channel width is difficult to estimate by actual measurement in some cases. For example, estimation of an effective channel width from a design value requires an assumption that the shape of a semiconductor is known. Accordingly, in the case where the shape of a semiconductor is not known accurately, it is difficult to measure an effective channel width accurately.

In this specification, the simple term “channel width” refers to an apparent channel width in some cases. Alternatively, in this specification, the simple term “channel width” refers to an effective channel width in some cases. Note that values of a channel length, a channel width, an effective channel width, an apparent channel width, and the like can be determined, for example, by analyzing a cross-sectional TEM image and the like.

Note that an impurity in a semiconductor refers to, for example, elements other than the main components of a semiconductor. For example, an element with a concentration of lower than 0.1 atomic % can be regarded as an impurity. When an impurity is contained, for example, DOS (Density of States) in a semiconductor may be increased or the crystallinity may be decreased. In the case where the semiconductor is an oxide semiconductor, examples of an impurity which changes characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. In the case of an oxide semiconductor, water also functions as an impurity in some cases. In addition, in the case of an oxide semiconductor, oxygen vacancies (also referred to as Vo) are formed by mixing of impurities in some cases. Furthermore, in the case where the semiconductor is silicon, examples of an impurity which changes the characteristics of the semiconductor include oxygen, Group 1 elements except hydrogen, Group 2 elements, Group 13 elements, and Group 15 elements.

Note that in this specification and the like, a silicon oxynitride film is a film in which oxygen content is higher than nitrogen content in its composition. Moreover, a silicon nitride oxide film is a film in which nitrogen content is higher than oxygen content in its composition.

In addition, in this specification and the like, the term “insulator” can be replaced with an insulating film or an insulating layer. Moreover, the term “conductor” can be replaced with a conductive film or a conductive layer. Furthermore, the term “semiconductor” can be replaced with a semiconductor film or a semiconductor layer.

In this specification and the like, the term “parallel” indicates a state where two straight lines are placed such that the angle formed therebetween is greater than or equal to −10° and less than or equal to 10°. Thus, the case where the angle is greater than or equal to −5° and less than or equal to 5° is also included. Furthermore, the term “substantially parallel” indicates a state where two straight lines are placed such that the angle formed therebetween is greater than or equal to −30° and less than or equal to 30°. Moreover, “perpendicular” indicates a state where two straight lines are placed such that the angle formed therebetween is greater than or equal to 80° and less than or equal to 100°. Thus, the case where the angle is greater than or equal to 85° and less than or equal to 95° is also included. In addition, “substantially perpendicular” indicates a state where two straight lines are placed such that the angle formed therebetween is greater than or equal to 60° and less than or equal to 120°.

Note that in this specification, a barrier film means a film having a function of inhibiting transmission of oxygen and impurities such as water and hydrogen, and the barrier film having conductivity is referred to as a conductive barrier film in some cases.

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, in the case where an OS FET or an OS transistor is stated, it can also be referred to as a transistor including an oxide or an oxide semiconductor.

In this specification and the like, the term of normally off means that current per micrometer of channel width flowing in a transistor when no potential is applied to a gate or the gate is supplied with a ground potential is 1×10⁻²⁰ A or lower at room temperature, 1×10⁻¹⁸ A or lower at 85° C., or 1×10⁻¹⁶ A or lower at 125° C.

### Embodiment 1

An example of a semiconductor device including a transistor 200 of one embodiment of the present invention is described below.

### <Structure Example of Semiconductor Device>

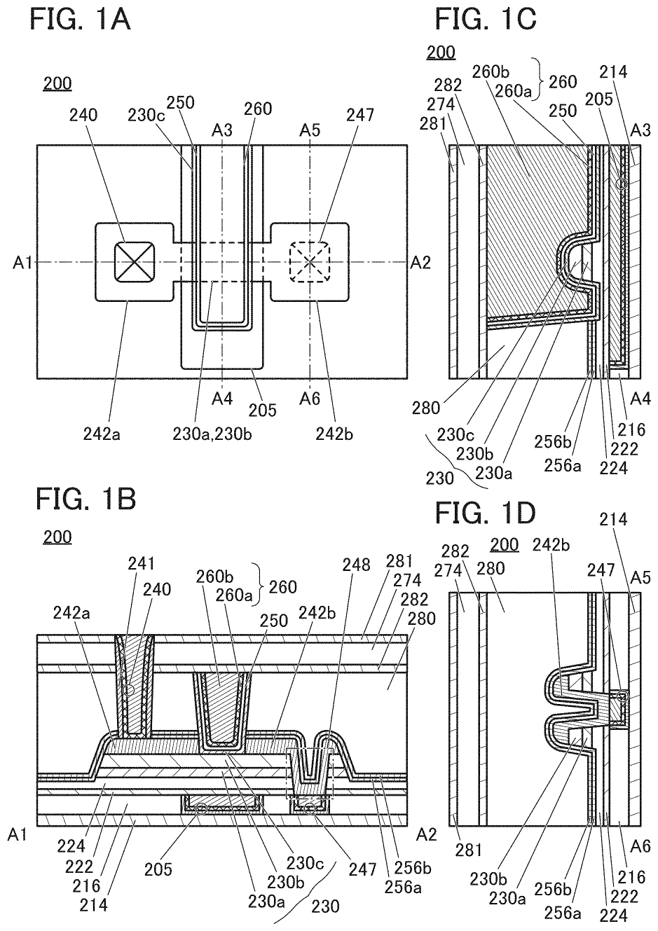

FIG. 1(A), FIG. 1(B), FIG. 1(C), and FIG. 1(D) are a top view and cross-sectional views of the transistor 200 of one embodiment of the present invention and the periphery of the transistor 200.

FIG. 1(A) is a top view of the semiconductor device including the transistor 200. FIG. 1(B), FIG. 1(C) and FIG. 1(D) are cross-sectional views of the semiconductor device. Here, FIG. 1(B) is a cross-sectional view of a portion indicated by a dashed-dotted line A1-A2 in FIG. 1(A), and is a cross-sectional view of the transistor 200 in the channel length direction. FIG. 1(C) is a cross-sectional view of a portion indicated by a dashed-dotted line A3-A4 in FIG. 1(A), and is a cross-sectional view of the transistor 200 in the channel width direction. FIG. 1(D) is a cross-sectional view of a portion indicated by a dashed-dotted line A5-A6 in FIG. 1(A), and is a cross-sectional view of a source region or a drain region of the transistor 200 in the channel width direction. Note that for simplification of the drawing, some components are not illustrated in the top view in FIG. 1(A).

The semiconductor device of one embodiment of the present invention includes an insulator 214 over a substrate (not illustrated), the transistor 200 over the insulator 214, an insulator 280 over the transistor 200, an insulator 282 over the insulator 280, an insulator 274 over the insulator 282, and an insulator 281 over the insulator 274. The insulator 214, the insulator 280, the insulator 282, the insulator 274, and the insulator 281 function as interlayer films. In addition, a conductor 247 is provided so as to be embedded in the insulator 216 provided over the insulator 214. The conductor 247 is electrically connected to the transistor 200 and functions as a plug. Furthermore, a conductor 240 that is electrically connected to the transistor 200 and functions as a plug is provided. Note that an insulator 241 is provided in contact with a side surface of the conductor 240 functioning as a plug.

The insulator 241 is provided in contact with an inner wall of an opening in an insulator 256 (an insulator 256a and an insulator 256b), the insulator 280, the insulator 282, the insulator 274, and the insulator 281; a first conductor of the conductor 240 is provided in contact with a side surface of the insulator 241; and a second conductor of the conductor 240 is provided on the inner side thereof. Here, the top surface of the conductor 240 and the top surface of the insulator 281 can be substantially level with each other. Note that although the transistor 200 having a structure in which the first conductor of the conductor 240 and the second conductor of the conductor 240 are stacked is illustrated, the present invention is not limited thereto. For example, the conductor 240 may be provided as a single layer or provided to have a stacked-layer structure of three or more layers. When a component has a stacked-layer structure, layers may be distinguished by ordinal numbers corresponding to the formation order.

### [Transistor 200]

As illustrated in FIG. 1, the transistor 200 includes the insulator 216 over the insulator 214; a conductor 205 (a conductor 205a and a conductor 205b) positioned so as to be embedded in the insulator 216; an insulator 222 over the insulator 216 and the conductor 205; an insulator 224 over the insulator 222; an oxide 230a over the insulator 224; an oxide 230b over the oxide 230a; a conductor 242a and a conductor 242b over the oxide 230b; an oxide 230c over the oxide 230b; an insulator 250 over the oxide 230c; a conductor 260 (a conductor 260a and a conductor 260b) positioned over the insulator 250 and overlapping with the oxide 230c; and the insulator 256a and the insulator 256b in contact with part of the top surface of the insulator 224, a side surface of the oxide 230a, a side surface of the oxide 230b, a side surface of the conductor 242a, the top surface of the conductor 242a, a side surface of the conductor 242b, and the top surface of the conductor 242b. The oxide 230c is in contact with a side surface of the conductor 242a and a side surface of the conductor 242b. The conductor 260 includes the conductor 260a and the conductor 260b, and the conductor 260a is positioned so as to cover the bottom surface and a side surface of the conductor 260b. Here, as illustrated in FIG. 1(B), the top surface of the conductor 260 is substantially level with the top surface of the insulator 250 and the top surface of the oxide 230c. The insulator 282 is in contact with the top surface of each of the conductor 260, the oxide 230c, the insulator 250, and the insulator 280.

An opening is formed in the insulator 216, and the conductor 247 described above is positioned in the opening. It is preferable that at least part of the top surface of the conductor 247 be exposed from the insulator 216, and the top surface of the conductor 247 and the top surface of the insulator 216 be substantially level with each other.

Here, the conductor 247 functions as a plug for electrically connecting the transistor 200 to a circuit element such as a switch, a transistor, a capacitor, an inductor, a resistor, or a diode, a wiring, an electrode, or a terminal, provided below the insulator 214. For example, a structure can be employed in which the conductor 247 is electrically connected to one electrode of a capacitor provided below the insulator 214. Alternatively, a structure can be employed in which the conductor 247 is electrically connected to a gate of a transistor provided below the insulator 214, for example.

Furthermore, an opening 248 through which at least part of the conductor 247 is exposed is formed in the insulator 222, the insulator 224, the oxide 230a, and the oxide 230b.

The conductor 242b is positioned over the oxide 230b and is in contact with at least part of the top surface of the conductor 247 through the opening 248. When the conductor 242b and the conductor 247 are connected to each other as described here, electrical resistance between the conductor 247 and a source or a drain of the transistor 200 can be reduced.

With such a structure, frequency characteristics of the semiconductor device including the transistor 200 can be improved and favorable electric characteristics can be obtained.

It is preferable that, at least part of a circuit element such as a switch, a transistor, a capacitor, an inductor, a resistor, or a diode, a wiring, an electrode, or a terminal, which is electrically connected to the conductor 247, overlap with the oxide 230. This can reduce the area occupied by the transistor 200 and the circuit element, the wiring, the electrode, or the terminal in the top view; thus, the semiconductor device of this embodiment can be miniaturized or highly integrated.

Note that the conductor 242b is preferably provided to be in contact with a side surface of the oxide 230a and a side surface of the oxide 230b in the opening 248.

Although the conductor 247 is provided below the conductor 242b in FIGS. 1(A) and 1(B), the semiconductor device described in this embodiment is not limited thereto. For example, the conductor 247 may be provided below the conductor 242a, or the conductor 247 may be provided below both the conductor 242a and the conductor 242b.

It is preferable that the insulator 222, the insulator 256 (the insulator 256a and the insulator 256b), and the insulator 282 have a function of inhibiting diffusion of hydrogen (e.g., at least one of a hydrogen atom, a hydrogen molecule, and the like). In addition, it is preferable that the insulator 222, the insulator 256, and the insulator 282 have a function of inhibiting diffusion of oxygen (e.g., at least one of an oxygen atom, an oxygen molecule, and the like). For example, it is preferable that the insulator 222, the insulator 256, and the insulator 282 each have a lower permeability of one or both of oxygen and hydrogen than the insulator 224. It is preferable that the insulator 222, the insulator 256, and the insulator 282 each have a lower permeability of one or both of oxygen and hydrogen than the insulator 250. It is preferable that the insulator 222, the insulator 256, and the insulator 282 each have a lower permeability of one or both of oxygen and hydrogen than the insulator 280.

It is preferable that, as illustrated in FIG. 1(B), the conductor 242a and the conductor 242b be provided over the oxide 230b, and the insulator 256 be in contact with the top surface and the side surface of the conductor 242a, the top surface and the side surface of the conductor 242b, the side surface of the oxide 230b, the side surface of the oxide 230a, and the top surface of the insulator 224. Furthermore, the insulator 256 preferably has a stacked-layer structure including the insulator 256a and the insulator 256b. In that case, the side surfaces of the oxide 230a and the oxide 230b are not in contact with the conductor 242a and the conductor 242b in parts except in the opening 248, that is, the peripheral side surfaces, and the insulator 280 is isolated from the insulator 224, the oxide 230a, and the oxide 230b by the insulator 256 (the insulator 256a and the insulator 256b).

The oxide 230 preferably includes the oxide 230a over the insulator 224, the oxide 230b over the oxide 230a, and the oxide 230c which is placed over the oxide 230b and at least partly in contact with the top surface of the oxide 230b.

The transistor 200 described here has a structure in which the oxide 230 has a three-layer stacked structure of the oxide 230a, the oxide 230b, and the oxide 230c in a region where a channel is formed (hereinafter also referred to as a channel formation region) and its vicinity; however, the present invention is not limited thereto. For example, the oxide 230 may have a structure in which a single-layer structure of the oxide 230b, a two-layer structure of the oxide 230b and the oxide 230a, a two-layer structure of the oxide 230b and the oxide 230c, or a stacked-layer structure of four or more layers is provided. Alternatively, each of the oxide 230a, the oxide 230b, and the oxide 230c may have a stacked-layer structure of two or more layers. Although the transistor 200 described here has a structure in which the conductor 260 has a stacked-layer structure of two layers, the present invention is not limited thereto. For example, the conductor 260 may have a single-layer structure or a stacked-layer structure of three or more layers.

Here, the conductor 260 functions as a gate electrode of the transistor and the conductor 242a and the conductor 242b function as the source electrode and the drain electrode. In the transistor 200, the conductor 260 functioning as the gate electrode is formed in a self-aligned manner to fill an opening formed in the insulator 280 and the like. The formation of the conductor 260 in this manner allows the conductor 260 to be surely placed in a region between the conductor 242a and the conductor 242b without alignment.

In the transistor 200, a metal oxide functioning as an oxide semiconductor (hereinafter also referred to as an oxide semiconductor) is preferably used for the oxide 230 (the oxide 230a, the oxide 230b, and the oxide 230c), which includes the channel formation region.

The transistor 200 using an oxide semiconductor in its channel formation region has an extremely low leakage current (off-state current) in a non-conduction state; thus, a semiconductor device with low power consumption can be provided. An oxide semiconductor can be deposited by a sputtering method or the like, and thus can be used for the transistor 200 included in a highly integrated semiconductor device.

For example, for the oxide 230, a metal oxide such as an In-M-Zn oxide (an element M is one kind or a plurality of kinds selected from aluminum, gallium, yttrium, tin, copper, vanadium, beryllium, boron, titanium, iron, nickel, germanium, zirconium, molybdenum, lanthanum, cerium, neodymium, hafnium, tantalum, tungsten, magnesium, and the like) is preferably used. In particular, aluminum, gallium, yttrium, or tin is preferably used as the element M. An In—Ga oxide or an In—Zn oxide may be used for the oxide 230.

Here, when the oxide 230 contains impurities such as hydrogen, nitrogen, or a metal element, the carrier density may increase and the resistance may be lowered. Furthermore, when the oxygen concentration of the oxide 230 is reduced, the carrier density may be increased and the resistance may be lowered.

When the conductors 242 (the conductor 242a and the conductor 242b) that are provided on and in contact with the oxide 230b and function as the source electrode and the drain electrode have a function of absorbing oxygen in the oxide 230 or have a function of supplying impurities such as hydrogen, nitrogen, or a metal element to the oxide 230, a low-resistance region is partly formed in the oxide 230 in some cases. The conductors 242 are formed over the oxide 230b, and are not in contact with the insulator 224 and the side surfaces of the oxide 230a and the oxide 230b in parts except in the opening 248, that is, the peripheral side surfaces. Accordingly, oxidation of the conductors 242 due to oxygen contained in at least one of the oxide 230a, the oxide 230b, and the insulator 224 can be inhibited. In addition, absorption of oxygen contained in the oxide 230a and the oxide 230b, particularly in the channel formation region and the vicinity thereof, from the side surfaces of the oxide 230a and the oxide 230b into the conductors 242 can be inhibited.

The insulator 256 is provided so that the side surfaces of the oxide 230a and the oxide 230b are not directly in contact with the insulator 280. Moreover, the insulator 256 is provided to inhibit oxidation of the conductors 242. Note that in the case where the conductors 242 are oxidation-resistance materials or in the case where the conductivity of the conductors 242 is not significantly decreased even after absorbing oxygen, the insulator 256 does not need to have an effect of inhibiting oxidation of the conductors 242.

The insulator 256 can inhibit injection of oxygen contained in the insulator 280 from the side surfaces of the oxide 230a and the oxide 230b.

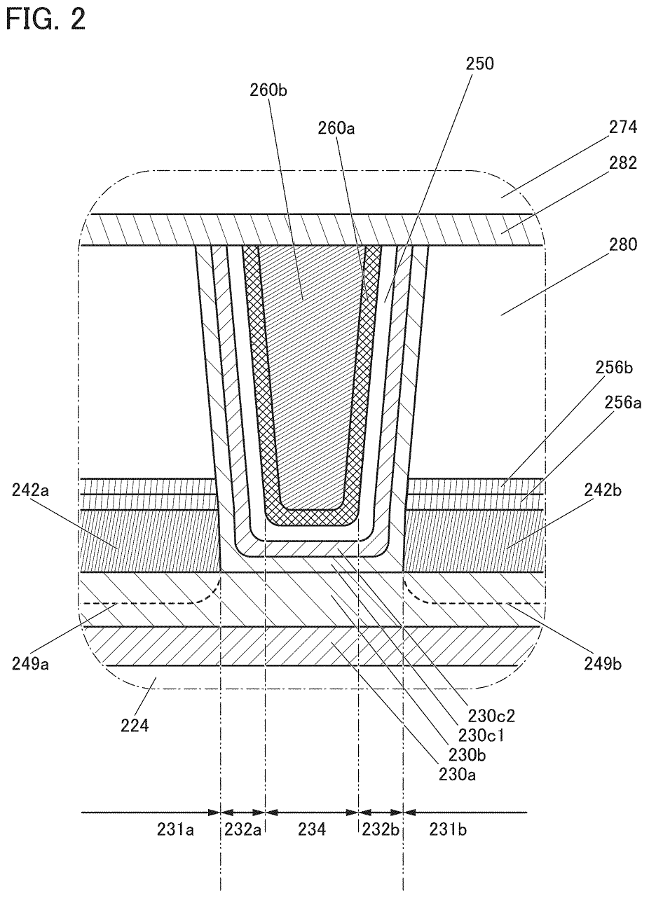

FIG. 2 illustrates an enlarged view of the vicinity of the channel formation region in FIG. 1(B).

As illustrated in FIG. 2, the conductors 242 are provided over and in contact with the oxide 230b, and regions 249 (a region 249a and a region 249b) are formed as low-resistance regions at and near the interfaces of the oxide 230 with the conductors 242. The oxide 230 includes a region 234 functioning as the channel formation region of the transistor 200, regions 231 (a region 231a and a region 231b) functioning as the source region and the drain region, and regions 232 (a region 232a and a region 232b) between the region 234 and the regions 231. Here, the regions 231 include the regions 249. Although FIG. 2 illustrates an example in which the oxide 230c has a stacked-layer structure including an oxide 230c1 and an oxide 230c2, this embodiment is not limited thereto. The oxide 230c may have a single-layer structure or a stacked-layer structure of three or more layers.

In each of the regions 231 that functions as the source region or the drain region, the region 249, particularly, is a region that has a low oxygen concentration or contains impurities such as hydrogen, nitrogen, or a metal element and thus has an increased carrier concentration and reduced resistance. In other words, the regions 231 are regions having higher carrier density and lower resistance than the region 234. Furthermore, the region 234 functioning as the channel formation region is a high-resistance region with a low carrier density because it has a higher oxygen concentration or a lower impurity concentration than, particularly, the regions 249 of the regions 231. It is preferable that the oxygen concentration of the regions 232 be higher than or equal to the oxygen concentration in the regions 231 and lower than or equal to the oxygen concentration of the region 234. Alternatively, it is preferable that the impurity concentration of the regions 232 be lower than or equal to the impurity concentration of the regions 231 and higher than or equal to the impurity concentration of the region 234.

That is, the regions 232 may function as channel formation regions like the region 234 when having resistance substantially equal to that of the region 234, low-resistance regions that have resistance substantially equal to that of the regions 231, or low-resistance regions that have higher resistance than the regions 231 and lower resistance than the region 234, depending on the concentration of oxygen or impurities contained in the regions 232. In particular, in the case where part of the oxide 230 includes a CAAC-OS described later, impurities contained in the regions 231 are easily diffused in the a-b plane direction and the resistance of the regions 232 is reduced in some cases.

Note that, in the case where the regions 249, which are low-resistance regions, contain a metal element, the regions 249 preferably contain, in addition to the metal element contained in the oxide 230, one or a plurality of metal elements selected from metal elements such as aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum.

Although the regions 249 are formed near the interfaces of the oxide 230b with the conductors 242 in the thickness direction of the oxide 230b in FIG. 2, this embodiment is not limited thereto. For example, the regions 249 may have substantially the same thickness as the oxide 230b or may also be formed in the oxide 230a. Furthermore, although the regions 249 are formed only in the regions 231 in FIG. 2, this embodiment is not limited thereto. In the case where impurities are diffused in the a-b plane direction as described above, the regions 249 may be formed in the regions 231 and the regions 232, may be formed in part of the regions 231 and part of the regions 232, or may be formed in part of the regions 231, part of the regions 232, and part of the region 234.

In the oxide 230, the boundaries between the regions are difficult to detect clearly in some cases. The concentrations of a metal element and an impurity element such as hydrogen and nitrogen, which are detected in each region, may be not only gradually changed between the regions, but also continuously changed (also referred to as gradation) in each region. That is, the region closer to the channel formation region has lower concentrations of a metal element and an impurity element such as hydrogen and nitrogen.

To selectively reduce the resistance of the oxide 230, for the conductors 242, for example, a material that contains at least one of impurities and metal elements that increase conductivity such as aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum is preferably used. Alternatively, a conductive film 242A to be the conductors 242 is formed using a material, a deposition method, or the like that injects impurities such as an element that forms oxygen vacancies or an element trapped by oxygen vacancies into the oxide 230. Examples of the element include hydrogen, boron, carbon, nitrogen, fluorine, phosphorus, sulfur, chlorine, and a rare gas element. Typical examples of the rare gas element are helium, neon, argon, krypton, and xenon.

A transistor using an oxide semiconductor is likely to have its electrical characteristics changed when impurities and oxygen vacancies exist in a region of the oxide semiconductor where a channel is formed, which may affect the reliability. Moreover, if the region of the oxide semiconductor where a channel is formed contains oxygen vacancies, the transistor tends to have normally-on characteristics. Therefore, oxygen vacancies in the region 234 where a channel is formed are preferably reduced as much as possible.

To inhibit the transistor from becoming normally on, the insulator 250 near the oxide 230 preferably contains oxygen more than oxygen in the stoichiometric composition (also referred to as excess oxygen). Oxygen in the insulator 250 is diffused into the oxide 230 to reduce oxygen vacancies in the oxide 230 and can inhibit the transistor from becoming normally on.

That is, oxygen contained in the insulator 250 is diffused into the region 234 of the oxide 230, whereby oxygen vacancies in the region 234 of the oxide 230 can be reduced. Furthermore, oxygen contained in the insulator 280 is diffused into the region 234 of the oxide 230 through the oxide 230c, whereby oxygen vacancies in the region 234 of the oxide 230 can be reduced. In that case, a structure may be employed as illustrated in FIG. 2 in which the oxide 230c has a stacked-layer structure including the oxide 230c1 and the oxide 230c2 so that oxygen contained in the insulator 280 is diffused into the region 234 of the oxide 230 through the oxide 230c1. Furthermore, when a material which is less likely to transmit oxygen is used for the oxide 230c2, diffusion of oxygen contained in the insulator 280 into the insulator 250 or the conductor 260 can be inhibited and oxygen in the insulator 280 can be efficiently supplied to the region 234 of the oxide 230.

The above-described structure enables the amount of oxygen supplied to the oxide 230 to be adjusted; accordingly, a highly reliable transistor which is prevented from becoming normally-on can be obtained.

As illustrated in FIGS. 1(B) and 1(C), the transistor 200 of one embodiment of the present invention has a structure in which the insulator 282 and the insulator 250 are directly in contact with each other. With such a structure, oxygen contained in the insulator 280 is less likely to be absorbed into the conductor 260. Thus, oxygen contained in the insulator 280 can be injected into the oxide 230a and the oxide 230b efficiently through the oxide 230c; hence, oxygen vacancies in the oxide 230a and the oxide 230b can be reduced and the electrical characteristics and the reliability of the transistor 200 can be improved. In addition, the mixing of impurities such as hydrogen contained in the insulator 280 into the insulator 250 can be inhibited, which can inhibit the adverse effects on the electrical characteristics and the reliability of the transistor 200. For the insulator 282, silicon nitride, silicon nitride oxide, aluminum oxide, or hafnium oxide can be used. It is particularly suitable that silicon nitride is used for the insulator 282. The silicon nitride can suitably block impurities (e.g., hydrogen or water) that might enter from the outside.

The insulator 256 preferably has a function of inhibiting transmission of oxygen and impurities such as hydrogen or water. The insulator 256 may have a single-layer structure, or a stacked-layer structure of two or more layers including the insulator 256a and the insulator 256b. For the insulator 256a or the insulator 256b, for example, aluminum oxide, hafnium oxide, a silicon oxide film, a silicon nitride film, or a silicon nitride oxide film can be used. The insulator 256a and the insulator 256b may be formed using the same material or different materials. In the case of using the same material for the insulator 256a and the insulator 256b, the insulator 256a and the insulator 256b may be formed by different deposition methods. For example, the insulator 256a may be formed by a sputtering method and the insulator 256b may be formed by an ALD method. Alternatively, the insulator 256a may be formed by an ALD method and the insulator 256b may be formed by a sputtering method. A material that can be used for the oxide 230 may be used for the insulator 256. In that case, a metal oxide with In:Ga:Zn=1:3:4 [atomic ratio] or 1:1:0.5 [atomic ratio], which is an oxide that is less likely to transmit oxygen, is used for the insulator 256.

FIG. 1(D) is a cross-sectional view of a portion indicated by a dashed-dotted line A5-A6 in FIG. 1(A), and is also a cross-sectional view in the channel width direction of a source region or a drain region of the transistor 200. As illustrated in FIG. 1(D), a structure is employed in which the top surface of the conductor 242b and the side surface of the conductor 242b are covered with the insulator 256; thus, oxygen and impurities such as hydrogen or water can be inhibited from being diffused into the conductor 242b from the directions of the side surface of the conductor 242b and the top surface of the conductor 242b. Hence, diffusion of oxygen into the conductor 242b from the periphery of the conductor 242b can be inhibited, so that the oxidation of the conductor 242b can be inhibited. Note that a similar effect can also be obtained in the conductor 242a. Impurities such as hydrogen or water can be inhibited from being diffused into the oxide 230a and the oxide 230b from the side surface direction of the oxide 230a and the side surface direction of the oxide 230b.

As illustrated in FIG. 1(C), when the bottom surface of the insulator 224 is used as a reference, the level of the bottom surface of the conductor 260 in a region where the oxide 230a and the oxide 230b do not overlap with the conductor 260 is preferably lower than the level of the bottom surface of the oxide 230b. The difference between the level of the bottom surface of the conductor 260 in a region where the oxide 230b does not overlap with the conductor 260 and the level of the bottom surface of the oxide 230b is set to greater than or equal to 0 nm and less than or equal to 100 nm, preferably greater than or equal to 3 nm and less than or equal to 50 nm, further preferably greater than or equal to 5 nm and less than or equal to 20 nm.

As described above, the conductor 260, which functions as the gate electrode, covers the side surface and the top surface of the oxide 230b of the channel formation region, with the oxide 230c and the insulator 250 positioned therebetween; this enables the electrical field of the conductor 260 to easily affect the entire oxide 230b of the channel formation region. Consequently, the on-state current of the transistor 200 can be increased and the frequency characteristics can be improved.

Accordingly, a miniaturized or highly integrated semiconductor device can be provided. Alternatively, a semiconductor device that includes a transistor having a high on-state current can be provided. Alternatively, a semiconductor device that includes a transistor having excellent frequency characteristics can be provided. Alternatively, a semiconductor device that has stable electrical characteristics with a small variation in electrical characteristics and improved reliability can be provided. Alternatively, a semiconductor device that includes a transistor having a low off-state current can be provided.

The structure of the semiconductor device including the transistor 200 of one embodiment of the present invention is described in detail below.

The conductor 205 is placed to overlap with the oxide 230 and the conductor 260. Furthermore, the conductor 205 is preferably provided to be embedded in the insulator 214 and the insulator 216.

The conductor 260 sometimes functions as a first gate (also referred to as a top gate) electrode. The conductor 205 sometimes functions as a second gate (also referred to as a bottom gate) electrode. In that case, the Vth of the transistor 200 can be controlled by changing a potential applied to the conductor 205 independently of a potential applied to the conductor 260. In particular, the Vth of the transistor 200 can be higher than 0 V and the off-state current can be reduced by applying a negative potential to the conductor 205. Thus, a drain current when a potential applied to the conductor 260 is 0 V can be smaller in the case where a negative potential is applied to the conductor 205 than in the case where the negative potential is not applied to the conductor 205.

As illustrated in FIG. 1(A), the conductor 205 is preferably provided to be larger than a region of the oxide 230 that does not overlap with the conductor 242a or the conductor 242b. As illustrated in FIG. 1(C), it is particularly preferable that the conductor 205 extend to a region outside an end portion of the oxide 230 that intersects with the channel width direction. That is, the conductor 205 and the conductor 260 preferably overlap with each other with the insulators therebetween on an outer side of the side surface of the oxide 230 in the channel width direction. A large conductor 205 can sometimes reduce local charging (referred to as charge up) in a treatment using plasma of a manufacturing step after the formation of the conductor 205. Note that one embodiment of the present invention is not limited thereto. The conductor 205 overlaps at least with the oxide 230 positioned between the conductor 242a and the conductor 242b.

With the above structure, the channel formation region can be electrically surrounded by the electric field of the conductor 260 having a function of the first gate electrode and the electric field of the conductor 205 having a function of the second gate electrode. In this specification, the transistor structure in which the channel formation region is electrically surrounded by the electric fields of the first gate electrode and the second gate electrode is referred to as a surrounded channel (S-channel) structure.

The conductor 205a is preferably a conductor that inhibits the transmission of oxygen and impurities such as water or hydrogen. For example, titanium, titanium nitride, tantalum, or tantalum nitride can be used. Moreover, the conductor 205b is preferably formed using a conductive material containing tungsten, copper, or aluminum as its main component. Although the conductor 205 is illustrated as having two layers, a multilayer structure with three or more layers may be employed.

The insulator 214, the insulator 256, the insulator 282, and the insulator 281 preferably function as a barrier insulating film that inhibits impurities such as water or hydrogen from entering the transistor 200 from the substrate side or from the above. Thus, the insulator 214, the insulator 256, the insulator 282, and the insulator 281 are preferably formed using an insulating material having a function of inhibiting diffusion of impurities (through which the impurities are unlikely to pass) such as a hydrogen atom, a hydrogen molecule, a water molecule, a nitrogen atom, a nitrogen molecule, a nitrogen oxide molecule (e.g., N₂O, NO, or NO₂), or a copper atom. Alternatively, it is preferable to use an insulating material having a function of inhibiting diffusion of oxygen (e.g., at least one of an oxygen atom, an oxygen molecule, and the like) (or through which the above oxygen is less likely to pass).

For example, it is preferable that silicon nitride or the like be used for the insulator 214, the insulator 256, the insulator 282, and the insulator 281. Accordingly, impurities such as water or hydrogen can be inhibited from being diffused into the transistor 200 side from the substrate side through the insulator 214. Alternatively, oxygen contained in the insulator 224 and the like can be prevented from being diffused into the substrate side of the insulator 214. Impurities such as water or hydrogen can be inhibited from diffusing into the transistor 200 side from the insulator 280 and the like, which are provided above the insulator 256.

The resistivities of the insulator 214, the insulator 256, the insulator 282, and the insulator 281 are preferably low in some cases. For example, by setting the resistivities of the insulator 214, the insulator 256, the insulator 282, and the insulator 281 to approximately 1×10¹³ Ωcm, the insulator 214, the insulator 256, the insulator 282, and the insulator 281 can reduce charge up of the conductor 205, the conductors 242 or the conductor 260 in a treatment using plasma or the like of a manufacturing process of a semiconductor device in some cases. The resistivities of the insulator 214, the insulator 256, the insulator 282, and the insulator 281 are preferably higher than or equal to 1×10¹⁰ Ωcm and lower than or equal to 1×10¹⁵ Ωcm.

The insulator 214 may have a stacked-layer structure. For example, it is suitable that a stacked-layer structure of an aluminum oxide film and a silicon nitride film is used for the insulator 214. With the aluminum oxide film, oxygen can be supplied to a lower part of the insulator 214. Furthermore, diffusion of impurities such as hydrogen and water that enter the transistor 200 side from the substrate side can be inhibited by the silicon nitride film.

The insulator 216, the insulator 280, and the insulator 274 preferably have a lower dielectric constant than the insulator 214. When a material having a low dielectric constant is used for an interlayer film, parasitic capacitance generated between wirings can be reduced. As the insulator 216, the insulator 280, and the insulator 274, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like is used, for example.

The insulator 222 and the insulator 224 have a function of a gate insulator.

Here, it is preferable that oxygen be released from the insulator 224 in contact with the oxide 230 by heating. In this specification, oxygen that is released by heating is referred to as excess oxygen in some cases. For example, silicon oxide, silicon oxynitride, or the like is used for the insulator 224 as appropriate. When an insulator containing oxygen is provided in contact with the oxide 230, oxygen vacancies in the oxide 230 can be reduced and the reliability of the transistor 200 can be improved.

As the insulator 224, specifically, an oxide material from which part of oxygen is released by heating is preferably used. An oxide that releases oxygen by heating is an oxide film in which the amount of released oxygen converted into oxygen molecules is greater than or equal to 1.0×10¹⁸ molecules/cm³, preferably greater than or equal to 1.0×10¹⁹ molecules/cm³, further preferably greater than or equal to 2.0×10¹⁹ molecules/cm³ or greater than or equal to 3.0×10²⁰ molecules/cm³ in TDS (Thermal Desorption Spectroscopy) analysis. Note that the temperature of the film surface in the TDS analysis is preferably higher than or equal to 100° C. and lower than or equal to 700° C., or higher than or equal to 100° C. and lower than or equal to 400° C.

The insulator 222 preferably functions as a barrier insulating film that inhibits impurities such as water or hydrogen from being mixed in the transistor 200 from the substrate side. For example, the insulator 222 has the property of being less likely to transmit hydrogen than the insulator 224. Surrounding the insulator 224, the oxide 230, and the like by the insulator 222 and the insulator 256 can inhibit entry of impurities such as water or hydrogen into the transistor 200 from the outside.

Furthermore, the insulator 222 preferably has a function of inhibiting diffusion of oxygen (e.g., at least one of an oxygen atom, an oxygen molecule, and the like) (or is preferably less likely to transmit the above oxygen). For example, the insulator 222 preferably has the property of being less likely to transmit oxygen than the insulator 224. The insulator 222 preferably has a function of inhibiting diffusion of oxygen or impurities, in which case diffusion of oxygen contained in the oxide 230 into a layer under the insulator 222 can be reduced. Furthermore, the conductor 205 can be inhibited from reacting with oxygen contained in the insulator 224 or the oxide 230.

Furthermore, it is particularly preferable to use an insulator containing an oxide of one or both of aluminum and hafnium, which is an insulating material, for the insulator 222. As the insulator containing an oxide of one or both of aluminum and hafnium, aluminum oxide, hafnium oxide, an oxide containing aluminum and hafnium (hafnium aluminate), or the like is preferably used. When the insulator 222 is formed using such a material, the insulator 222 functions as a layer that inhibits release of oxygen from the oxide 230 and mixing of impurities such as hydrogen from the periphery of the transistor 200 in the oxide 230.

Alternatively, to these insulators, aluminum oxide, bismuth oxide, germanium oxide, niobium oxide, silicon oxide, titanium oxide, tungsten oxide, yttrium oxide, or zirconium oxide may be added, for example. Alternatively, these insulators may be subjected to nitriding treatment. Silicon oxide, silicon oxynitride, or silicon nitride may be stacked over the insulator.

For example, a single layer or a stacked layer of an insulator containing what is called a high-k material such as aluminum oxide, hafnium oxide, tantalum oxide, zirconium oxide, lead zirconate titanate (PZT), strontium titanate (SrTiO₃), or (Ba,Sr)TiO₃ (BST) may be used for the insulator 222. With miniaturization and high integration of a transistor, a problem such as leakage current may arise because of a thinner gate insulator. When a high-k material is used for an insulator functioning as the gate insulator, a gate potential during operation of the transistor can be reduced while the physical thickness of the gate insulator is kept.

Note that the insulator 222 and the insulator 224 may each have a stacked-layer structure of two or more layers. In that case, without limitation to a stacked-layer structure formed of the same material, a stacked-layer structure formed of different materials may be employed.

The conductor 247 may also have a structure in which a first conductive layer and a second conductive layer positioned on an inner side of the first conductive layer like the conductor 205. The first conductive layer of the conductor 247 is preferably a conductor that inhibits the transmission of oxygen and impurities such as water or hydrogen. For example, titanium, titanium nitride, tantalum, or tantalum nitride can be used. Moreover, the second conductive layer of the conductor 247 is preferably formed using a conductive material containing tungsten, copper, or aluminum as its main component. Although the conductor 247 is illustrated as having two layers, a multilayer structure with three or more layers may be employed.

An insulator that inhibits the diffusion of oxygen and impurities such as hydrogen or water, like the insulator 241, may be provided at the side surface of the conductor 247 as in the conductor 240.

The oxide 230 includes the oxide 230a, the oxide 230b over the oxide 230a, and the oxide 230c over the oxide 230b. Here, the oxide 230c is positioned such that at least part thereof overlaps with the region between the conductor 242a and the conductor 242b. When the oxide 230a is provided below the oxide 230b, impurities can be inhibited from diffusing into the oxide 230b from the components formed below the oxide 230a. When the oxide 230c is provided over the oxide 230b, impurities can be inhibited from diffusing into the oxide 230b from the components formed above the oxide 230c.

Note that the oxide 230 preferably has a stacked-layer structure using oxides which differ in the atomic ratio of metal atoms. Specifically, the atomic proportion of the element M in constituent elements in the metal oxide used as the oxide 230a is preferably greater than the atomic proportion of the element M in constituent elements in the metal oxide used as the oxide 230b. Moreover, the atomic ratio of the element M to In in the metal oxide used as the oxide 230a is preferably greater than the atomic ratio of the element M to In in the metal oxide used as the oxide 230b. Furthermore, the atomic ratio of In to the element M in the metal oxide used as the oxide 230b is preferably greater than the atomic ratio of In to the element M in the metal oxide used as the oxide 230a. A metal oxide that can be used for the oxide 230a or the oxide 230b can be used as the oxide 230c.

The oxide 230b preferably has crystallinity. For example, a CAAC-OS (c-axis aligned crystalline oxide semiconductor) described later is preferably used. An oxide having crystallinity, such as a CAAC-OS, has a dense structure with small amounts of impurities and defects (oxygen vacancies or the like) and high crystallinity. This can inhibit oxygen extraction from the oxide 230b by the source electrode or the drain electrode. This can reduce oxygen extraction from the oxide 230b even when heat treatment is performed; hence, the transistor 200 is stable with respect to high temperatures in the manufacturing process (what is called thermal budget).

The energy of the conduction band minimum of each of the oxide 230a and the oxide 230c is preferably higher than the energy of the conduction band minimum of the oxide 230b. In other words, the electron affinity of each of the oxide 230a and the oxide 230c is preferably smaller than the electron affinity of the oxide 230b.

Here, the energy level of the conduction band minimum is gradually varied at a junction region of the oxide 230a, the oxide 230b, and the oxide 230c. In other words, the energy level of the conduction band minimum at a junction region of each of the oxide 230a, the oxide 230b, and the oxide 230c is continuously varied or continuously connected. To obtain this, the densities of defect states in mixed layers formed at an interface between the oxide 230a and the oxide 230b and an interface between the oxide 230b and the oxide 230c are preferably made low.

Specifically, as the oxide 230a, a metal oxide with In:Ga:Zn=1:3:4 [atomic ratio] or 1:1:0.5 [atomic ratio] is used. As the oxide 230b, a metal oxide with In:Ga:Zn=4:2:3 [atomic ratio] or 1:1:1 [atomic ratio] is used. As the oxide 230c, a metal oxide with In:Ga:Zn=1:3:4 [atomic ratio], In:Ga:Zn=4:2:3 [atomic ratio], Ga:Zn=2:1 [atomic ratio], or Ga:Zn=2:5 [atomic ratio] is used. Specific examples of the oxide 230c having a stacked-layer structure include a stacked-layer structure of In:Ga:Zn=4:2:3 [atomic ratio] as the oxide 230c1 and In:Ga:Zn=1:3:4 [atomic ratio] as the oxide 230c2, a stacked-layer structure of In:Ga:Zn=4:2:3 [atomic ratio] as the oxide 230c1 and Ga:Zn=2:1 [atomic ratio] as the oxide 230c2, a stacked-layer structure of In:Ga:Zn=4:2:3 [atomic ratio] as the oxide 230c1 and Ga:Zn=2:5 [atomic ratio] as the oxide 230c2, and a stacked-layer structure of In:Ga:Zn=4:2:3 [atomic ratio] as the oxide 230c1 and gallium oxide as the oxide 230c2.

At this time, the oxide 230b serves as a main carrier path. When the oxide 230a and the oxide 230c have the above structure, the density of defect states at the interface between the oxide 230a and the oxide 230b and the interface between the oxide 230b and the oxide 230c can be made low. Thus, the influence of interface scattering on carrier conduction is small, and the transistor 200 can have a high on-state current and excellent frequency characteristics. Note that in the case where the oxide 230c has a stacked-layer structure, not only the above effect of reducing the density of defect states at the interface between the oxide 230b and the oxide 230c but also the effect of inhibiting diffusion of a constituent element contained in the oxide 230c to the insulator 250 side should be obtained. More specifically, the oxide 230c has a stacked-layer structure and an oxide containing no In or having a reduced In concentration is positioned in an upper portion of the stacked-layer structure, so that possible diffusion of In to the insulator 250 side can be inhibited. Since the insulator 250 functions as the gate insulator, the transistor has defects in characteristics when In diffuses. Thus, when the oxide 230c has a stacked-layer structure, a highly reliable semiconductor device can be provided.

When the oxide 230c has a stacked-layer structure, the interface between the oxide 230b and the oxide 230c1 and its vicinity may serve as a main carrier path.

Since the oxide 230c1 is in contact with the side surface of the insulator 280, oxygen contained in the insulator 280 can be supplied to the channel formation region of the transistor 200 through the oxide 230c1. For the oxide 230c2, a material which is less likely to transmit oxygen is preferably used. The use of the above material can inhibit absorption of oxygen contained in the insulator 280 into the insulator 250 or the conductor 260 through the oxide 230c2; as a result, oxygen can be efficiently supplied to the channel formation region.

The oxide 230 includes the regions 231 and the region 234. At least part of each region 231 includes a region in contact with the conductor 242.

When the transistor 200 is turned on, one of the region 231a and the region 231b functions as the source region and the other functions as the drain region. At least part of the region 234 functions as the region where the channel is formed.

That is, through appropriate selection of the areas of the regions, a transistor having electrical characteristics necessary for a circuit design can be easily provided.

As the oxide 230, a metal oxide functioning as an oxide semiconductor is preferably used. For example, a metal oxide whose energy gap is greater than or equal to 2 eV, preferably greater than or equal to 2.5 eV, is preferably used. With the use of a metal oxide having such a large energy gap, the off-state current of the transistor can be reduced. With use of such a transistor, a semiconductor device with low power consumption can be provided.

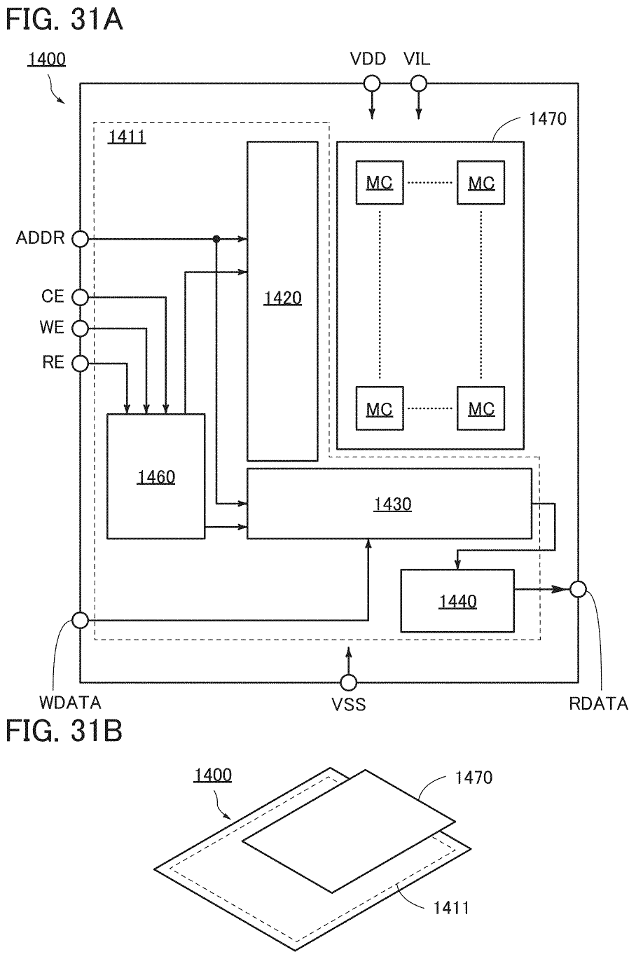

Electron affinity or conduction band minimum Ec can be obtained from an energy gap Eg and an ionization potential Ip, which is a difference between a vacuum level and an energy of valence band maximum Ev, as shown in FIG. 31. The ionization potential Ip can be measured using, for example, an ultraviolet photoelectron spectroscopy (UPS) apparatus. The energy gap Eg can be measured using, for example, a spectroscopic ellipsometer.

The conductors 242 (the conductor 242a and the conductor 242b) functioning as the source electrode and the drain electrode are provided over the oxide 230b. The thickness of the conductors 242 is, for example, greater than or equal to 1 nm and less than or equal to 50 nm, preferably greater than or equal to 2 nm and less than or equal to 25 nm.

For the conductors 242, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above metal elements; an alloy containing a combination of the above metal elements; or the like. For example, tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that retain their conductivity even after absorbing oxygen.

The insulator 250 functions as a gate insulator. The insulator 250 is preferably placed in contact with the inner side (the top surface and the side surface) of the oxide 230c. For the insulator 250, silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride, which are thermally stable, are preferable.

The insulator 250 is preferably formed using an insulator from which oxygen is released by heating as in the insulator 224. When an insulator from which oxygen is released by heating is provided as the insulator 250 in contact with the top surface of the oxide 230c, oxygen can be efficiently supplied to the channel formation region of the oxide 230b. Furthermore, as in the insulator 224, the concentration of impurities such as water or hydrogen in the insulator 250 is preferably reduced. The thickness of the insulator 250 is preferably greater than or equal to 1 nm and less than or equal to 20 nm.

Furthermore, a metal oxide may be provided between the insulator 250 and the conductor 260. The metal oxide preferably inhibits diffusion of oxygen from the insulator 250 into the conductor 260. Provision of the metal oxide that inhibits diffusion of oxygen inhibits diffusion of oxygen from the insulator 250 into the conductor 260. That is, a reduction in the amount of excess oxygen supplied to the oxide 230 can be inhibited. In addition, oxidation of the conductor 260 due to oxygen from the insulator 250 can be inhibited.

The metal oxide has a function of part of the gate insulator in some cases. Therefore, when silicon oxide, silicon oxynitride, or the like is used for the insulator 250, a metal oxide that is a high-k material with a high relative permittivity is preferably used as the metal oxide. When the gate insulator has a stacked-layer structure of the insulator 250 and the metal oxide, the stacked-layer structure can be thermally stable and have a high relative permittivity. Accordingly, a gate potential that is applied during operation of the transistor can be reduced while the physical thickness of the gate insulator is kept. In addition, the equivalent oxide thickness (EOT) of an insulator functioning as the gate insulator can be reduced.

Specifically, a metal oxide containing one kind or two or more kinds selected from hafnium, aluminum, gallium, yttrium, zirconium, tungsten, titanium, tantalum, nickel, germanium, magnesium, and the like can be used. It is particularly preferable to use an insulator containing an oxide of one or both of aluminum and hafnium such as aluminum oxide, hafnium oxide, or an oxide containing aluminum and hafnium (hafnium aluminate).

The metal oxide has a function of part of the gate electrode in some cases. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in a metal oxide where the channel is formed. Alternatively, a conductive material containing the above metal element and nitrogen may be used. Alternatively, indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Furthermore, indium gallium zinc oxide containing nitrogen may be used. With use of such a material, hydrogen contained in the metal oxide where the channel is formed can be trapped in some cases. Alternatively, hydrogen entering from an external insulator or the like can be trapped in some cases.

Although the conductor 260 has a two-layer structure in FIG. 1, a single-layer structure or a stacked-layer structure of three or more layers may be employed.

For the conductor 260a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use a conductive material having a function of inhibiting diffusion of oxygen (e.g., at least one of an oxygen atom, an oxygen molecule, and the like).

When the conductor 260a has a function of inhibiting diffusion of oxygen, the conductivity of the conductor 260b can be inhibited from being lowered because of oxidation due to oxygen contained in the insulator 250. As a conductive material having a function of inhibiting diffusion of oxygen, for example, tantalum, tantalum nitride, ruthenium, ruthenium oxide, or the like is preferably used.

Moreover, a conductive material containing tungsten, copper, or aluminum as its main component is preferably used for the conductor 260b. As the conductor 260 also functioning as a wiring, a conductor having high conductivity is preferably used. For example, a conductive material containing tungsten, copper, or aluminum as its main component can be used. In addition, the conductor 260b may have a stacked-layer structure, for example, a stacked-layer structure of any of the above conductive materials and titanium or titanium nitride.

The insulator 280 preferably contain, for example, silicon oxide, silicon oxynitride, silicon nitride oxide, silicon oxide to which fluorine is added, silicon oxide to which carbon is added, silicon oxide to which carbon and nitrogen are added, porous silicon oxide, or the like. In particular, silicon oxide and silicon oxynitride, which are thermally stable, are preferable. Materials such as silicon oxide, silicon oxynitride, and porous silicon oxide, in each of which a region containing oxygen that is released by heating can be easily formed, are particularly preferable. The insulator 280 preferably contains a larger amount of oxygen so that oxygen contained in the insulator 280 is supplied to the oxide 230b through the oxide 230c, or the oxide 230c1, and preferably contains more oxygen than that in the stoichiometric ratio, for example. To increase the concentration of oxygen contained in the insulator 280, a deposition gas used for forming the insulator 280 preferably contains oxygen.

The concentration of impurities such as water or hydrogen in the insulator 280 is preferably reduced. It is particularly preferable that the insulator 280 be formed by a sputtering method because the insulator 280 in which the concentration of impurities such as water or hydrogen is reduced can be obtained. For example, silicon oxide deposited by a sputtering method using a target containing silicon or silicon oxide and a gas containing argon or oxygen is more suitable for the insulator 280 than silicon oxynitride and silicon oxide deposited by a CVD method using a deposition gas containing hydrogen because the hydrogen concentration of the film is low. Taking a deposition rate at the time of forming the insulator 280 and coverage of steps formed by the oxide 230a, the oxide 230b, the opening 248, and the like into consideration, the insulator 280 may be formed by a CVD method. Although not illustrated, the insulator 280 may have a stacked-layer structure of two or more layers, in which case silicon oxide deposited by a sputtering method is used as the first layer and silicon oxynitride deposited by a CVD method is used as the second layer. The top surface of the insulator 280 may be planarized.

The insulator 282 preferably functions as a barrier insulating film that inhibits impurities such as water or hydrogen from entering the insulator 280 from the above. As the insulator 282, an insulator such as aluminum oxide, silicon nitride, or silicon nitride oxide may be used.

The insulator 274 functioning as an interlayer film is preferably provided over the insulator 282. As in the insulator 224 or the like, the concentration of impurities such as water or hydrogen in the insulator 274 is preferably reduced.

For the conductor 240, a conductive material containing tungsten, copper, or aluminum as its main component is preferably used. In addition, the conductor 240 may have a stacked-layer structure.

In the case where the conductor 240 has a stacked-layer structure, a conductive material having a function of inhibiting the transmission of impurities such as water or hydrogen is preferably used for a conductor in contact with the insulator 281, the insulator 274, the insulator 282, the insulator 280, and the insulator 256. For example, tantalum, tantalum nitride, titanium, titanium nitride, ruthenium, ruthenium oxide, or the like is preferably used. A single layer or a stacked layer of the conductive material having a function of inhibiting the transmission of impurities such as water or hydrogen may be used. The use of the conductive material can prevent oxygen added to the insulator 280 from being absorbed by the conductor 240. Moreover, the mixing of impurities such as water or hydrogen into the oxide 230 through the conductor 240 from a layer above the insulator 281 can be inhibited.

As the insulator 241, an insulator such as aluminum oxide, silicon nitride, or silicon nitride oxide may be used. Since the insulator 241 is provided in contact with the insulator 256, the mixing of impurities such as water or hydrogen into the oxide 230 through the conductor 240 from the insulator 280 or the like can be inhibited. In addition, oxygen contained in the insulator 280 can be prevented from being absorbed by the conductor 240.

A conductor functioning as a wiring may be provided in contact with the top surface of the conductor 240. The conductor functioning as a wiring is preferably formed using a conductive material containing tungsten, copper, or aluminum as its main component. Furthermore, the conductor may have a stacked-layer structure; for example, stacked layers of the above conductive material, and titanium or titanium nitride. Note that the conductor may be formed to be embedded in an opening provided in an insulator.

### <Constituent Material of Semiconductor Device>

Constituent materials that can be used for the semiconductor device will be described below.

### <Substrate>

As a substrate over which the transistor 200 is formed, an insulator substrate, a semiconductor substrate, or a conductor substrate may be used, for example. Examples of the insulator substrate include a glass substrate, a quartz substrate, a sapphire substrate, a stabilized zirconia substrate (an yttria-stabilized zirconia substrate or the like), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Moreover, a semiconductor substrate in which an insulator region is included in the above semiconductor substrate, e.g., an SOI (Silicon On Insulator) substrate or the like is used. Examples of the conductor substrate include a graphite substrate, a metal substrate, an alloy substrate, and a conductive resin substrate. A substrate including a metal nitride, a substrate including a metal oxide, or the like is used. Moreover, an insulator substrate provided with a conductor or a semiconductor, a semiconductor substrate provided with a conductor or an insulator, a conductor substrate provided with a semiconductor or an insulator, or the like is used. Alternatively, any of these substrates provided with an element may be used. Examples of the element provided for the substrate include a capacitor, a resistor, a switching element, a light-emitting element, and a memory element.

### <Insulator>

As an insulator, an oxide, a nitride, an oxynitride, a nitride oxide, a metal oxide, a metal oxynitride, and a metal nitride oxide, each of which has an insulating property can be given.

With miniaturization and high integration of a transistor, a problem such as leakage current may arise because of a thinner gate insulator. When a high-k material is used for an insulator functioning as the gate insulator, a voltage during operation of the transistor can be reduced while the physical thickness of the gate insulator is kept. By contrast, when a material with a low relative permittivity is used for the insulator functioning as an interlayer film, the parasitic capacitance generated between wirings can be reduced. Accordingly, a material is preferably selected depending on the function of an insulator.

As the insulator having a high relative permittivity, gallium oxide, hafnium oxide, zirconium oxide, an oxide containing aluminum and hafnium, an oxynitride containing aluminum and hafnium, an oxide containing silicon and hafnium, an oxynitride containing silicon and hafnium, a nitride containing silicon and hafnium, and the like can be given.

As the insulator with a low relative permittivity, silicon oxide, silicon oxynitride, silicon nitride oxide, silicon oxide to which fluorine is added, silicon oxide to which carbon is added, silicon oxide to which carbon and nitrogen are added, porous silicon oxide, a resin and the like can be given.

When a transistor using an oxide semiconductor is surrounded by insulators having a function of inhibiting transmission of oxygen and impurities such as hydrogen, the electrical characteristics of the transistor can be stable. As the insulator having a function of inhibiting transmission of oxygen and impurities such as hydrogen, an insulator, which is a single layer or a stacked layer, containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum is used, for example. Specifically, for the insulator having a function of inhibiting transmission of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; a metal nitride such as aluminum nitride, aluminum titanium nitride, titanium nitride, silicon nitride oxide or silicon nitride; or the like can be used.

In addition, the insulator functioning as the gate insulator is preferably an insulator including a region containing oxygen that is released by heating. When a structure is employed in which silicon oxide or silicon oxynitride including a region containing oxygen that is released by heating is in contact with the oxide 230, oxygen vacancies contained in the oxide 230 can be compensated for.

### <Conductor>

For the conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that retain their conductivity even after absorbing oxygen. Furthermore, a semiconductor having high electrical conductivity, typified by polycrystalline silicon containing an impurity element such as phosphorus, or silicide such as nickel silicide may be used.

Furthermore, a stack including a plurality of conductive layers formed with the above materials may be used. For example, a stacked-layer structure combining a material containing the above metal element and a conductive material containing oxygen may be employed. Furthermore, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

Note that when an oxide is used for the channel formation region of the transistor, a stacked-layer structure combining a material containing the above metal element and a conductive material containing oxygen is preferably employed for the conductor functioning as the gate electrode. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in a metal oxide in which a channel is formed. Furthermore, a conductive material containing the above metal element and nitrogen may be used. For example, a conductive material containing nitrogen, such as titanium nitride or tantalum nitride, may be used. Furthermore, indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Furthermore, indium gallium zinc oxide containing nitrogen may be used. With the use of such a material, hydrogen contained in the metal oxide in which a channel is formed can be trapped in some cases. Alternatively, hydrogen mixed from an external insulator or the like can be trapped in some cases.

### <Metal Oxide>

As the oxide 230, a metal oxide functioning as an oxide semiconductor is preferably used. A metal oxide that can be used for the oxide 230 of the present invention will be described below.

The metal oxide preferably contains at least indium or zinc. In particular, indium and zinc are preferably contained. Furthermore, aluminum, gallium, yttrium, tin, or the like is preferably contained in addition to them. Furthermore, one kind or a plurality of kinds selected from boron, titanium, iron, nickel, germanium, zirconium, molybdenum, lanthanum, cerium, neodymium, hafnium, tantalum, tungsten, magnesium, and the like may be contained.

Here, the case where the metal oxide is an In-M-Zn oxide containing indium, an element M, and zinc is considered. Note that the element M is aluminum, gallium, yttrium, tin, or the like. Examples of other elements that can be used as the element M include boron, titanium, iron, nickel, germanium, zirconium, molybdenum, lanthanum, cerium, neodymium, hafnium, tantalum, tungsten, and magnesium. Note that a plurality of the above-described elements may be combined as the element M.

Note that in this specification and the like, a metal oxide containing nitrogen is also referred to as a metal oxide in some cases. Alternatively, a metal oxide containing nitrogen may be referred to as a metal oxynitride.

### [Structure of Metal Oxide]

Oxide semiconductors (metal oxides) can be classified into a single crystal oxide semiconductor and a non-single-crystal oxide semiconductor. Examples of the non-single-crystal oxide semiconductors include a CAAC-OS (c-axis-aligned crystalline oxide semiconductor), a polycrystalline oxide semiconductor, an nc-OS (nanocrystalline oxide semiconductor), an amorphous-like oxide semiconductor (a-like OS), and an amorphous oxide semiconductor.

The CAAC-OS has c-axis alignment, a plurality of nanocrystals are connected in the a-b plane direction, and its crystal structure has distortion. Note that the distortion refers to a portion where the direction of a lattice arrangement changes between a region with a regular lattice arrangement and another region with a regular lattice arrangement in a region where the plurality of nanocrystals are connected.

The nanocrystal is basically a hexagon but is not always a regular hexagon and is a non-regular hexagon in some cases. Furthermore, a pentagonal or heptagonal lattice arrangement, for example, is included in the distortion in some cases. Note that a clear crystal grain boundary (also referred to as grain boundary) is difficult to observe even in the vicinity of distortion in the CAAC-OS. That is, formation of a crystal grain boundary is inhibited by the distortion of a lattice arrangement. This is because the CAAC-OS can tolerate distortion owing to a low density of arrangement of oxygen atoms in the a-b plane direction, an interatomic bond length changed by substitution of a metal element, and the like.

Furthermore, the CAAC-OS tends to have a layered crystal structure (also referred to as a layered structure) in which a layer containing indium and oxygen (hereinafter, an In layer) and a layer containing the element M, zinc, and oxygen (hereinafter, (M,Zn) layer) are stacked. Note that indium and the element M can be replaced with each other, and when the element M in the (M,Zn) layer is replaced with indium, the layer can also be referred to as an (In,M,Zn) layer. Furthermore, when indium in the In layer is replaced with the element M, the layer can be referred to as an (In,M) layer.

The CAAC-OS is a metal oxide with high crystallinity. By contrast, in the CAAC-OS, a reduction in electron mobility due to the crystal grain boundary is less likely to occur because it is difficult to observe a clear crystal grain boundary. Furthermore, mixing of impurities, formation of defects, or the like might decrease the crystallinity of a metal oxide, which means that the CAAC-OS is a metal oxide having small amounts of impurities and defects (e.g., oxygen vacancies). Thus, a metal oxide including a CAAC-OS is physically stable. Therefore, the metal oxide including a CAAC-OS is resistant to heat and has high reliability.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor depending on the analysis method.

Note that indium-gallium-zinc oxide (hereinafter referred to as IGZO) that is a kind of metal oxide containing indium, gallium, and zinc has a stable structure in some cases by being formed of the above-described nanocrystals. In some cases, IGZO has a stable structure when formed of smaller crystals (e.g., the above-described nanocrystals) rather than larger crystals (here, crystals with a size of several millimeters or several centimeters) because crystal growth tends to hardly occur particularly in the air.

An a-like OS is a metal oxide having a structure between those of the nc-OS and an amorphous oxide semiconductor. The a-like OS contains a void or a low-density region. That is, the a-like OS has low crystallinity as compared with the nc-OS and the CAAC-OS.

The oxide semiconductor (metal oxide) can have various structures which show different properties. Two or more kinds of the amorphous oxide semiconductor, the polycrystalline oxide semiconductor, the a-like OS, the nc-OS, and the CAAC-OS may be included in the oxide semiconductor of one embodiment of the present invention.

Note that there is no particular limitation on a structure of an oxide semiconductor (metal oxide) in the semiconductor device of one embodiment of the present invention; however, the oxide semiconductor preferably has crystallinity. For example, the oxide 230 can have a CAAC-OS structure. The semiconductor device can have high reliability when the oxide 230 has the above crystal structure.

### [Impurities]

Here, the influence of each impurity in the metal oxide will be described.

When the metal oxide contains an alkali metal or an alkaline earth metal, defect states are formed and carriers are generated, in some cases. Thus, a transistor using a metal oxide that contains an alkali metal or an alkaline earth metal in its channel formation region is likely to have normally-on characteristics. Therefore, it is preferable to reduce the concentration of an alkali metal or an alkaline earth metal in the metal oxide. Specifically, the concentration of an alkali metal or an alkaline earth metal in the metal oxide obtained by SIMS (the concentration obtained by secondary ion mass spectrometry (SIMS)) is set lower than or equal to 1×10¹⁸ atoms/cm³, preferably lower than or equal to 2×10¹⁶ atoms/cm³.

Hydrogen contained in a metal oxide reacts with oxygen bonded to a metal atom to become water, and thus forms an oxygen vacancy, in some cases. When hydrogen enters the oxygen vacancy, an electron which is a carrier is generated in some cases. Furthermore, in some cases, bonding of part of hydrogen to oxygen bonded to a metal atom causes generation of an electron which is a carrier. Thus, a transistor using a metal oxide containing hydrogen is likely to have normally-on characteristics.

Accordingly, hydrogen in the metal oxide is preferably reduced as much as possible. Specifically, the hydrogen concentration of the metal oxide, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³. When a metal oxide in which impurities are sufficiently reduced is used in a channel formation region of a transistor, stable electrical characteristics can be given.

Note that as a metal oxide used for a semiconductor of a transistor, a thin film having high crystallinity is preferably used. With the use of the thin film, the stability or the reliability of the transistor can be improved. Examples of the thin film include a thin film of a single-crystal metal oxide and a thin film of a polycrystalline metal oxide. However, to form the thin film of a single-crystal metal oxide or the thin film of a polycrystalline metal oxide over a substrate, a high-temperature process or a laser heating process is needed. Thus, the manufacturing process cost is increased, and in addition, the throughput is decreased.

Non-Patent Document 1 and Non-Patent Document 2 have reported that, in 2009, an In—Ga—Zn oxide having a CAAC structure (referred to as CAAC-IGZO) was found. It has been reported that CAAC-IGZO has c-axis alignment, a grain boundary is not clearly observed in CAAC-IGZO, and CAAC-IGZO can be formed over a substrate at low temperatures. It has also been reported that a transistor using CAAC-IGZO has excellent electrical characteristics and reliability.

In addition, in 2013, an In—Ga—Zn oxide having an nc structure (referred to as nc-IGZO) was found (see Non-Patent Document 3). It has been reported that nc-IGZO has periodic atomic arrangement in a microscopic region (for example, a region with a size greater than or equal to 1 nm and less than or equal to 3 nm) and there is no regularity of crystal orientation between different regions.

Non-Patent Document 4 and Non-Patent Document 5 have shown a change in average crystal size due to electron beam irradiation to thin films of the above-described CAAC-IGZO, the above nc-IGZO, and IGZO having low crystallinity. In the thin film of IGZO having low crystallinity, crystalline IGZO of approximately 1 nm was observed even before the electron beam irradiation. Thus, it has been reported that the existence of a completely amorphous structure was not observed in IGZO. In addition, it has been shown that the thin film of CAAC-IGZO and the thin film of nc-IGZO each have higher stability to electron beam irradiation than the thin film of IGZO having low crystallinity. Thus, the thin film of CAAC-IGZO or the thin film of nc-IGZO is preferably used for a semiconductor of a transistor.

Non-Patent Document 6 shows that a transistor using a metal oxide has an extremely low leakage current in an off state; specifically, the off-state current per micrometer in the channel width of the transistor is of the order of yA/μm (10⁻²⁴ A/μm). For example, a low-power-consumption CPU (Central Processing Unit) applying a characteristic of low leakage current of the transistor using a metal oxide is disclosed (see Non-Patent Document 7).

Furthermore, application of a transistor using a metal oxide to a display device that utilizes the characteristic of a low leakage current of the transistor has been reported (see Non-Patent Document 8). In the display device, a displayed image is changed several tens of times per second. The number of times an image is changed per second is referred to as a refresh rate. The refresh rate is also referred to as driving frequency. Such high-speed screen change that is hard for human eyes to recognize is considered as a cause of eyestrain. Thus, it is proposed that the refresh rate of the display device is lowered to reduce the number of times of image rewriting. Moreover, driving with a lowered refresh rate enables the power consumption of the display device to be reduced. Such a driving method is referred to as idling stop (IDS) driving.

The discovery of the CAAC structure and the nc structure has contributed to an improvement in electrical characteristics and reliability of a transistor using a metal oxide having the CAAC structure or the nc structure, a reduction in manufacturing cost, and an improvement in throughput. Furthermore, applications of the transistor to a display device and an LSI utilizing the characteristics of a low leakage current of the transistor have been studied.

### <Method for Manufacturing Semiconductor Device>

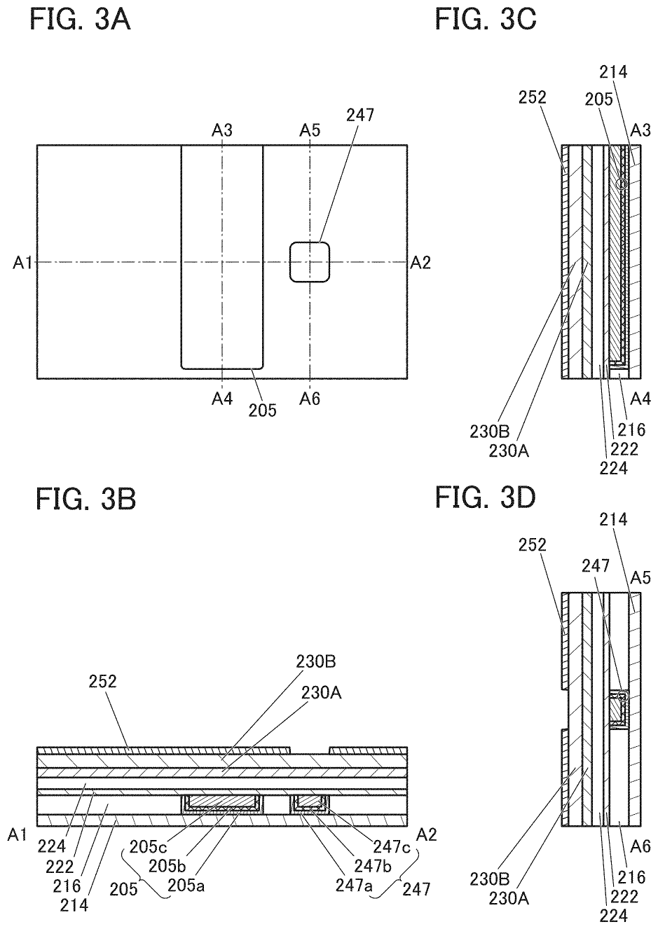

Next, a method for manufacturing the semiconductor device including the transistor 200 according to the present invention, which is illustrated in FIG. 1, will be described with reference to FIG. 3 to FIG. 11. In FIG. 3 to FIG. 11, (A) of each drawing is a top view. Moreover, (B) of each drawing is a cross-sectional view corresponding to a portion indicated by the dashed-dotted line A1-A2 in (A), and is also a cross-sectional view of the transistor 200 in the channel length direction. Furthermore, (C) of each drawing is a cross-sectional view corresponding to a portion indicated by the dashed-dotted line A3-A4 in (A), and is also a cross-sectional view in the channel width direction of the transistor 200. Furthermore, (D) of each drawing is a cross-sectional view corresponding to a portion indicated by the dashed-dotted line A5-A6 in (A), and is also a cross-sectional view of the transistor 200 in the source region or the drain region in the channel width direction. Note that for simplification of the drawings, some components are not illustrated in the top view of (A) of each drawing.

First, a substrate (not illustrated) is prepared, and the insulator 214 is deposited over the substrate. The insulator 214 can be deposited by a sputtering method, a chemical vapor deposition (CVD) method, a molecular beam epitaxy (MBE) method, a pulsed laser deposition (PLD) method, an atomic layer deposition (ALD) method, or the like.

Note that CVD methods can be classified into a plasma enhanced CVD (PECVD) method using plasma, a thermal CVD (TCVD) method using heat, a photo CVD method using light, and the like. Moreover, the CVD methods can be classified into a metal CVD (MCVD) method and a metal organic CVD (MOCVD) method depending on a source gas to be used.

By a plasma CVD method, a high-quality film can be obtained at a relatively low temperature. Furthermore, a thermal CVD method is a deposition method that does not use plasma and thus enables less plasma damage to an object. For example, a wiring, an electrode, an element (e.g., transistor or capacitor), or the like included in a semiconductor device might be charged up by receiving charges from plasma. In this case, accumulated charges might break the wiring, electrode, element, or the like included in the semiconductor device. By contrast, in the case of a thermal CVD method that does not use plasma, such plasma damage is not caused and the yield of the semiconductor device can be increased. Furthermore, a thermal CVD method does not cause plasma damage during deposition, so that a film with few defects can be obtained.

In an ALD method, one atomic layer can be deposited at a time using self-regulating characteristics of atoms. Hence, an ALD method has effects such as deposition of an extremely thin film, deposition on a component with a large aspect ratio, deposition of a film with a small number of defects such as pinholes, deposition with excellent coverage, and low-temperature deposition. An ALD method includes a PEALD (plasma-enhanced ALD) method, which is a deposition method using plasma. The use of plasma is sometimes preferable because deposition at a lower temperature is possible. Note that a precursor used in an ALD method sometimes contains impurities such as carbon. Thus, in some cases, a film provided by an ALD method contains impurities such as carbon in a larger amount than a film provided by another deposition method. Note that impurities can be quantified by X-ray photoelectron spectroscopy (XPS).

Unlike a deposition method in which particles ejected from a target or the like are deposited, a CVD method and an ALD method are deposition methods in which a film is formed by reaction at a surface of an object. Thus, a CVD method and an ALD method are deposition methods that enable favorable step coverage almost regardless of the shape of an object. In particular, an ALD method enables excellent step coverage and excellent thickness uniformity and thus is suitable for covering a surface of an opening portion with a high aspect ratio, for example. On the other hand, an ALD method has a relatively low deposition rate; thus, it is sometimes preferable to combine an ALD method with another deposition method with a high deposition rate such as a CVD method.

A CVD method and an ALD method enable control of the composition of a film to be obtained with a flow rate ratio of the source gases. For example, by a CVD method or an ALD method, a film with a certain composition can be deposited depending on a flow rate ratio of the source gases. Moreover, by a CVD method or an ALD method, by changing the flow rate ratio of the source gases during the deposition, a film whose composition is continuously changed can be deposited. In the case of depositing while changing the flow rate ratio of the source gases, as compared with the case of depositing with the use of a plurality of deposition chambers, time taken for the deposition can be shortened because time taken for transfer and pressure adjustment is omitted. Thus, productivity of semiconductor devices can be improved in some cases.

In this embodiment, for the insulator 214, silicon nitride is deposited by a CVD method. As described here, an insulator through which copper is less likely to pass, such as silicon nitride, is used for the insulator 214; accordingly, even when a metal that is likely to diffuse, such as copper, is used for a conductor in a layer (not illustrated) below the insulator 214, diffusion of the metal into a layer above the insulator 214 can be inhibited.

Next, the insulator 216 is deposited over the insulator 214. The insulator 216 can be deposited by a sputtering method, a CVD method, an MBE method, a PLD method, an ALD method, or the like.

Then, an opening reaching the insulator 214 is formed in the insulator 216. Note that examples of the opening include a groove and a slit. A region where the opening is formed may be referred to as an opening portion. Wet etching can be used for the formation of the openings; however, dry etching is preferably used for microfabrication. As the insulator 214, it is preferable to select an insulator that functions as an etching stopper film used in forming the groove by etching the insulator 216. For example, in the case where a silicon oxide film is used as the insulator 216 in which the groove is to be formed, a silicon nitride film, an aluminum oxide film, or a hafnium oxide film is preferably used as the insulator 214.

After the formation of the opening, a conductive film to be the conductor 205 and the conductor 247 is deposited. The conductive film preferably includes a conductor that has a function of inhibiting the transmission of oxygen. For example, tantalum nitride, tungsten nitride, or titanium nitride can be used. Alternatively, a stacked-layer film with tantalum, tungsten, titanium, molybdenum, aluminum, copper, or a molybdenum-tungsten alloy can be used. The conductive film to be the conductor 205 can be deposited by a sputtering method, a CVD method, an MBE method, a PLD method, an ALD method, or the like.

In this embodiment, the conductive film to be the conductor 205 and the conductor 247 has a multilayer structure. First, tantalum nitride is deposited as a conductive film to be the conductor 205a and the conductor 247a by a sputtering method, and titanium nitride is stacked as a conductive film to be the conductor 205b and the conductor 247b over the tantalum nitride. Even when a metal that is likely to diffuse, such as copper, is used for a conductive film to be a conductor 205c and a conductor 247c described below, the use of such metal nitrides for a lower layer of the conductive film to be the conductor 205 can prevent outward diffusion of the metal from the conductor 205.

Next, the conductive film to be the conductor 205c and the conductor 247c is deposited. The conductive film can be deposited by a plating method, a sputtering method, a CVD method, an MBE method, a PLD method, an ALD method, or the like. In this embodiment, for the conductive film to be the conductor 205c and the conductor 247c, a low-resistance conductive material such as tungsten or copper is deposited.

Next, CMP treatment is performed to remove part of the conductive film to be the conductor 205 and the conductor 247, so that the insulator 216 is exposed. As a result, the conductive film to be the conductor 205 and the conductive film to be the conductor 247 remain only in the opening portions. Thus, the conductor 205 and the conductor 247 whose top surfaces are flat can be formed. Note that the insulator 216 is partly removed by the CMP treatment in some cases (see FIG. 3).

Here, a method for forming the conductor 205 and the conductor 247 which are different from the above will be described below.

The conductive film to be the conductor 205 and the conductor 247 is deposited over the insulator 214. The conductive film can be deposited by a sputtering method, a CVD method, an MBE method, a PLD method, an ALD method, or the like. In addition, the conductive film can be a multilayer film. In this embodiment, tungsten is deposited for the conductive film.

Next, the conductive film is processed by a lithography method to form the conductor 205 and the conductor 247.

In the lithography method, first, a resist is exposed to light through a mask. Next, a region exposed to light is removed or left using a developing solution, so that a resist mask is formed. Then, etching treatment through the resist mask is conducted, whereby a conductor, a semiconductor, an insulator, or the like can be processed into a desired shape. The resist mask is formed by, for example, exposure of the resist to light using KrF excimer laser light, ArF excimer laser light, EUV (Extreme Ultraviolet) light, or the like. Alternatively, a liquid immersion technique may be employed in which a portion between a substrate and a projection lens is filled with liquid (e.g., water) to perform light exposure. An electron beam or an ion beam may be used instead of the above-mentioned light. Note that a mask is not necessary in the case of using an electron beam or an ion beam. Note that the resist mask can be removed by dry etching treatment such as ashing, wet etching treatment, wet etching treatment after dry etching treatment, or dry etching treatment after wet etching treatment.

A hard mask formed of an insulator or a conductor may be used instead of the resist mask. In the case where a hard mask is used, a hard mask with a desired shape can be formed by forming an insulating film or a conductive film that is the hard mask material over the conductive film to be the conductor 205 and the conductor 247, forming a resist mask thereover, and then etching the hard mask material. The etching of the conductive film to be the conductor 205 and the conductor 247 may be performed after removal of the resist mask or with the resist mask remaining. In the latter case, the resist mask sometimes disappears during the etching. The hard mask may be removed by etching after the etching of the conductive film. The hard mask does not need to be removed in the case where the material of the hard mask does not affect the following process or can be utilized in the following process.

As a dry etching apparatus, a capacitively coupled plasma (CCP) etching apparatus including parallel plate type electrodes can be used. The capacitively coupled plasma etching apparatus including the parallel plate type electrodes may have a structure in which a high-frequency power is applied to one of the parallel plate type electrodes. Alternatively, a structure may be employed in which different high-frequency powers are applied to one of the parallel plate type electrodes. Alternatively, a structure may be employed in which high-frequency power sources with the same frequency are applied to the parallel plate type electrodes. Alternatively, a structure may be employed in which high-frequency power sources with different frequencies are applied to the parallel plate type electrodes. Alternatively, a dry etching apparatus including a high-density plasma source can be used. As the dry etching apparatus including a high-density plasma source, an inductively coupled plasma (ICP) etching apparatus can be used, for example.

Next, an insulating film to be the insulator 216 is deposited over the insulator 214, the conductor 205, and the conductor 247. The insulator to be insulator 216 can be deposited by a sputtering method, a CVD method, an MBE method, a PLD method, an ALD method, or the like. In this embodiment, for the insulating film to be insulator 216, silicon oxide is deposited by a CVD method.

Here, the thickness of the insulating film to be the insulator 216 is preferably greater than or equal to the thickness of the conductor 205 and the conductor 247. For example, when the thickness of the conductor 205 and the conductor 247 is 1, the thickness of the insulating film to be the insulator 216 is greater than or equal to 1 and less than or equal to 3. In this embodiment, the thickness of the thickness of the conductor 205 and the conductor 247 is 150 nm and the thickness of the insulating film to be the insulator 216 is 350 nm.

Next, CMP treatment is performed on the insulating film to be the insulator 216, so that part of the insulating film to be the insulator 216 is removed and surfaces of the conductor 205 and the conductor 247 are exposed. Thus, the conductor 205, the conductor 247, and the insulator 216 whose top surfaces are flat can be formed. The above is another method for forming the conductor 205 and the conductor 247.

Next, the insulator 222 is deposited over the insulator 216, the conductor 205, and the conductor 247. An insulator containing an oxide of one or both of aluminum and hafnium is preferably deposited as the insulator 222. Note that as the insulator containing an oxide of one or both of aluminum and hafnium, aluminum oxide, hafnium oxide, an oxide containing aluminum and hafnium (hafnium aluminate), or the like is preferably used. The insulator containing an oxide of one or both of aluminum and hafnium has a barrier property against oxygen, hydrogen, and water. When the insulator 222 has a barrier property against hydrogen and water, hydrogen and water contained in structure bodies provided around the transistor 200 are inhibited from diffusing into the transistor 200 through the insulator 222, and generation of oxygen vacancies in the oxide 230 can be inhibited.

The insulator 222 can be deposited by a sputtering method, a CVD method, an MBE method, a PLD method, an ALD method, or the like.

Then, the insulator 224 is deposited over the insulator 222. The insulator 224 can be deposited by a sputtering method, a CVD method, an MBE method, a PLD method, an ALD method, or the like.

Sequentially, heat treatment is preferably performed. The heat treatment may be performed at a temperature higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen atmosphere, an inert gas atmosphere, or an atmosphere containing an oxidizing gas at 10 ppm or more, 1% or more, or 10% or more. Alternatively, the heat treatment may be performed under reduced pressure. Alternatively, the heat treatment may be performed in such a manner that heat treatment is performed in a nitrogen atmosphere or an inert gas atmosphere, and then another heat treatment is performed in an atmosphere containing an oxidizing gas at 10 ppm or more, 1% or more, or 10% or more in order to compensate for released oxygen.

In this embodiment, treatment is performed at 400° C. in a nitrogen atmosphere for an hour, and successively another treatment is performed at 400° C. in an oxygen atmosphere for an hour. By the heat treatment, impurities such as water and hydrogen included in the insulator 224 can be removed.

The above heat treatment may be performed after the insulator 222 is deposited. For the heat treatment, the conditions for the above-described heat treatment can be used.

Here, plasma treatment containing oxygen may be performed under reduced pressure so that an excess-oxygen region can be formed in the insulator 224. The plasma treatment containing oxygen is preferably performed using an apparatus including a power source for generating high-density plasma using microwaves, for example. Alternatively, a power source for applying an RF (Radio Frequency) to a substrate side may be included. The use of high-density plasma enables high-density oxygen radicals to be produced, and RF application to the substrate side allows the oxygen radicals generated by the high-density plasma to be efficiently introduced into the insulator 224. Alternatively, after plasma treatment containing an inert gas is performed with this apparatus, plasma treatment containing oxygen may be performed to compensate for released oxygen. Note that impurities such as water and hydrogen included in the insulator 224 can be removed by selecting the conditions for the plasma treatment appropriately. In that case, the heat treatment is not necessarily performed.

Here, aluminum oxide may be deposited over the insulator 224 by a sputtering method and the aluminum oxide may be subjected to CMP until the insulator 224 is reached. The CMP treatment can planarize the surface of the insulator 224 and smooth the surface of the insulator 224. When the CMP treatment is performed on the aluminum oxide placed over the insulator 224, it is easy to detect the endpoint of CMP. Although part of the insulator 224 is polished by CMP and the thickness of the insulator 224 is reduced in some cases, the thickness can be adjusted when the insulator 224 is deposited. Planarizing and smoothing the surface of the insulator 224 can improve the coverage with an oxide deposited later and a decrease in the yield of the semiconductor device in some cases. The deposition of aluminum oxide over the insulator 224 by a sputtering method is preferred because oxygen can be added to the insulator 224.

Next, an oxide film 230A and an oxide film 230B are deposited in this order over the insulator 224 (see FIG. 3). Note that the oxide films are preferably deposited successively without exposure to an air atmosphere. By the deposition without exposure to the air, impurities or moisture from the air atmosphere can be prevented from being attached to the top surfaces of the oxide film 230A and the oxide film 230B, so that the vicinity of an interface between the oxide film 230A and the oxide film 230B can be kept clean.

The oxide film 230A and the oxide film 230B can be deposited by a sputtering method, a CVD method, an MBE method, a PLD method, an ALD method, or the like.

In the case where the oxide film 230A and the oxide film 230B are deposited by a sputtering method, for example, oxygen or a mixed gas of oxygen and a rare gas is used as a sputtering gas. The amount of excess oxygen in the oxide film to be deposited can be increased by an increase in the proportion of oxygen contained in the sputtering gas. In the case where the above oxide films are deposited by a sputtering method, the above In-M-Zn oxide target can be used.

In particular, when the oxide film 230A is deposited, part of oxygen included in the sputtering gas is supplied to the insulator 224 in some cases. Therefore, the proportion of oxygen included in the sputtering gas for the oxide film 230A is preferably 70% or higher, further preferably 80% or higher, and still further preferably 100%.

In the case where the oxide film 230B is formed by a sputtering method, when the proportion of oxygen included in the sputtering gas is higher than or equal to 1% and lower than or equal to 30%, preferably higher than or equal to 5% and lower than or equal to 20% during the deposition, an oxygen-deficient oxide semiconductor is formed. In a transistor using an oxygen-deficient oxide semiconductor for its channel formation region, relatively high field-effect mobility can be obtained.

In this embodiment, the oxide film 230A is deposited by a sputtering method using a target with In:Ga:Zn=1:1:0.5 [atomic ratio] (2:2:1 [atomic ratio]) or a target with In:Ga:Zn=1:3:4 [atomic ratio]. The oxide film 230B is deposited by a sputtering method using a target with In:Ga:Zn=4:2:4.1 [atomic ratio] or 1:1:1 [atomic ratio]. Note that each of the oxide films is preferably formed to have characteristics required for the oxide 230 by appropriate selection of deposition conditions and an atomic ratio.

Next, heat treatment may be performed. For the heat treatment, the conditions for the above-described heat treatment can be used. Through the heat treatment, impurities such as water and hydrogen in the oxide film 230A and the oxide film 230B can be removed, for example. In this embodiment, treatment is performed at 400° C. in a nitrogen atmosphere for an hour, and successively another treatment is performed at 400° C. in an oxygen atmosphere for an hour.

Then, a mask 252 is formed over the oxide film 230B (see FIG. 3). A resist mask or a hard mask can be used as the mask 252.

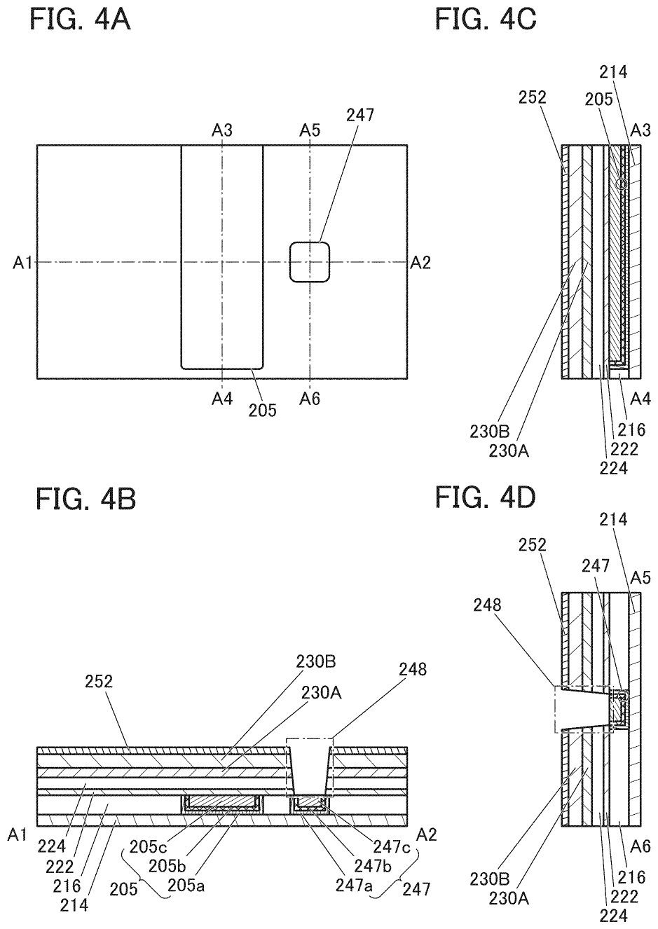

Next, the opening 248 through which at least part of the conductor 247 is exposed is formed in the oxide film 230B, the oxide film 230A, the insulator 224, and the insulator 222 using the mask 252 (see FIG. 4). Wet etching can be used for the formation of the opening 248; however, dry etching is preferably used for microfabrication.

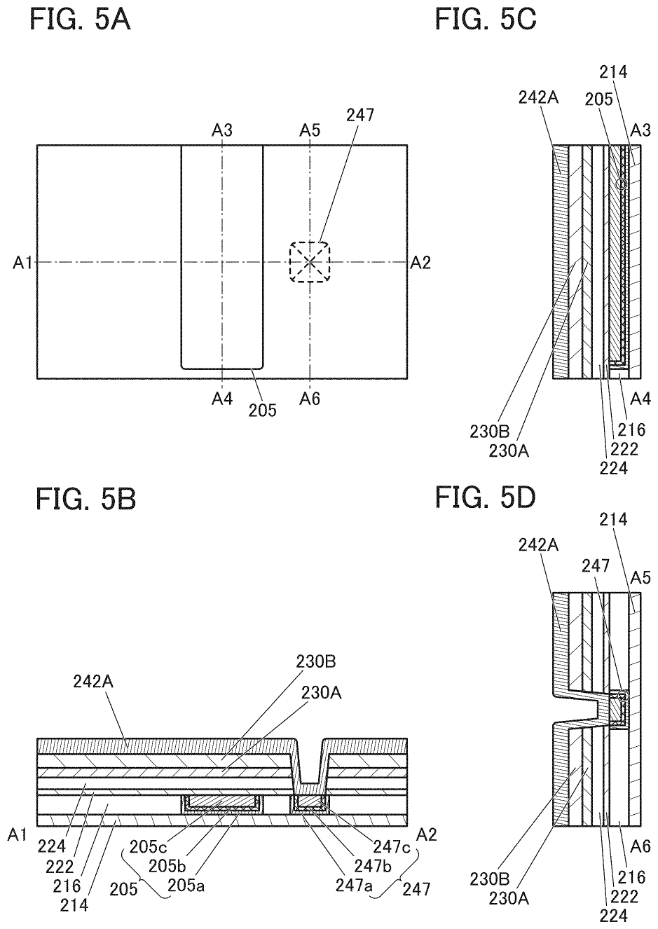

Then, the mask 252 is removed and a conductive film 242A is formed over the oxide film 230B. The conductive film 242A is in contact with the conductor 247 in the opening 248. The conductive film 242A can be deposited by a sputtering method, a CVD method, an MBE method, a PLD method, an ALD method, or the like (see FIG. 5).

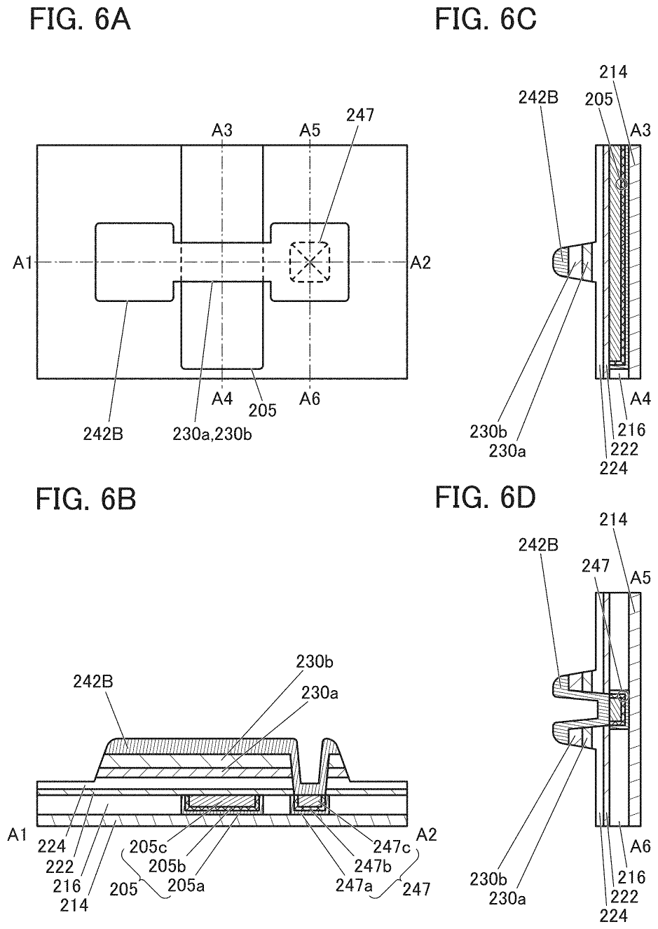

Next, the oxide film 230A, the oxide film 230B, and the conductive film 242A are processed into island shapes to form the oxide 230a, the oxide 230b, and a conductor layer 242B (see FIG. 6). Note that in this step, the thickness of a region of the insulator 224 which does not overlap with the oxide 230a becomes small in some cases.

Note that the oxide 230a, the oxide 230b, and the conductor layer 242B are formed to at least partly overlap with the conductor 205. It is preferable that the side surfaces of the oxide 230a, the oxide 230b, and the conductor layer 242B be substantially perpendicular to the top surface of the insulator 222. When the side surfaces of the oxide 230a, the oxide 230b, and the conductor layer 242B are substantially perpendicular to the top surface of the insulator 222, the plurality of transistors 200 can be provided in a smaller area and at a higher density. Alternatively, a structure may be employed in which an angle formed by the side surfaces of the oxide 230a, the oxide 230b, and the conductor layer 242B and the top surface of the insulator 222 is a small angle. In that case, the angle formed by the side surfaces of the oxide 230a, the oxide 230b, and the conductor layer 242B and the top surface of the insulator 222 is preferably greater than or equal to 60° and less than 70°. With such a shape, the coverage with the insulator 256 and the like can be improved in a later step, so that defects such as a void can be reduced.

Note that for the processing of the oxide films and the conductive film, a lithography method can be employed. The processing can be performed by a dry etching method or a wet etching method. The processing by a dry etching method is suitable for microfabrication.

It is preferable that there be a curved surface between the side surface of the conductor layer 242B and the top surface of the conductor layer 242B. That is, an end portion of the side surface and an end portion of the top surface are preferably curved (hereinafter such a curved shape is also referred to as a rounded shape). The radius of curvature of the curved surface at an end portion of the conductor layer 242B is greater than or equal to 3 nm and less than or equal to 10 nm, preferably greater than or equal to 5 nm and less than or equal to 6 nm, for example. When the end portions are not angular, the coverage with films deposited in a later step can be improved.

Note that for the processing of the conductive film, a lithography method can be employed. The processing can be performed by a dry etching method or a wet etching method. The processing by a dry etching method is suitable for microfabrication.

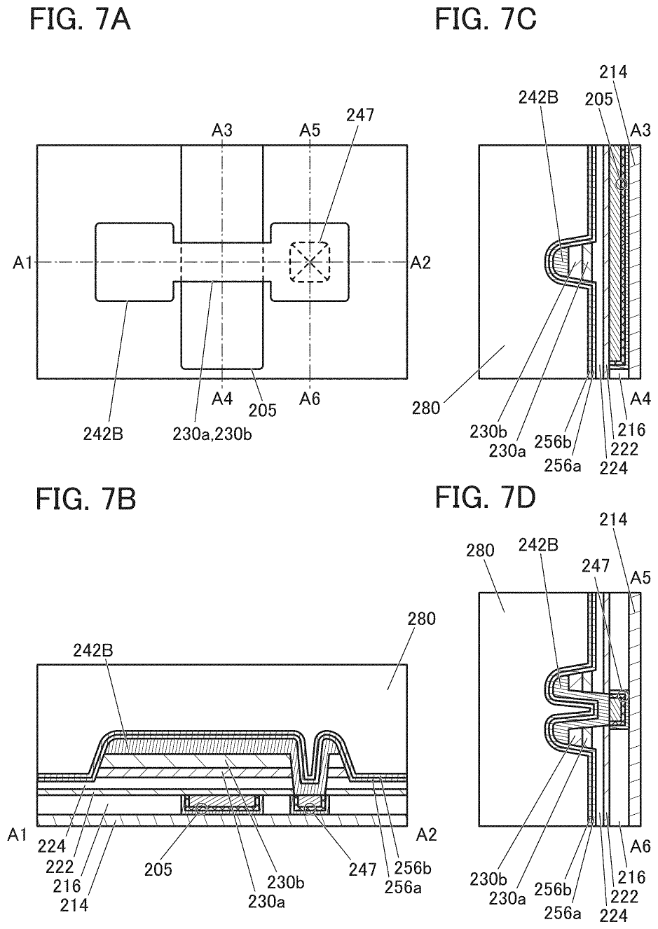

Next, the insulator 256 is deposited over the insulator 224, the oxide 230a, the oxide 230b, and the conductor layer 242B (see FIG. 7).

The insulator 256 can be deposited by a sputtering method, a CVD method, an MBE method, a PLD method, an ALD method, or the like. As the insulator 256, an insulating film having a function of inhibiting the transmission of oxygen is preferably used. For example, silicon nitride, silicon oxide, or aluminum oxide is deposited by a sputtering method. A material that can be used for the oxide 230a and the oxide 230b can be used for the insulator 256. For example, a metal oxide with In:Ga:Zn=1:3:4 [atomic ratio] or 1:1:0.5 [atomic ratio] is preferably used for the insulator 256.

The insulator 256 may have a stacked-layer structure including the insulator 256a and the insulator 256b. The insulator 256a and the insulator 256b can be deposited by the above-described methods, and the insulator 256a and the insulator 256b may be deposited by the same method or different methods. Furthermore, the above-described materials can be used for the insulator 256a and the insulator 256b, and the same material or different materials may be used for the insulator 256a and the insulator 256b. For example, it is preferable that an aluminum oxide film be deposited by a sputtering method as the insulator 256a and an aluminum oxide film be deposited by an ALD method as the insulator 256b. Alternatively, an aluminum oxide film may be deposited by a sputtering method as the insulator 256a and a silicon nitride film may be deposited by an ALD method as the insulator 256b (see FIG. 7).

Next, an insulating film to be the insulator 280 is deposited over the insulator 256. The insulating film to be the insulator 280 can be deposited by a sputtering method, a CVD method, an MBE method, a PLD method, an ALD method, or the like. In order that the insulator 280 contain a larger amount of oxygen, the deposition gas used for forming the insulator 280 preferably contains oxygen. In order that the hydrogen concentration of the insulator 280 be reduced, the deposition gas used for forming the insulator 280 preferably contains no hydrogen or contains hydrogen as little as possible. For example, it is preferable to deposit silicon oxide using a target containing silicon or silicon oxide and gas containing argon or oxygen. The insulator 280 may have a stacked-layer structure of two or more layers, in which case silicon oxide deposited by a sputtering method is used as the first layer and silicon oxynitride deposited by a CVD method is used as the second layer. Next, the insulating film to be the insulator 280 is subjected to CMP treatment, so that the insulator 280 having a flat top surface is formed (see FIG. 7).

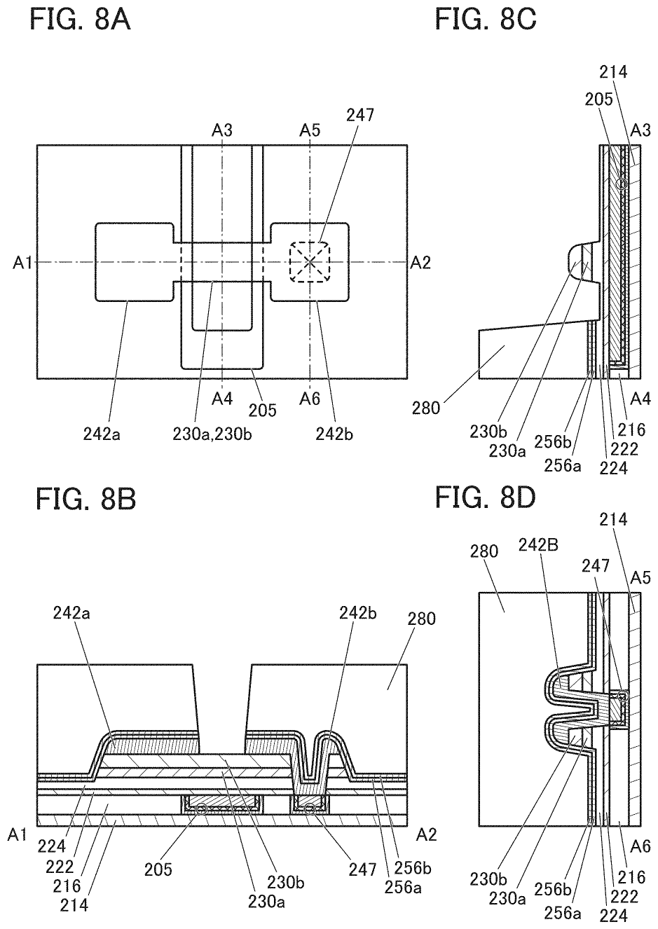

Next, part of the insulator 280, part of the insulator 256, and part of the conductor layer 242B are processed to form an opening from which the oxide 230b is exposed. The opening is preferably formed to overlap with the conductor 205. The conductor 242a and the conductor 242b are formed by the formation of the opening. In addition, formation of the opening decreases the thickness of part of the insulator 224 in some cases (see FIG. 8). Furthermore, in some cases, the top surface of the oxide 230b that is exposed through the region between the conductor 242a and the conductor 242b is partly removed.

Part of the insulator 280, part of the insulator 256, and part of the conductor layer 242B may be processed under different conditions. For example, part of the insulator 280 may be processed by a dry etching method, part of the insulator 256 may be processed by a wet etching method, and part of the conductor layer 242B may be processed by a dry etching method.

At this time, the opening formed in the insulator 280 overlaps with a region between the conductor 242a and the conductor 242b. In this manner, the conductor 260 can be positioned between the conductor 242a and the conductor 242b in a self-aligned manner in a later step.

In some cases, the treatment such as dry etching causes the attachment or diffusion of impurities due to an etching gas or the like to a surface or an inside of the oxide 230a, the oxide 230b, or the like. Examples of the impurities include fluorine and chlorine.

In order to remove the above impurities and the like, cleaning is performed. Examples of the cleaning method include wet cleaning using a cleaning solution, plasma treatment using plasma, and cleaning by heat treatment, and any of these cleanings may be performed in appropriate combination.

The wet cleaning may be performed using an aqueous solution in which oxalic acid, phosphoric acid, ammonia water, hydrofluoric acid, or the like is diluted with carbonated water or pure water. Alternatively, ultrasonic cleaning using pure water or carbonated water may be performed.

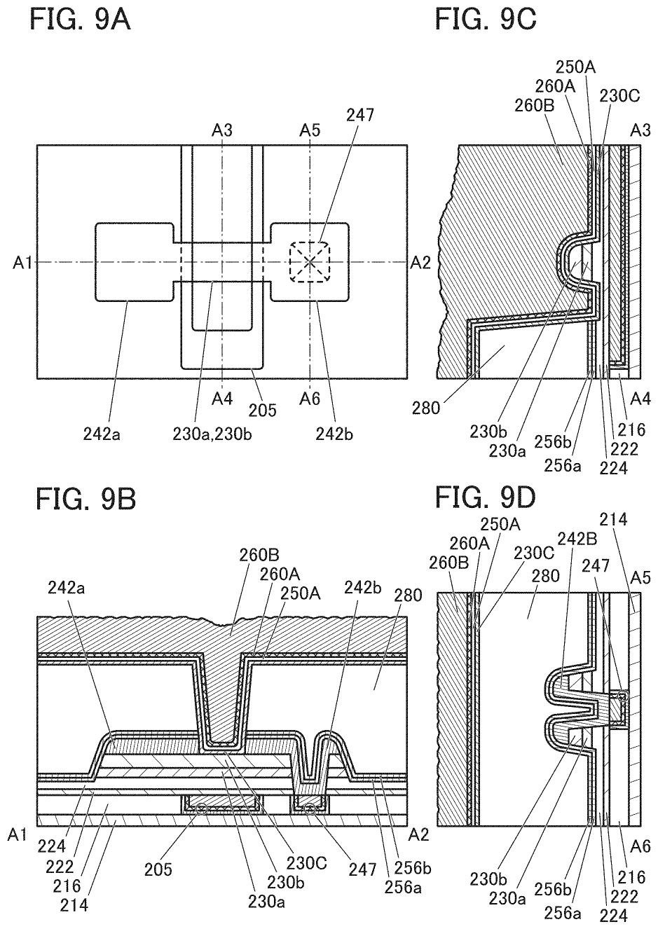

Next, heat treatment may be performed. Heat treatment may be performed under reduced pressure, and an oxide film 230C may be successively deposited without exposure to the air. The treatment can remove moisture and hydrogen adsorbed onto the surface of the oxide 230b and the like, and further can reduce the moisture concentration and the hydrogen concentration of the oxide 230a and the oxide 230b. The heat treatment is preferably performed at a temperature higher than or equal to 100° C. and lower than or equal to 400° C. In this embodiment, the heat treatment is performed at 200° C. (see FIG. 9).

It is preferable that the oxide film 230C be provided in contact with at least part of the side surface of the oxide 230a, part of the top and side surfaces of the oxide 230b, part of the side surfaces of the conductors 242, the side surfaces of the insulator 256, and the side surfaces of the insulator 280. When the conductors 242 are surrounded by the insulator 256 and the oxide film 230C, a decrease in the conductivity of the conductors 242 due to oxidation in a later step can be inhibited.

The oxide film 230C can be deposited by a sputtering method, a CVD method, an MBE method, a PLD method, an ALD method, or the like. The oxide film 230C is deposited by a method similar to that for the oxide film to be the oxide film 230A or the oxide film 230B in accordance with characteristics required for the oxide film 230C. In this embodiment, the oxide film 230C is deposited by a sputtering method using a target with In:Ga:Zn=1:3:4 [atomic ratio] or In:Ga:Zn=4:2:4.1 [atomic ratio].

The oxide film 230C may have a stacked-layer structure. For example, the oxide film 230C may be deposited by a sputtering method using a target of In:Ga:Zn=4:2:4.1 [atomic ratio] and successively deposited using a target of In:Ga:Zn=1:3:4 [atomic ratio].

In particular, when the oxide film 230C is deposited, part of oxygen included in the sputtering gas is supplied to the oxide 230a and the oxide 230b in some cases. Therefore, the proportion of oxygen included in the sputtering gas for the oxide film 230C is preferably 70% or higher, further preferably 80% or higher, and still further preferably 100%.

Next, heat treatment may be performed. Heat treatment may be performed under reduced pressure, and the insulating film 250A may be successively deposited without exposure to the air. The treatment can remove moisture and hydrogen adsorbed onto the surface onto the surface of the oxide film 230C and the like, and further can reduce the moisture concentration and the hydrogen concentration of the oxide 230a, the oxide 230b, and the oxide film 230C. The heat treatment is preferably performed at a temperature higher than or equal to 100° C. and lower than or equal to 400° C. (see FIG. 9).

The insulating film 250A can be deposited by a sputtering method, a CVD method, an MBE method, a PLD method, an ALD method, or the like. For the insulating film 250A, silicon oxynitride is preferably deposited by a CVD method. Note that the deposition temperature at the time of the deposition of the insulating film 250A is preferably higher than or equal to 350° C. and lower than 450° C., particularly preferably approximately 400° C. When the insulating film 250A is deposited at 400° C., an insulator having few impurities can be deposited.

Next, a conductive film 260A and a conductive film 260B are deposited. The conductive film 260A and the conductive film 260B can be deposited by a sputtering method, a CVD method, an MBE method, a PLD method, an ALD method, or the like. For example, a CVD method is preferably used. In this embodiment, the conductive film 260A is deposited by an ALD method, and the conductive film 260B is deposited by a CVD method (see FIG. 9).

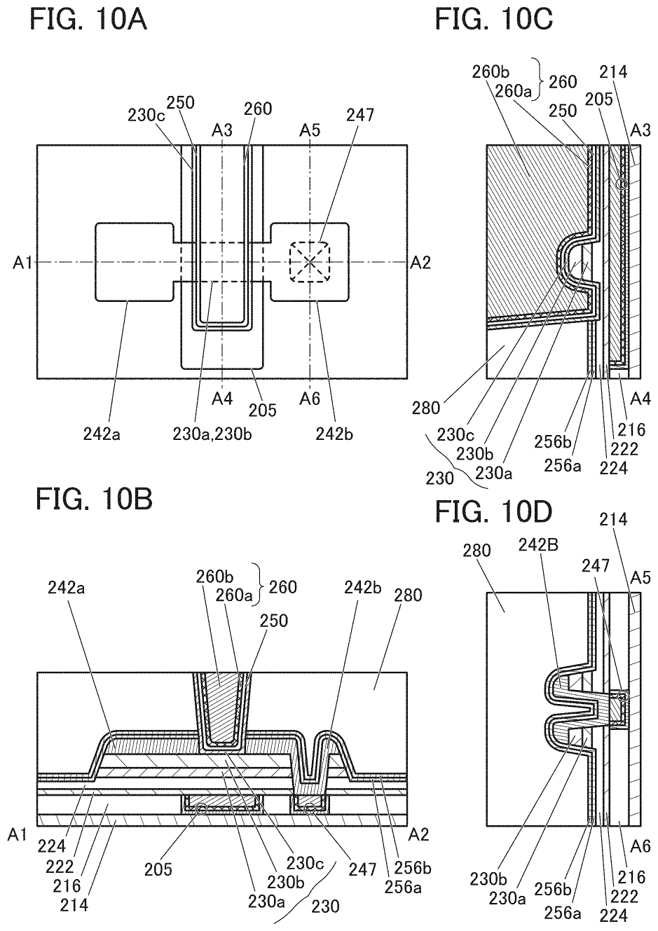

Then, the oxide film 230C, the insulating film 250A, the conductive film 260A, and the conductive film 260B are polished by CMP treatment until the insulator 280 is exposed, whereby the oxide 230c, the insulator 250, and the conductor 260 (the conductor 260a and the conductor 260b) are formed (see FIG. 10).

Since the conductors 242 are provided to be surrounded by the insulator 256 and the oxide 230c, a decrease in the conductivity of the conductors 242 due to oxidation can be inhibited.

Next, heat treatment may be performed. In this embodiment, the treatment is performed at 400° C. in a nitrogen atmosphere for an hour. The heat treatment can reduce the moisture concentration and the hydrogen concentration in the insulator 250 and the insulator 280.

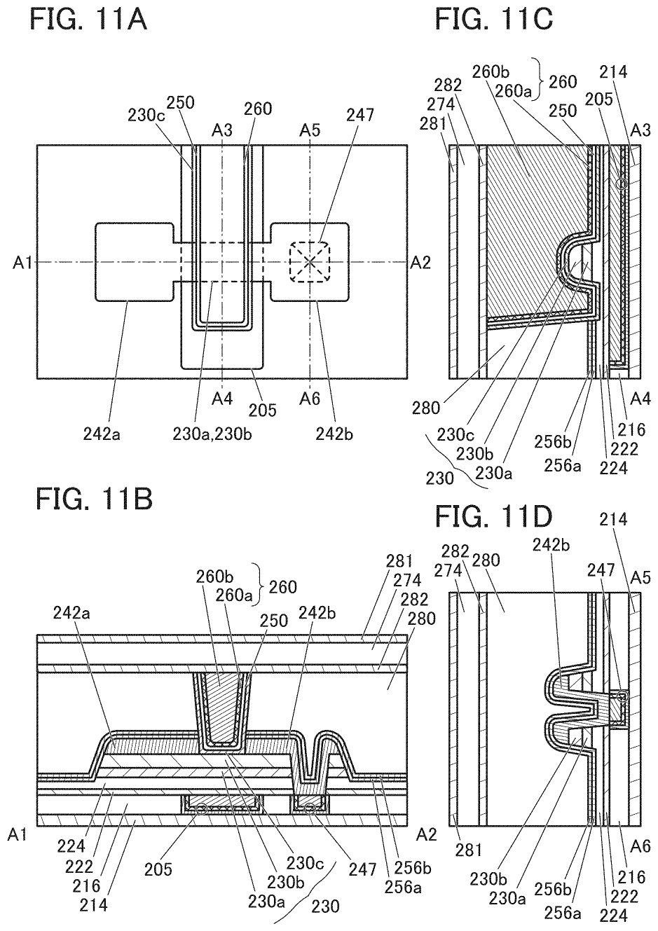

Next, an insulating film to be the insulator 282 may be formed over the conductor 260, the oxide 230c, the insulator 250, and the insulator 280. The insulating film to be the insulator 282 can be deposited by a sputtering method, a CVD method, an MBE method, a PLD method, an ALD method, or the like. An aluminum oxide is preferably deposited as the insulating film to be the insulator 282 by a sputtering method, for example. It is preferable to form the insulator 282 in contact with the top surface of the conductor 260 in this manner because oxygen included in the insulator 280 can be inhibited from being absorbed into the conductor 260 in a later heat treatment (see FIG. 11).

Next, heat treatment may be performed. In this embodiment, the treatment is performed at 400° C. in a nitrogen atmosphere for an hour. By the heat treatment, oxygen added by the deposition of the insulator 282 can be injected into the insulator 280. In addition, the oxygen can be injected into the oxide 230a and the oxide 230b through the oxide 230c.

Next, an insulator to be the insulator 274 may be deposited over the insulator 282. The insulating film to be the insulator 274 can be deposited by a sputtering method, a CVD method, an MBE method, a PLD method, an ALD method, or the like (see FIG. 11).

Next, an insulator to be the insulator 281 may be deposited over the insulator 274. An insulating film to be the insulator 281 can be deposited by a sputtering method, a CVD method, an MBE method, a PLD method, an ALD method, or the like. Silicon nitride is preferably deposited as the insulating film to be the insulator 281 by a sputtering method, for example (see FIG. 11).

Then, an opening that reaches the conductor 242a is formed in the insulator 256, the insulator 280, the insulator 282, the insulator 274, and the insulator 281. The opening is formed by a lithography method.

Next, an insulating film to be the insulator 241 is deposited and the insulating film is subjected to anisotropic etching, so that the insulator 241 is formed. The insulating film can be deposited by a sputtering method, a CVD method, an MBE method, a PLD method, an ALD method, or the like. As the insulating film to be the insulator 241, an insulating film having a function of inhibiting transmission of oxygen is preferably used. For example, aluminum oxide or silicon nitride is preferably deposited by an ALD method. For the anisotropic etching, a dry etching method or the like is performed, for example. When the sidewall portion of the opening have such a structure, transmission of oxygen from the outside can be inhibited and oxidation of the formed conductor 240 can be prevented. Furthermore, impurities such as water and hydrogen can be prevented from diffused from the conductor 240 to the outside.

Next, a conductive film to be the conductor 240 is deposited. The conductive film to be the conductor 240 desirably has a stacked-layer structure which includes a conductor having a function of inhibiting transmission of impurities such as water and hydrogen. For example, a stacked layer of tantalum nitride, titanium nitride, or the like and tungsten, molybdenum, copper, or the like can be employed. The conductive film to be the conductor 240 can be deposited by a sputtering method, a CVD method, an MBE method, a PLD method, an ALD method, or the like.

Next, CMP treatment is performed to remove part of the conductive film to be the conductor 240, so that the insulator 281 is exposed. As a result, the conductive film remains only in the opening, so that the conductor 240 having a planar top surface can be formed (see FIG. 1). Note that the insulator 281 is partly removed by the CMP treatment in some cases.

A conductor electrically connected to the conductor 240 may be formed. A conductor which is in contact with the top surface of the conductor 240 can be formed by forming a conductive film by a sputtering method, a CVD method, an MBE method, a PLD method, an ALD method, or the like and then processing the conductive film by a lithography method.

Through the above process, the semiconductor device including the transistor 200 illustrated in FIG. 1 can be manufactured. As illustrated in FIG. 3 to FIG. 11, with the use of the method of manufacturing the semiconductor device described in this embodiment, the transistor 200 can be manufactured.

According to one embodiment of the present invention, a semiconductor device that can be miniaturized or highly integrated can be provided. Alternatively, according to one embodiment of the present invention, a semiconductor device having favorable electrical characteristics can be provided. Alternatively, according to one embodiment of the present invention, a semiconductor device having a high on-state current can be provided. Alternatively, according to one embodiment of the present invention, a semiconductor device having excellent frequency characteristics can be provided. Alternatively, according to one embodiment of the present invention, a semiconductor device having favorable reliability can be provided. Alternatively, according to one embodiment of the present invention, a semiconductor device with a low off-state current can be provided. Alternatively, according to one embodiment of the present invention, a semiconductor device with reduced power consumption can be provided. Alternatively, according to one embodiment of the present invention, a semiconductor device having high productivity can be provided.

### <Modification Example of Semiconductor Device>

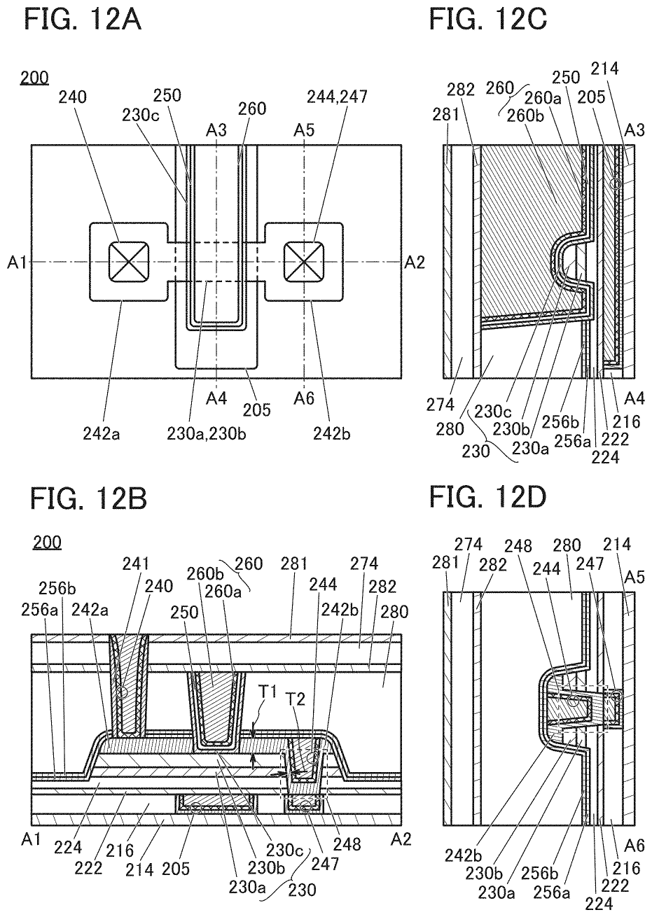

Examples of a semiconductor device including the transistor 200 of one embodiment of the present invention, which are different from the semiconductor device described in <Structure example of semiconductor device> above, will be described below with reference to FIG. 12 to FIG. 19.

In FIG. 12 to FIG. 19, (A) of each drawing is a top view. Moreover, (B) of each drawing is a cross-sectional view corresponding to a portion indicated by the dashed-dotted line A1-A2 in (A), and is also a cross-sectional view of the transistor 200 in the channel length direction. Furthermore, (C) of each drawing is a cross-sectional view corresponding to a portion indicated by the dashed-dotted line A3-A4 in (A), and is also a cross-sectional view in the channel width direction of the transistor 200. Furthermore, (D) of each drawing is a cross-sectional view corresponding to a portion indicated by the dashed-dotted line A5-A6 in (A), and is also a cross-sectional view of the transistor 200 in a source region or a drain region in the channel width direction. For simplification of the drawings, some components are not illustrated in the top view of (A) of each drawing.

Note that in semiconductor devices illustrated in FIG. 12 to FIG. 19, components having the same functions as the components in the semiconductor device described in <Structure example of semiconductor device> (see FIG. 12) are denoted by the same reference numerals. Note that in this section, the materials described in detail in <Structure example of semiconductor device> can be used as the constituent materials for the transistor 200.

### <Modification Example 1 of Semiconductor Device>

A semiconductor device illustrated in FIG. 12 includes the insulator 214 over a substrate (not illustrated), the transistor 200 over the insulator 214, the insulator 280 over the transistor 200, the insulator 282 over the insulator 280, the insulator 274 over the insulator 282, and the insulator 281 over the insulator 274. The insulator 214, the insulator 280, the insulator 282, the insulator 274, and the insulator 281 function as interlayer films. In addition, the conductor 247 is provided so as to be embedded in the insulator 216 provided over the insulator 214. The conductor 247 is electrically connected to the transistor 200 and functions as a plug. Furthermore, the conductor 240 that is electrically connected to the transistor 200 and functions as a plug is provided. Note that the insulator 241 is provided in contact with a side surface of the conductor 240 functioning as a plug.

As illustrated in FIG. 12, the transistor 200 includes the insulator 216 over the insulator 214; the conductor 205 (the conductor 205a and the conductor 205b) positioned so as to be embedded in the insulator 216; the insulator 222 over the insulator 216 and the conductor 205; the insulator 224 over the insulator 222; the oxide 230a over the insulator 224; the oxide 230b over the oxide 230a; the conductor 242a and the conductor 242b over the oxide 230b; the oxide 230c over the oxide 230b; the insulator 250 over the oxide 230c; the conductor 260 (the conductor 260a and the conductor 260b) positioned over the insulator 250 and overlapping with the oxide 230c; and the insulator 256a and the insulator 256b in contact with part of the top surface of the insulator 224, a side surface of the oxide 230a, a side surface of the oxide 230b, a side surface of the conductor 242a, the top surface of the conductor 242a, a side surface of the conductor 242b, and the top surface of the conductor 242b. The oxide 230c is in contact with a side surface of the conductor 242a and a side surface of the conductor 242b. The conductor 260 includes the conductor 260a and the conductor 260b, and the conductor 260a is positioned so as to cover the bottom surface and a side surface of the conductor 260b. Here, as illustrated in FIG. 12(B), the top surface of the conductor 260 is substantially level with the top surface of the insulator 250 and the top surface of the oxide 230c. The insulator 282 is in contact with the top surface of each of the conductor 260, the oxide 230c, the insulator 250, and the insulator 280.

An opening is formed in the insulator 216, and the conductor 247 described above is positioned in the opening. It is preferable that at least part of the top surface of the conductor 247 be exposed from the insulator 216, and the top surface of the conductor 247 and the top surface of the insulator 216 be substantially level with each other.

Furthermore, the opening 248 through which at least part of the conductor 247 is exposed is formed in the insulator 222, the insulator 224, the oxide 230a, and the oxide 230b.

The conductor 242b is positioned over the oxide 230b and is in contact with at least part of the top surface of the conductor 247 through the opening 248. When the conductor 242b and the conductor 247 are connected to each other as described here, electrical resistance between the conductor 247 and a source or a drain of the transistor 200 can be reduced.

Note that the conductor 242b is preferably provided to be in contact with a side surface of the oxide 230a and a side surface of the oxide 230b in the opening 248.

Here, a depression portion is formed in a portion of the conductor 242b that overlaps with the opening 248, along the shape of the opening 248. A thickness T2 of the conductor 242b in a portion in contact with the side surface of the oxide 230a or the oxide 230b in the opening 248 is smaller than a thickness T1 of the conductor 242b in a portion in contact with the top surface of the oxide 230b, in some cases. In particular, when the diameter of the opening 248 is small, the thickness T2 becomes significantly small and the conductor 242b is not formed on the side surface of the oxide 230a or the oxide 230b in the opening 248, in some cases.

When the thickness of the conductor 242b is small on a side surface of the opening 248 as described above, the resistivity might be increased at the thin portion of the conductor 242b, which leads to a decrease in on-state current of the transistor 200, for example.

Thus, in this modification example, a conductor 244 is provided over the conductor 242b such that at least part thereof overlaps with the opening 248 and the conductor 247. The transistor 200 illustrated in FIG. 12 is different from the transistor 200 illustrated in FIG. 1 in this point. The structures illustrated in FIG. 1 can be referred to for the other structures of the semiconductor device illustrated in FIG. 12.

Here, the conductor 244 is preferably provided in contact with a side surface and the bottom surface of the depression portion of the conductor 242b. Thus, the conductor 244 is preferably deposited by a CVD method or an ALD method providing favorable embeddability.

A stacked-layer film may be used for the conductor 244 as illustrated in FIGS. 12(B) and 12(D), in which case a conductive material with high adhesion is used for a lower layer. For example, a conductive film in which titanium nitride and tungsten are stacked in this order is used for the conductor 244.

When the depression portion of the conductor 242b is filled with the conductor 244 in this manner, the thickness of the conductor 242b and the conductor 244 that function as the source electrode or the drain electrode of the transistor 200 can be sufficiently large.

Accordingly, a decrease in on-state current of the semiconductor device described in this embodiment can be inhibited and favorable electrical characteristics can be provided. Furthermore, a contact between the transistor 200 and the conductor 247 can be obtained without making the diameter of the opening 248 too large; thus, the semiconductor device of this embodiment can be miniaturized or highly integrated.

The top surface of the conductor 244 is preferably substantially level with the top surface of the conductor 242b. With such a structure, the exposed area of the conductor 244 from the conductor 242b can be minimum even when a metal which is oxidized relatively easily is used for the conductor 244; thus, the amount of oxygen absorbed from an oxide around the conductor 244 can be reduced.

The above-described conductive material that can be used for the conductors 242 can be used for the conductor 244. Since the conductor 244 is preferably deposited by a CVD method or an ALD method providing favorable embeddability in the depression portion of the conductor 242b, tungsten, titanium, aluminum, cobalt, or the like can be used, for example. Furthermore, a stacked-layer film may be used for the conductor 244. The above metal film can be used for an upper layer of the conductor 244, and a metal nitride having high adhesion to the metal film can be used for a lower layer. As the metal nitride, titanium nitride or the like can be used, for example. Such a stacked-layer structure enables formation of the conductor 244 in the depression portion of the conductor 242b with favorable embeddability and prevention of separation from the conductor 242b. Note that the conductor 244 is not limited to a two-layer structure and may be a stacked-layer film of three or more layers.

As illustrated in FIG. 12(D), a structure is employed in which the top surface of the conductor 244, the top surface of the conductor 242b, and a side surface of the conductor 242b are covered with the insulator 256; thus, oxygen and impurities such as hydrogen or water can be inhibited from being diffused into the conductor 244 and the conductor 242b from the directions of the top surface of the conductor 244, the side surface of the conductor 242b, and the top surface of the conductor 242b. Hence, diffusion of oxygen into the conductor 244 and the conductor 242b from the periphery can be inhibited, so that the oxidation of the conductor 244 and the conductor 242b can be inhibited. Note that a similar effect can also be obtained in the conductor 242a.

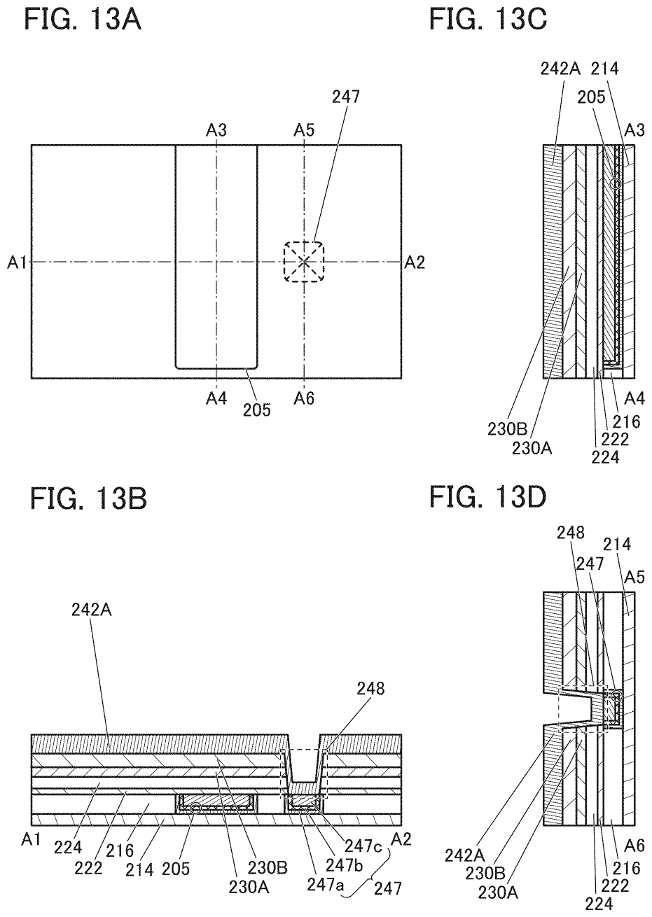

Next, a method for manufacturing the semiconductor device including the transistor 200, which is illustrated in FIG. 12, will be described with reference to FIG. 13 to FIG. 15. In FIG. 13 to FIG. 15, (A) of each drawing is a top view. Moreover, (B) of each drawing is a cross-sectional view corresponding to a portion indicated by the dashed-dotted line A1-A2 in (A), and is also a cross-sectional view of the transistor 200 in the channel length direction. Furthermore, (C) of each drawing is a cross-sectional view corresponding to a portion indicated by the dashed-dotted line A3-A4 in (A), and is also a cross-sectional view in the channel width direction of the transistor 200. Furthermore, (D) of each drawing is a cross-sectional view corresponding to a portion indicated by the dashed-dotted line A5-A6 in (A), and is also a cross-sectional view of the transistor 200 in the source region or the drain region in the channel width direction. Note that for simplification of the drawings, some components are not illustrated in the top view of (A) of each drawing.

First, a manufacturing process of the semiconductor device proceeds using the methods illustrated in FIG. 3 and FIG. 4 as described above.

Then, the mask 252 is removed and the conductive film 242A is formed over the oxide film 230B. The conductive film 242A is in contact with the conductor 247 in the opening 248. The conductive film 242A can be deposited by a sputtering method, a CVD method, an MBE method, a PLD method, an ALD method, or the like (see FIG. 13). Here, a depression portion is formed in the conductive film 242A along the shape of the opening 248, as illustrated in FIGS. 13(C) and 13(D). The thickness of the conductive film 242A on the sidewall of the opening 248 is smaller than that over the oxide film 230B, in some cases.

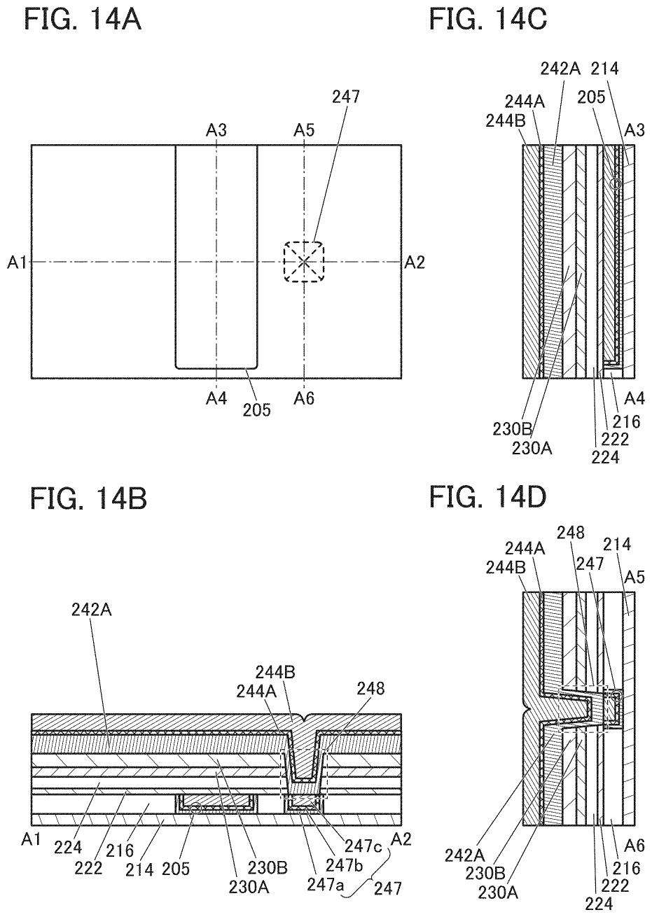

Next, a conductive film 244A and a conductive film 244B are deposited in this order over the conductive film 242A (see FIG. 14). The conductive film 244A and the conductive film 244B can be deposited by a sputtering method, a CVD method, an MBE method, a PLD method, an ALD method, or the like.

Here, the conductive film 244A and the conductive film 244B are preferably deposited by a deposition method that provides favorable embeddability, and a CVD method (e.g., a metal CVD method or a metal organic CVD (MOCVD) method) or an ALD method is preferably used for the deposition.

The conductive film 244A is preferably a conductive film having favorable adhesion to the conductive film 242A and the conductive film 244B. For example, for the conductive film 244A, titanium nitride is deposited by an ALD method.

The conductive film 244B preferably has a larger thickness than the conductive film 244A and is preferably deposited by a method with a higher deposition rate than the method for the conductive film 244A. For example, for the conductive film 244B, tungsten is deposited by a CVD method.

When the conductive film 244A and the conductive film 244B are deposited in such a manner, the opening 248 can be filled with the conductive film 242A, the conductive film 244A, and the conductive film 244B.

Note that although the conductive film 244A and the conductive film 244B are deposited in the steps illustrated in FIG. 14, this embodiment is not limited thereto. In the case where the conductive film 244B has sufficiently favorable adhesion to the conductive film 242A, for example, the conductive film 244A is not necessarily deposited. Furthermore, a two-layer structure including the conductive film 244A and the conductive film 244B is not necessarily employed and a structure including three or more layers may be employed.

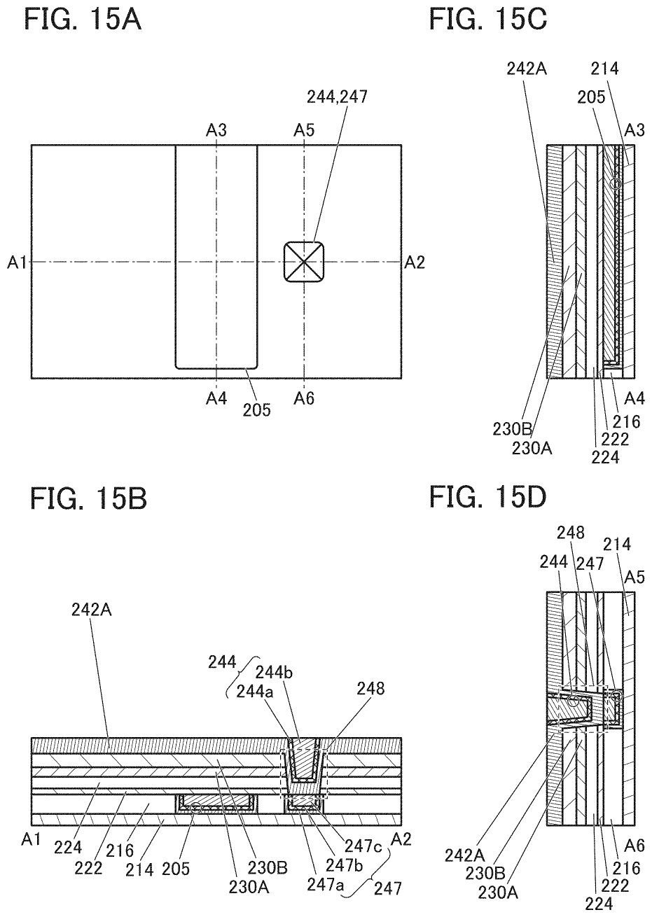

Next, the conductive film 244A and the conductive film 244B are partly removed so that the top surface of the conductive film 242A is exposed, whereby the conductor 244a and the conductor 244b thereover are formed (see FIG. 15). Hereinafter, the conductor 244a and the conductor 244b are collectively referred to as the conductor 244.

The conductive film 244A and the conductive film 244B are partly removed preferably by performing one or both of dry etching treatment and CMP treatment. For example, dry etching treatment is performed and then CMP treatment is performed.

When dry etching treatment is performed on the top surface of the conductive film 244A or the conductive film 244B, an upper portion of the conductive film 244A or the conductive film 244B can be removed and at the same time, unevenness of the top surface of the conductive film 244A or the conductive film 244B can be reduced.

Furthermore, when CMP treatment is performed on the top surface with reduced unevenness of the conductive film 244A or the conductive film 244B, parts of the conductive film 244A and the conductive film 244B which are above the conductive film 242A can be removed. In addition, the planarity of the top surfaces of the conductive film 242A, the conductor 244a, and the conductor 244b can be improved.

In that case, endpoint detection of the CMP treatment is performed using the top surface of the conductive film 242A as a guide. Alternatively, CMP treatment may be performed after part of the top surface of the conductive film 242A is removed. When CMP treatment is performed on the conductive film 244A and the conductive film 244B as described above, the top surface of the conductor 244 and the top surface of the conductor 242b can be substantially level with each other. With such a structure, the exposed area of the conductor 244 from the conductor 242b can be minimum even when a metal which is oxidized relatively easily is used for the conductor 244; thus, the amount of oxygen absorbed from an oxide around the conductor 244 can be reduced.

For CMP treatment performed to remove parts of the conductive film 244A and the conductive film 244B, an optical endpoint detection method or a motor current based (torque-based) endpoint detection method is preferably used. In the case of using an optical endpoint detection method, polishing ending time can be determined by sensing a change in reflection of a laser beam or white light on a surface to be polished by a sensor provided in an endpoint detector. In the case of using a motor current based endpoint detection method, an endpoint detector senses a change in resistance due to friction between a polishing cloth and a surface to be polished, so that polishing ending time can be determined.

Note that although the top surface of the conductive film 242A is exposed in the steps illustrated in FIG. 15, this embodiment is not limited thereto. In the case where the oxidation resistance of the conductor 244 is sufficiently high, for example, the conductive film 242A is not necessarily exposed and a structure may be employed in which part of the conductor 244 covers the conductive film 242A.

Subsequently, the manufacturing process of the semiconductor device proceeds using the methods illustrated in FIG. 6 to FIG. 11 as described above. In such a manner, the semiconductor device illustrated in FIG. 12 can be manufactured.

### <Modification Example 2 of Semiconductor Device>

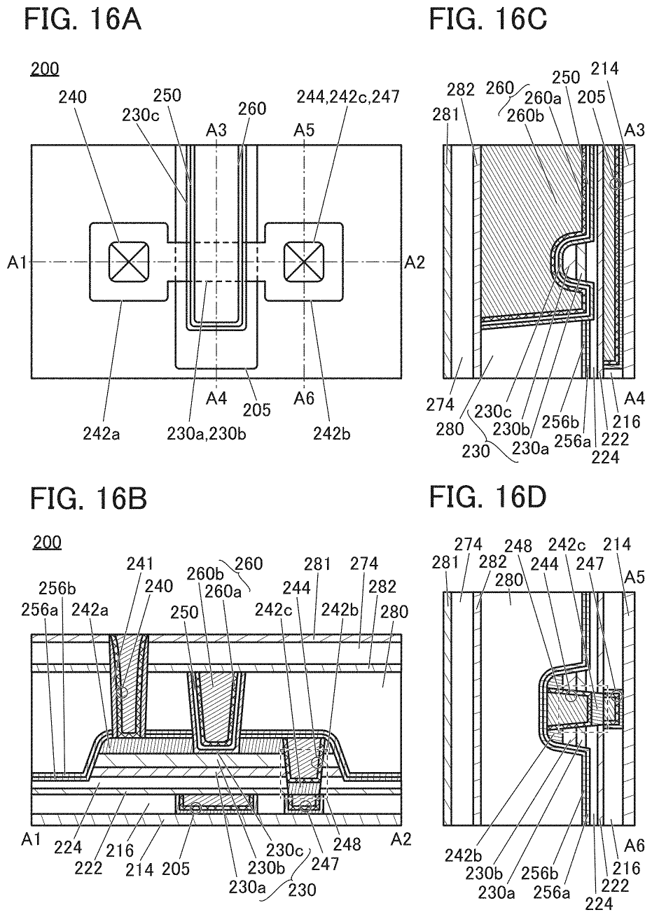

The transistor 200 illustrated in FIG. 16 is different from the transistor 200 illustrated in FIG. 12 in that the conductor 242b is formed only over the oxide 230b and a conductor 242c is formed on a bottom portion of the opening 248. In addition, the transistor 200 illustrated in FIG. 16 is different from the transistor 200 illustrated in FIG. 12 in that the conductor 244 is provided so as to fill the opening 248 and part of a side surface of the conductor 244 is in contact with at least one of a side surface of the oxide 230a and a side surface of the oxide 230b.

Part of the side surface of the conductor 244 is in contact with a side surface of the conductor 242b in a region overlapping with the opening 248, and the bottom surface of the conductor 244 is in contact with the top surface of the conductor 242c. The bottom surface of the conductor 242c is in contact with the top surface of the conductor 247. In other words, the conductor 242b is electrically connected to the conductor 247 via the conductor 244 and the conductor 242c.

Here, the conductor 242c is formed using a conductive material similar to that of the conductor 242b. The conductor 242c is formed on the bottom portion of the opening 248 when the conductive film 242A is cut due to a step in the opening 248 in the process illustrated in FIG. 4. The conductive film 242A is less likely to be formed on a side surface of the opening 248 particularly when the conductive film 242A is deposited by a sputtering method; thus, the conductor 242c is formed in some cases.

When the opening 248 is filled with the conductor 244 in the case where the conductive film 242A is not formed on a side surface of the opening 248 in this manner, the thickness of the conductor 242b and the conductor 244 that function as a source electrode or a drain electrode of the transistor 200 can be sufficiently large. Accordingly, a decrease in on-state current of the semiconductor device described in this embodiment can be inhibited and favorable electrical characteristics can be provided.

### <Modification Example 3 of Semiconductor Device>

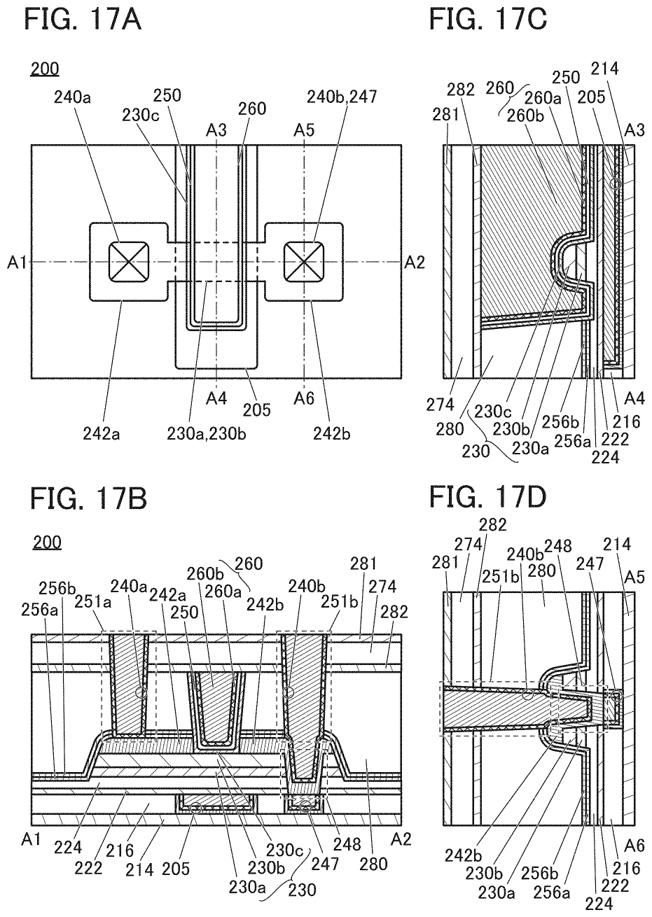

The transistor 200 illustrated in FIG. 17 is different from the transistor 200 illustrated in FIG. 12 in that the conductor 244 is not provided; an opening 251b that overlaps with the opening 248 is formed in the insulator 256a, the insulator 256b, the insulator 280, the insulator 282, the insulator 274, and the insulator 281; and a conductor 240b is positioned so as to fill the opening 248 and the opening 251b. The conductor 240b is in contact with the top surface and a side surface of the conductor 242b so as to fill a depression portion of the conductor 242b.

Furthermore, an opening 251a that reaches the conductor 242a is formed in the insulator 256a, the insulator 256b, the insulator 280, the insulator 282, the insulator 274, and the insulator 281, and a conductor 240a is positioned so as to fill the opening 251a. Here, the conductor 240a and the conductor 240b each have a structure similar to that of the conductor 240. Note that the top surface of the conductor 240a is connected to a wiring, an electrode, a terminal, or the like, whereas the top surface of the conductor 240b is not necessarily connected to a wiring, an electrode, a terminal, or the like.

A stacked-layer film may be used for each of the conductor 240a and the conductor 240b, in which case a conductive material with high adhesion is used for a lower layer. For example, a conductive film in which titanium nitride and tungsten are stacked in this order is used for each of the conductor 240a and the conductor 240b.

Unlike in the transistor 200 illustrated in FIG. 12, it is preferable that the insulator 241 in contact with side surfaces of the conductor 240a and the conductor 240b not be provided in the transistor 200 illustrated in FIG. 17. In that case, a favorable contact between the conductor 240b and the conductor 242b can be obtained.

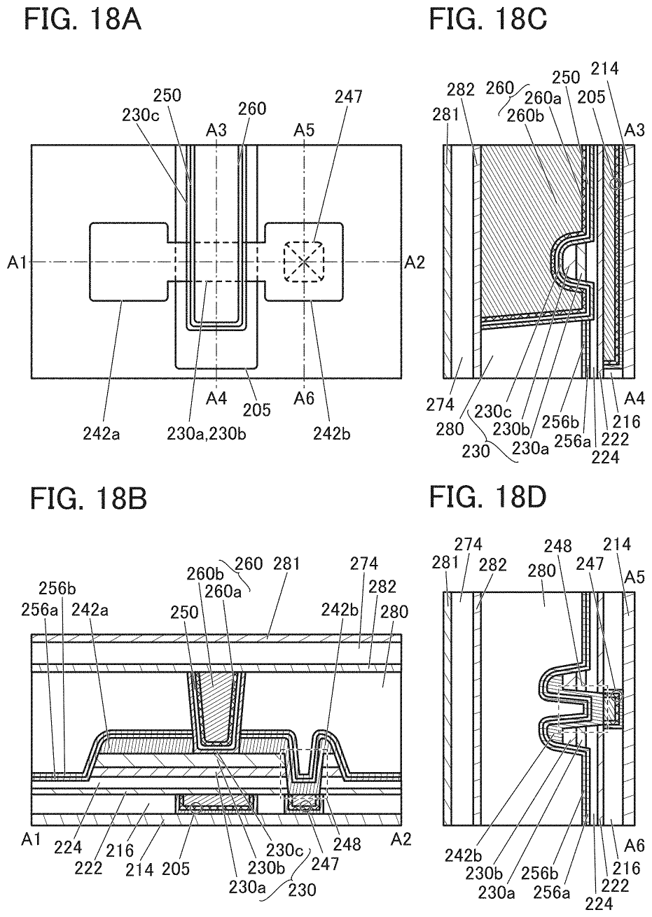

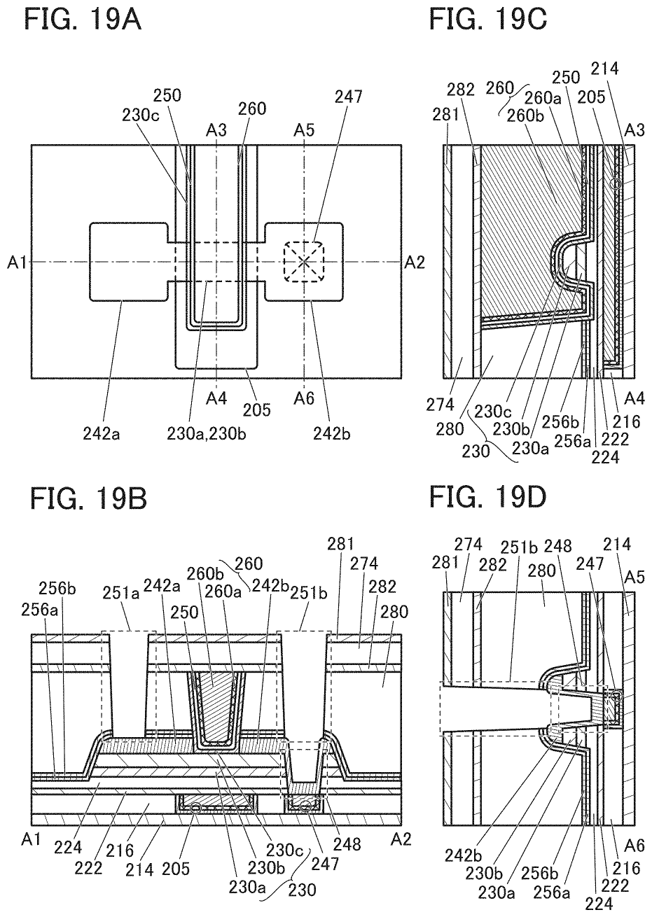

Here, a method for manufacturing the transistor 200 illustrated in FIG. 17 is described with reference to FIG. 18 and FIG. 19.

First, steps similar to those in the manufacturing process of the transistor 200 illustrated in FIG. 12 are performed except for the step of depositing the conductive film 244A and the conductive film 244B illustrated in FIG. 14 and the step of forming the conductor 244 illustrated in FIG. 15 (see FIG. 18). At this time, the depression portion is formed in the conductor 242b along the shape of the opening 248, and the depression portion is filled with the insulator 256a, the insulator 256b, and the insulator 280 as illustrated in FIGS. 18(B) and 18(D).

Next, the opening 251a that reaches the top surface of the conductor 242a and the opening 251b that overlaps with the opening 248 and reaches the top surface of the conductor 242b are formed in the insulator 256a, the insulator 256b, the insulator 280, the insulator 282, the insulator 274, and the insulator 281 (see FIG. 19). The opening 251a and the opening 251b can be formed by a lithography method.

Subsequently, the conductor 240a is formed in the opening 251a and the conductor 240b is formed in the opening 251b in a manner similar to the formation step of the conductor 240 described in the above manufacturing method.

Owing to the method for manufacturing the transistor 200 described in this modification example, the transistor 200 can be manufactured without a step of forming the conductor 244. Accordingly, the semiconductor device described in this embodiment can be manufactured with high productivity.

When the opening 248 is filled with the conductor 240b concurrently with the formation of the conductor 240a in this manner even in the case where the opening 248 is not filled with the conductor 244, the thickness of the conductor 242b and the conductor 240b that function as a source electrode or a drain electrode of the transistor 200 can be sufficiently large. Accordingly, a decrease in on-state current of the semiconductor device described in this embodiment can be inhibited and favorable electrical characteristics can be provided.

The structure, method, and the like described above in this embodiment can be used in combination as appropriate with the structures, methods, and the like described in the other embodiments.

### Embodiment 2

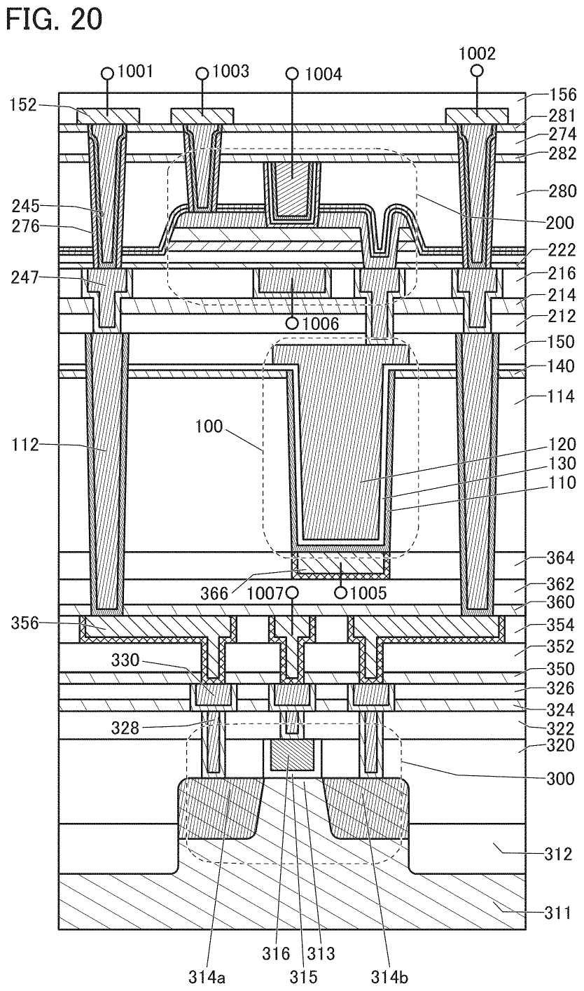

In this embodiment, one embodiment of a semiconductor device will be described with reference to FIG. 20 to FIG. 30.

### [Memory Device 1]

FIG. 20 illustrates an example of a semiconductor device (memory device) using a capacitor, which is one embodiment of the present invention. In the semiconductor device of one embodiment of the present invention, the transistor 200 is provided above a capacitor 100 and a transistor 300, and the capacitor 100 is provided above the transistor 300. At least part of the capacitor 100 or the transistor 300 preferably overlaps with the transistor 200. In that case, the area occupied by the capacitor 100, the transistor 200, and the transistor 300 in a top view can be reduced, whereby the semiconductor device of this embodiment can be miniaturized or highly integrated.

Note that the transistor 200 described in the above embodiment can be used as the transistor 200. Therefore, the description in the above embodiment can be referred to for the transistor 200 and a layer including the transistor 200.

The transistor 200 is a transistor whose channel is formed in a semiconductor layer containing an oxide semiconductor. Since the transistor 200 has a low off-state current, a memory device including the transistor 200 can retain stored data for a long time. In other words, refresh operation is not required or the frequency of the refresh operation is extremely low, which leads to a sufficient reduction in power consumption of the memory device.

In the semiconductor device illustrated in FIG. 20, a wiring 1001 is electrically connected to a source of the transistor 300, a wiring 1002 is electrically connected to a drain of the transistor 300, and a wiring 1007 is electrically connected to a gate of the transistor 300. A wiring 1003 is electrically connected to one of a source and a drain of the transistor 200, a wiring 1004 is electrically connected to a first gate of the transistor 200, and a wiring 1006 is electrically connected to a second gate of the transistor 200. The other of the source and the drain of the transistor 200 is electrically connected to one electrode of the capacitor 100, and a wiring 1005 is electrically connected to the other electrode of the capacitor 100.

The semiconductor device illustrated in FIG. 20 has characteristics of being able to retain charges stored in the one electrode of the capacitor 100 by switching of the transistor 200; thus, writing, retention, and reading of data can be performed.

Furthermore, by arranging the semiconductor devices illustrated in FIG. 20 in a matrix, a memory cell array can be formed. In this case, the transistor 300 can be used for a read circuit, a driver circuit, or the like that is connected to the memory cell array.

### <Transistor 300>

The transistor 300 is provided over a substrate 311 and includes a conductor 316 functioning as the gate electrode, an insulator 315 functioning as a gate insulator, a semiconductor region 313 that is part of the substrate 311, and a low-resistance region 314a and a low-resistance region 314b functioning as a source region and a drain region.

Here, the insulator 315 is positioned over the semiconductor region 313, and the conductor 316 is positioned over the insulator 315. The transistors 300 formed in the same layer are electrically isolated from one another by an insulator 312 functioning as an element isolation insulating layer. The insulator 312 can be formed using an insulator similar to that used for an insulator 326 or the like described later. The transistor 300 may be a p-channel transistor or an n-channel transistor.

In the substrate 311, a region of the semiconductor region 313 where a channel is formed, a region in the vicinity thereof, the low-resistance region 314a and the low-resistance region 314b functioning as the source region and the drain region, and the like preferably contain a semiconductor such as a silicon-based semiconductor, further preferably single crystal silicon. Alternatively, the regions may be formed using a material containing Ge (germanium), SiGe (silicon germanium), GaAs (gallium arsenide), GaAlAs (gallium aluminum arsenide), or the like. A structure may be employed in which silicon whose effective mass is controlled by applying stress to the crystal lattice and thereby changing the lattice spacing is used. Alternatively, the transistor 300 may be an HEMT (High Electron Mobility Transistor) using GaAs and GaAlAs, or the like.

The low-resistance region 314a and the low-resistance region 314b contain an element that imparts n-type conductivity, such as arsenic or phosphorus, or an element that imparts p-type conductivity, such as boron, in addition to the semiconductor material used for the semiconductor region 313.

The conductor 316 functioning as the gate electrode can be formed using a semiconductor material such as silicon containing an element that imparts n-type conductivity, such as arsenic or phosphorus, or an element that imparts p-type conductivity, such as boron, or using a conductive material such as a metal material, an alloy material, or a metal oxide material.

Note that the work function depends on a material of the conductor; thus, the threshold voltage can be adjusted by changing the material of the conductor. Specifically, it is preferable to use a material such as titanium nitride or tantalum nitride for the conductor. Moreover, in order to obtain both conductivity and embeddability, it is preferable to use stacked layers of metal materials such as tungsten and aluminum for the conductor, and it is particularly preferable to use tungsten in terms of heat resistance.

Here, in the transistor 300 illustrated in FIG. 20, the semiconductor region 313 (part of the substrate 311) in which the channel is formed has a convex shape. Furthermore, the conductor 316 is provided so as to cover a side surface and the top surface of the semiconductor region 313 with the insulator 315 positioned therebetween. Such a transistor 300 is also referred to as a FIN-type transistor because it utilizes a convex portion of the semiconductor substrate. Note that an insulator functioning as a mask for forming the convex portion may be placed in contact with an upper portion of the convex portion. Furthermore, although the case where the convex portion is formed by processing part of the semiconductor substrate is described here, a semiconductor film having a convex shape may be formed by processing an SOI substrate.

Note that the transistor 300 illustrated in FIG. 20 is an example and the structure is not limited thereto; an appropriate transistor is used in accordance with a circuit configuration or a driving method.

### <Capacitor>

The capacitor 100 includes an insulator 114 over an insulator 364, an insulator 140 over the insulator 114, a conductor 110 positioned in an opening formed in the insulator 114 and the insulator 140, an insulator 130 over the conductor 110 and the insulator 140, a conductor 120 over the insulator 130, and an insulator 150 over the conductor 120 and the insulator 130. Here, at least parts of the conductor 110, the insulator 130, and the conductor 120 are positioned in the opening formed in the insulator 114 and the insulator 140.

The conductor 110 functions as a lower electrode of the capacitor 100, the conductor 120 functions as an upper electrode of the capacitor 100, and the insulator 130 functions as a dielectric of the capacitor 100. The capacitor 100 has a structure in which the upper electrode and the lower electrode face each other with the dielectric positioned therebetween on a side surface as well as the bottom surface of the opening in the insulator 114 and the insulator 140; thus, the capacitance per unit area can be increased. Thus, the deeper the opening is, the larger the capacitance of the capacitor 100 can be. Increasing the capacitance per unit area of the capacitor 100 in this manner can promote miniaturization or higher integration of the semiconductor device.

An insulator that can be used for the insulator 280 can be used as the insulator 114 and the insulator 150. The insulator 140 preferably functions as an etching stopper at the time of forming the opening in the insulator 114 and is formed using an insulator that can be used for the insulator 214.

The shape of the opening formed in the insulator 114 and the insulator 140 when seen from the above may be a quadrangular shape, a polygonal shape other than a quadrangular shape, a polygonal shape with rounded corners, or a circular shape including an elliptical shape. Here, the area where the opening and the transistor 200 overlap with each other is preferably large in a top view. Such a structure can reduce the area occupied by the semiconductor device including the capacitor 100 and the transistor 200.

The conductor 110 is positioned in contact with the opening formed in the insulator 140 and the insulator 114. The top surface of the conductor 110 is preferably substantially level with the top surface of the insulator 140. The bottom surface of the conductor 110 is in contact with a conductor 366 that fills an opening in the insulator 364. The conductor 110 is preferably deposited by an ALD method, a CVD method, or the like; for example, a conductor that can be used for the conductor 205 is used.

The insulator 130 is positioned to cover the conductor 110 and the insulator 140. The insulator 130 is preferably deposited by an ALD method or a CVD method, for example. The insulator 130 can be provided to have stacked layers or a single layer using, for example, silicon oxide, silicon oxynitride, silicon nitride oxide, silicon nitride, zirconium oxide, aluminum oxide, aluminum oxynitride, aluminum nitride oxide, aluminum nitride, hafnium oxide, hafnium oxynitride, hafnium nitride oxide, or hafnium nitride. As the insulator 130, an insulating film in which zirconium oxide, aluminum oxide, and zirconium oxide are stacked in this order can be used, for example.

For the insulator 130, a material with high dielectric strength, such as silicon oxynitride, or a high dielectric constant (high-k) material is preferably used. Alternatively, a stacked-layer structure using a material with high dielectric strength and a high dielectric (high-k) material may be employed.

As an insulator of a high dielectric constant (high-k) material (a material having a high relative permittivity), gallium oxide, hafnium oxide, zirconium oxide, an oxide containing aluminum and hafnium, an oxynitride containing aluminum and hafnium, an oxide containing silicon and hafnium, an oxynitride containing silicon and hafnium, a nitride containing silicon and hafnium, and the like can be given. The use of such a high-k material can ensure sufficient capacitance of the capacitor 100 even when the insulator 130 has a large thickness. When the insulator 130 has a large thickness, leakage current generated between the conductor 110 and the conductor 120 can be inhibited.

As the material with high dielectric strength, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, and the like can be given. For example, it is possible to use an insulating film in which SiNₓ deposited by an ALD method, SiOₓ deposited by a PEALD method, and SiNₓ deposited by an ALD method are stacked in this order. The use of such an insulator with high dielectric strength can increase the dielectric strength and inhibit electrostatic breakdown of the capacitor 100.

The conductor 120 is positioned to fill the opening formed in the insulator 140 and the insulator 114. The conductor 247 is in contact with the top surface of the conductor 120 through an opening in the insulator 150. The conductor 120 is preferably deposited by an ALD method, a CVD method, or the like and is formed using a conductor that can be used for the conductor 205, for example.

In the fabrication process of the capacitor 100, high-temperature heat treatment at higher than 700° C. is needed in some cases. When such a high-temperature heat treatment is performed after the formation of the transistor 200, the oxide 230 might be affected by diffusion of oxygen or impurities such as hydrogen or water, which might degrade the electrical characteristics of the transistor 200.

However, when the transistor 200 is formed over the capacitor 100 as described in this modification example, the thermal budget in the fabrication process of the capacitor 100 does not affect the transistor 200. Thus, degradation in electrical characteristics of the transistor 200 can be prevented and a semiconductor device having stable electrical characteristics can be provided.

### <Wiring Layer>

A wiring layer provided with an interlayer film, a wiring, a plug, and the like may be provided between the components. A plurality of wiring layers can be provided depending on the design. Here, a plurality of conductors functioning as plugs or wirings are collectively denoted by the same reference numeral in some cases. Furthermore, in this specification and the like, a wiring and a plug electrically connected to the wiring may be a single component. That is, there are a case where part of a conductor functions as a wiring and a case where part of a conductor functions as a plug.

For example, an insulator 320, an insulator 322, an insulator 324, and the insulator 326 are stacked over the transistor 300 in this order as interlayer films. In addition, a conductor 328, a conductor 330, and the like that are electrically connected to a conductor 152 functioning as a terminal are embedded in the insulator 320, the insulator 322, the insulator 324, and the insulator 326. Note that the conductor 328 and the conductor 330 function as plugs or wirings.

The insulators functioning as interlayer films may each function as a planarization film that covers an uneven shape thereunder. For example, the top surface of the insulator 322 may be planarized by planarization treatment using a chemical mechanical polishing (CMP) method or the like to improve planarity.

A wiring layer may be provided over the insulator 326 and the conductor 330. For example, in FIG. 20, an insulator 350, an insulator 352, and an insulator 354 are stacked in this order. Furthermore, a conductor 356 is formed in the insulator 350, the insulator 352, and the insulator 354. The conductor 356 functions as a plug or a wiring.

An insulator 360 is positioned over the insulator 354, an insulator 362 is positioned over the insulator 360, the insulator 364 is positioned over the insulator 362, and the insulator 114 is positioned over the insulator 364.

An opening is formed in the insulator 364, and the conductor 366 is positioned in the opening. The conductor 366 is in contact with the bottom surface of the conductor 110. That is, the conductor 366 functions as a wiring that is connected to the other electrode of the capacitor 100. For the conductor 366, an insulator that can be used for the conductor 356 and the like can be used.

A conductor 112, conductors (the conductor 120 and the conductor 110) included in the capacitor 100, and the like are embedded in the insulator 360, the insulator 362, the insulator 364, the insulator 114, the insulator 140, the insulator 130, and the insulator 150. Note that the conductor 112 functions as a plug or a wiring that electrically connects the transistor 300 and the conductor 152 that functions as a terminal.

Similarly, the conductor 247, a conductor (the conductor 205) included in the transistor 200, and the like are embedded in an insulator 212, the insulator 214, and the insulator 216. Note that the conductor 247 has a function as a plug or a wiring that is electrically connected to the capacitor 100, the transistor 200, or the transistor 300. For example, one part of the conductor 247 is electrically connected to the conductor 120 functioning as the upper electrode of the capacitor 100. For example, another part of the conductor 247 has a function as a plug or a wiring that electrically connects the transistor 300 and the conductor 152 that functions as a terminal.

The conductor 152 is provided over the insulator 281, and the conductor 152 is covered with an insulator 156. Here, the conductor 152 is in contact with the top surface of the conductor 245 and functions as a terminal of the transistor 200 or the transistor 300.

Note that as an insulator that can be used for an interlayer film, an oxide, a nitride, an oxynitride, a nitride oxide, a metal oxide, a metal oxynitride, and a metal nitride oxide, each of which has an insulating property can be given. For example, when a material with a low relative permittivity is used for an insulator functioning as an interlayer film, the parasitic capacitance generated between wirings can be reduced. Accordingly, a material is preferably selected depending on the function of the insulator.

For example, the insulator 320, the insulator 322, the insulator 326, the insulator 352, the insulator 354, the insulator 362, the insulator 364, the insulator 114, the insulator 150, the insulator 212, the insulator 156, and the like preferably include an insulator with a low relative permittivity. For example, the insulators each preferably contain silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. Alternatively, the insulators each preferably have a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. When silicon oxide or silicon oxynitride, which is thermally stable, is combined with a resin, a stacked-layer structure having thermal stability and a low relative permittivity can be obtained. Examples of the resin include polyester, polyolefin, polyamide (nylon, aramid, or the like), polyimide, polycarbonate, and acrylic.

It is preferable that the resistivity of an insulator provided over or under the conductor 152 be higher than or equal to 1.0×10¹² Ωcm and lower than or equal to 1.0×10¹⁵ Ωcm, further preferably higher than or equal to 5.0×10¹² Ωcm and lower than or equal to 1.0×10¹⁴ Ωcm, still further preferably higher than or equal to 1.0×10¹³ Ωcm and lower than or equal to 5.0×10¹³ Ωcm. The resistivity of the insulator provided over or under the conductor 152 is preferably within the above range because the insulator can disperse charges accumulated between the transistor 200, the transistor 300, the capacitor 100, and wirings such as the conductor 152 while maintaining the insulating property, and thus, poor characteristics and electrostatic breakdown of the transistor and the semiconductor device including the transistor due to the charges can be inhibited. For such an insulator, silicon nitride or silicon nitride oxide can be used. For example, the resistivity of the insulator 281 can be set within the above range.

When a transistor using an oxide semiconductor is surrounded by insulators having a function of inhibiting transmission of oxygen and impurities such as hydrogen, the electrical characteristics of the transistor can be stable. Thus, an insulator having a function of inhibiting transmission of oxygen and impurities such as hydrogen is used as the insulator 324, the insulator 350, and the insulator 360.

As the insulator having a function of inhibiting transmission of oxygen and impurities such as hydrogen, an insulator, which is a single layer or a stacked layer, containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum is used, for example. Specifically, for the insulator having a function of inhibiting transmission of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; or silicon nitride can be used.

For the conductor that can be used for a wiring or a plug, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. A semiconductor having high electrical conductivity, typified by polycrystalline silicon containing an impurity element such as phosphorus, or silicide such as nickel silicide may be used.

For example, for the conductor 328, the conductor 330, the conductor 356, the conductor 112, the conductor 247, the conductor 152, and the like, a single layer or a stacked layer of a conductive material such as a metal material, an alloy material, a metal nitride material, or a metal oxide material that is formed using the above material can be used. It is preferable to use a high-melting-point material that has both heat resistance and conductivity, such as tungsten or molybdenum, and tungsten is preferably used. Alternatively, a low-resistance conductive material such as aluminum or copper is preferably used. The use of a low-resistance conductive material can reduce wiring resistance.

<Wiring or Plug in Layer Provided with Oxide Semiconductor>

In the case where an oxide semiconductor is used in the transistor 200, an insulator including an excess oxygen region is provided in the vicinity of the oxide semiconductor in some cases. In that case, an insulator having a barrier property is preferably provided between the insulator including the excess oxygen region and a conductor provided in the insulator including the excess oxygen region.

For example, an insulator 276 is provided between the insulator 280 containing excess oxygen and the conductor 245 in FIG. 20. Here, the conductor 245 corresponds to the conductor 240 described in the above embodiment and the insulator 276 corresponds to the insulator 241 described in the above embodiment. Since the insulator 276 is provided in contact with the insulator 256, the conductor 245 and the transistor 200 can be sealed by insulators having a barrier property.

That is, the excess oxygen contained in the insulator 280 can be inhibited from being absorbed by the conductor 245 when the insulator 276 is provided. In addition, diffusion of hydrogen, which is an impurity, into the transistor 200 through the conductor 245 can be inhibited when the insulator 276 is provided.

Here, the conductor 245 functions as a plug or a wiring that is electrically connected to the transistor 200 or the transistor 300.

The above is the description of the structure example. With the use of this structure, a semiconductor device using a transistor including an oxide semiconductor can be miniaturized or highly integrated. Alternatively, a change in electrical characteristics can be inhibited and reliability can be improved in a semiconductor device using a transistor including an oxide semiconductor. Alternatively, a transistor including an oxide semiconductor and having a high on-state current can be provided. Alternatively, a transistor including an oxide semiconductor and having a low off-state current can be provided. Alternatively, a semiconductor device with low power consumption can be provided.

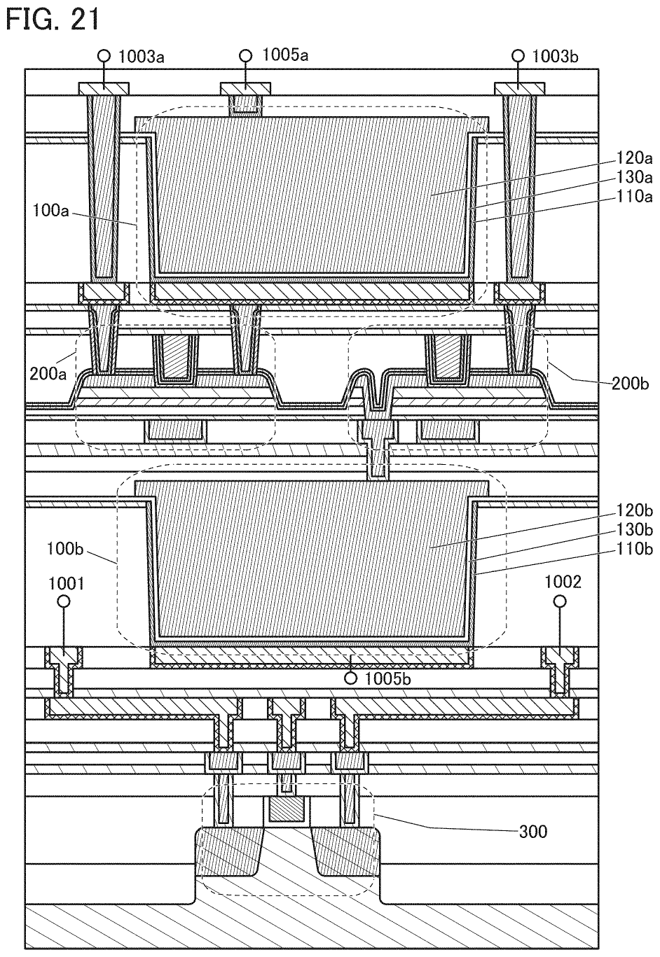

Note that although an example in which the capacitor 100 is provided below the transistor 200 is illustrated in FIG. 20, the semiconductor device described in this embodiment is not limited thereto. For example, a structure may be employed in which a capacitor 100a is positioned over a transistor 200a and a capacitor 100b is positioned below a transistor 200b in adjacent memory cells, as illustrated in FIG. 21. The semiconductor device illustrated in FIG. 21 has a structure similar to that of the semiconductor device illustrated in FIG. 20 except that the capacitor 100a is positioned over the transistor 200.

In the memory device illustrated in FIG. 21, the wiring 1001 is electrically connected to a source of the transistor 300, and the wiring 1002 is electrically connected to a drain of the transistor 300. A wiring 1003a is electrically connected to one of a source and a drain of the transistor 200a. The other of the source and the drain of the transistor 200a is electrically connected to one electrode of the capacitor 100a, and a wiring 1005a is electrically connected to the other electrode of the capacitor 100a. A wiring 1003b is electrically connected to one of a source and a drain of the transistor 200b. The other of the source and the drain of the transistor 200b is electrically connected to one electrode of the capacitor 100b, and a wiring 1005b is electrically connected to the other electrode of the capacitor 100b.

FIG. 21 illustrates the transistor 200a, the capacitor 100a, the transistor 200b, and the capacitor 100b included in memory cells adjacent to each other. The transistor 200a and the transistor 200b each have a structure similar to that of the transistor 200. Note that the conductor 247 is not positioned below the transistor 200a because the transistor 200a is connected to the capacitor 100a positioned over the transistor 200a.

The capacitor 100a and the capacitor 100b each have a structure similar to that of the capacitor 100. In other words, the capacitor 100a includes a conductor 110a, an insulator 130a, and a conductor 120a, and the capacitor 100b includes a conductor 110b, an insulator 130b, and a conductor 120b. The conductor 110a and the conductor 110b each have a structure similar to that of the conductor 110. The insulator 130a and the insulator 130b each have a structure similar to that of the insulator 130. The conductor 120a and the conductor 120b each have a structure similar to that of the conductor 120.

Here, the capacitor 100a preferably overlaps with the transistor 200a and the transistor 200b; for example, the capacitor 100a preferably overlaps with a channel formation region of the transistor 200a and a channel formation region of the transistor 200b. Furthermore, the capacitor 100b preferably overlaps with the transistor 200a and the transistor 200b; for example, the capacitor 100b preferably overlaps with the channel formation region of the transistor 200a and the channel formation region of the transistor 200b.

When the capacitor 100a and the capacitor 100b are positioned in such a manner, the capacitance of the capacitor 100a and the capacitor 100b can be increased without increasing the area occupied by the capacitor 100a, the capacitor 100b, the transistor 200a, and the transistor 200b in a top view. Accordingly, the semiconductor device of this embodiment can be miniaturized or highly integrated.

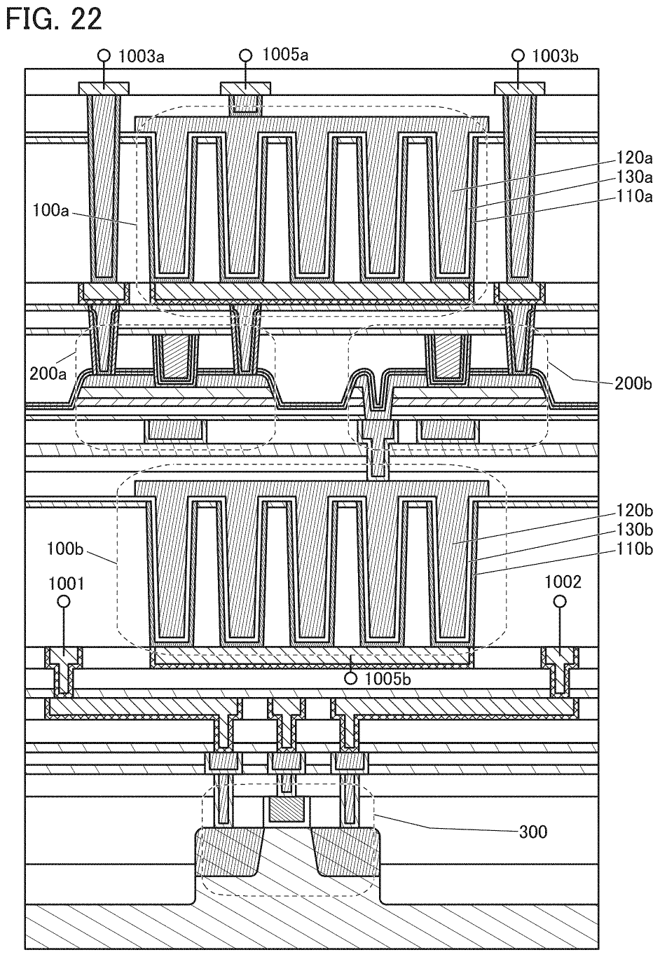

As illustrated in FIG. 22, a plurality of openings in which the capacitor 100a and the capacitor 100b are provided may be provided. Here, the conductor 110a may be provided to be separated by the openings. Similarly, the conductor 110b may be provided to be separated by the openings. Accordingly, the capacitor 100a and the capacitor 100b can be formed also on a side surface of each opening. Thus, the capacitor 100a and the capacitor 100b illustrated in FIG. 22 can have larger capacitance than the capacitor 100a and the capacitor 100b illustrated in FIG. 21 with substantially the same occupied area.

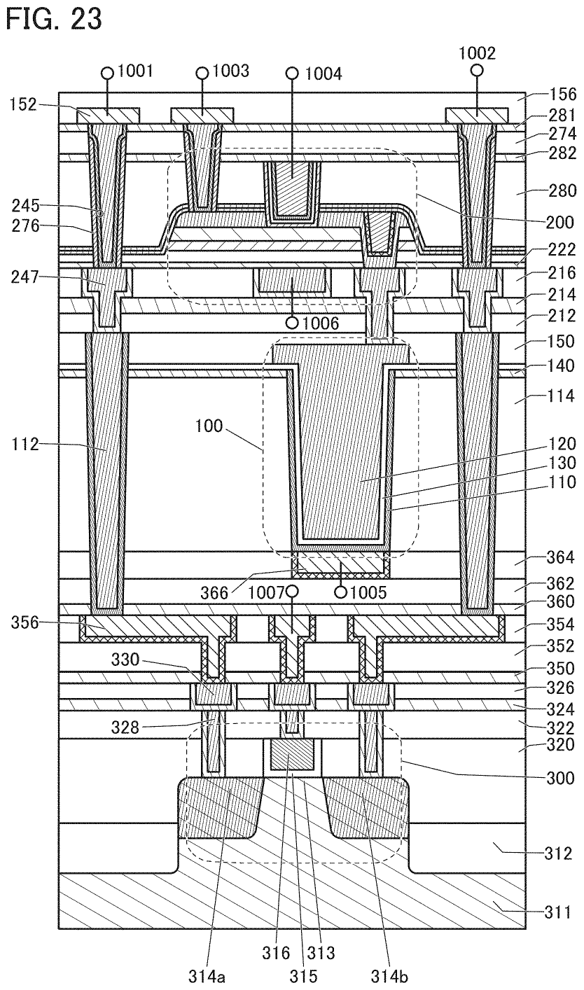

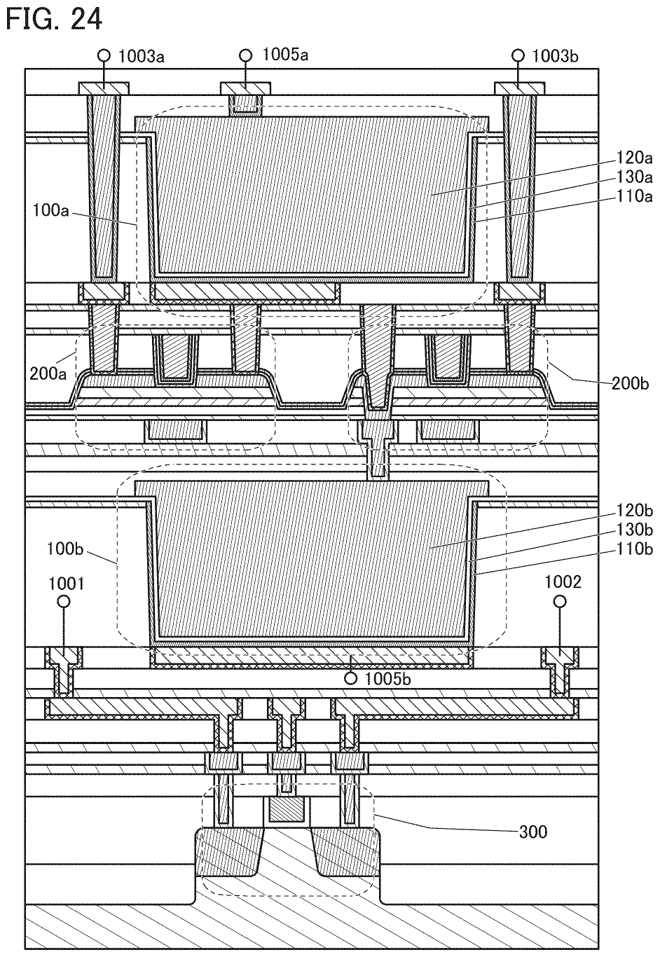

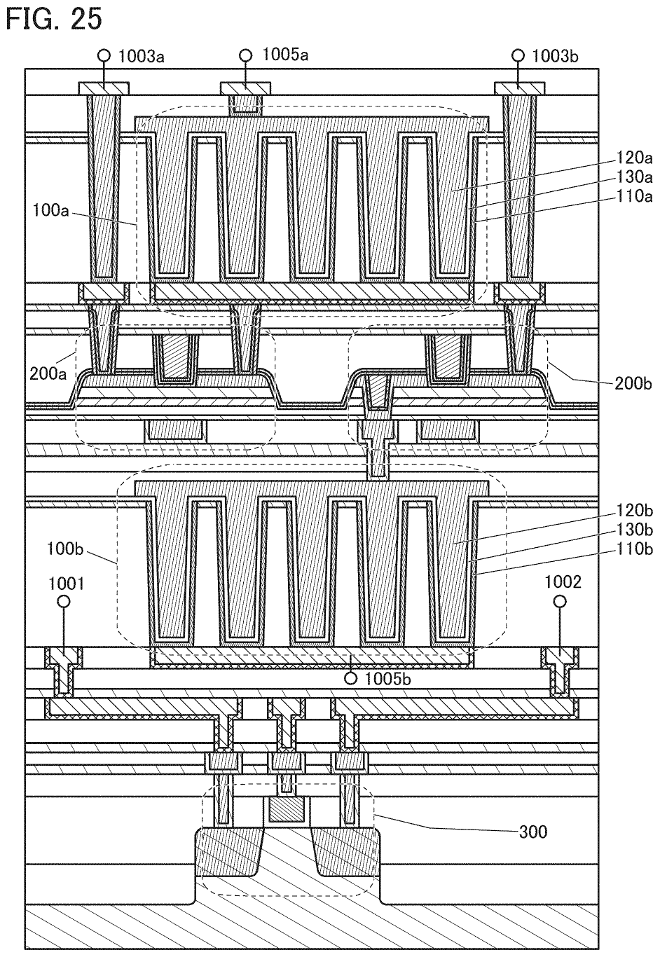

Note that although examples in which the transistor 200 illustrated in FIG. 1 is used in the semiconductor devices illustrated in FIG. 20 to FIG. 22 are described, the semiconductor devices described in this embodiment are not limited thereto. In the semiconductor devices illustrated in FIG. 20 to FIG. 22, the transistor 200 illustrated in FIG. 12, the transistor 200 illustrated in FIG. 16, the transistor 200 illustrated in FIG. 17, or the like may be used. For example, a structure may be employed in which the transistor 200 illustrated in FIG. 12 is used as the transistor 200 of the semiconductor device illustrated in FIG. 20 and a depression portion of the conductor 242b is filled with the conductor 244, as illustrated in FIG. 23. Alternatively, a structure may be employed in which, for example, the transistor 200 illustrated in FIG. 17 is used as the transistor 200b of the semiconductor device illustrated in FIG. 21 and a depression portion of the conductor 242b is filled with the conductor 245, as illustrated in FIG. 24. In that case, unlike in the structure illustrated in FIG. 20 or the like, a structure is preferably employed in which the insulator 276 is not provided on a side surface of the conductor 245. Alternatively, for example, a structure may be employed in which the transistor 200 illustrated in FIG. 12 is used as the transistor 200b of the semiconductor device illustrated in FIG. 22 and a depression portion of the conductor 242b is filled with the conductor 244, as illustrated in FIG. 25. As described here, the structure of the transistor 200 can be set as appropriate.

### [Memory Device 2]

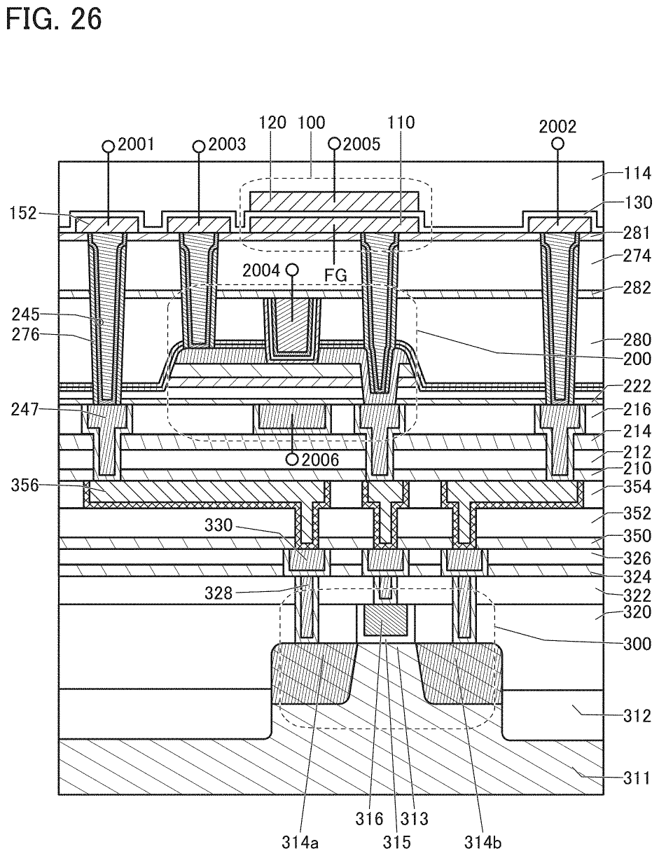

FIG. 26 illustrates an example of a semiconductor device (memory device) in which the semiconductor device of one embodiment of the present invention is used. The semiconductor device illustrated in FIG. 26 includes the transistor 200, the transistor 300, and the capacitor 100, like the semiconductor device illustrated in FIG. 20. Note that the semiconductor device illustrated in FIG. 26 is different from the semiconductor device illustrated in FIG. 20 in that the capacitor 100 is positioned over the transistor 200, the capacitor 100 is a planar capacitor, and the transistor 200 and the transistor 300 are electrically connected to each other through the conductor 247.

In the semiconductor device of one embodiment of the present invention, the transistor 200 is provided above the transistor 300, and the capacitor 100 is provided above the transistor 300 and the transistor 200. At least part of the capacitor 100 or the transistor 300 preferably overlap with the transistor 200. In that case, the area occupied by the capacitor 100, the transistor 200, and the transistor 300 in a top view can be reduced, whereby the semiconductor device of this embodiment can be miniaturized or highly integrated.

Note that as the transistor 200 and the transistor 300, the transistor 200 and the transistor 300 mentioned above can be used. Therefore, the above description can be referred to for the transistor 200, the transistor 300, and layers including them.

In the semiconductor device illustrated in FIG. 26, a wiring 2001 is electrically connected to a source of the transistor 300, and a wiring 2002 is electrically connected to a drain of the transistor 300. A wiring 2003 is electrically connected to one of a source and a drain of the transistor 200, a wiring 2004 is electrically connected to a first gate of the transistor 200, and a wiring 2006 is electrically connected to a second gate of the transistor 200. A gate of the transistor 300 and the other of the source and the drain of the transistor 200 is electrically connected to one electrode of the capacitor 100, and a wiring 2005 is electrically connected to the other electrode of the capacitor 100. Note that a node where the gate of the transistor 300, the other of the source and the drain of the transistor 200, and the one electrode of the capacitor 100 are connected to each other is hereinafter referred to as a node FG in some cases.

The semiconductor device illustrated in FIG. 26 has characteristics of being able to retain a potential of the gate of the transistor 300 (the node FG) by switching of the transistor 200; thus, writing, retention, and reading of data can be performed.

Furthermore, by arranging the semiconductor devices illustrated in FIG. 26 in a matrix, a memory cell array can be formed.

The layer including the transistor 300 has a structure similar to that of the semiconductor device illustrated in FIG. 20, and therefore the above description can be referred to for the structure below the insulator 354.

An insulator 210, the insulator 212, the insulator 214, and the insulator 216 are positioned over the insulator 354. Here, an insulator having a function of inhibiting transmission of oxygen and impurities such as hydrogen is used for the insulator 210, as in the insulator 350 or the like.

The conductor 247 is embedded in the insulator 210, the insulator 212, the insulator 214, and the insulator 216. The conductor 247 has a function as a plug or a wiring that is electrically connected to the capacitor 100, the transistor 200, or the transistor 300. For example, the conductor 247 is electrically connected to the conductor 316 functioning as the gate electrode of the transistor 300.

The conductor 245 functions as a plug or a wiring that is electrically connected to the transistor 200 or the transistor 300. For example, the conductor 245 electrically connects the conductor 242b functioning as the other of the source and the drain of the transistor 200 and the conductor 110 functioning as the one electrode of the capacitor 100.

The planar capacitor 100 is provided above the transistor 200. The capacitor 100 includes the conductor 110 functioning as a first electrode, the conductor 120 functioning as a second electrode, and the insulator 130 functioning as a dielectric. Note that the conductor 110, the conductor 120, and the insulator 130 can be those described above in Memory device 1.

The conductor 152 and the conductor 110 are provided in contact with the top surface of the conductor 245. The conductor 152 is in contact with the top surface of the conductor 245 and functions as a terminal of the transistor 200 or the transistor 300.

The conductor 152 and the conductor 110 are covered with the insulator 130, and the conductor 120 is positioned to overlap with the conductor 110 with the insulator 130 therebetween. In addition, the insulator 114 is positioned over the conductor 120 and the insulator 130.

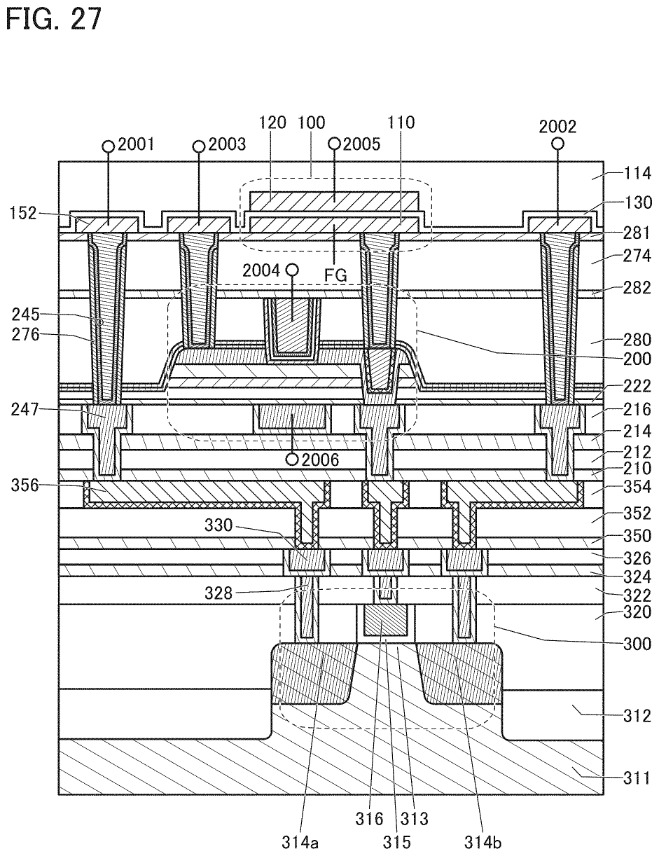

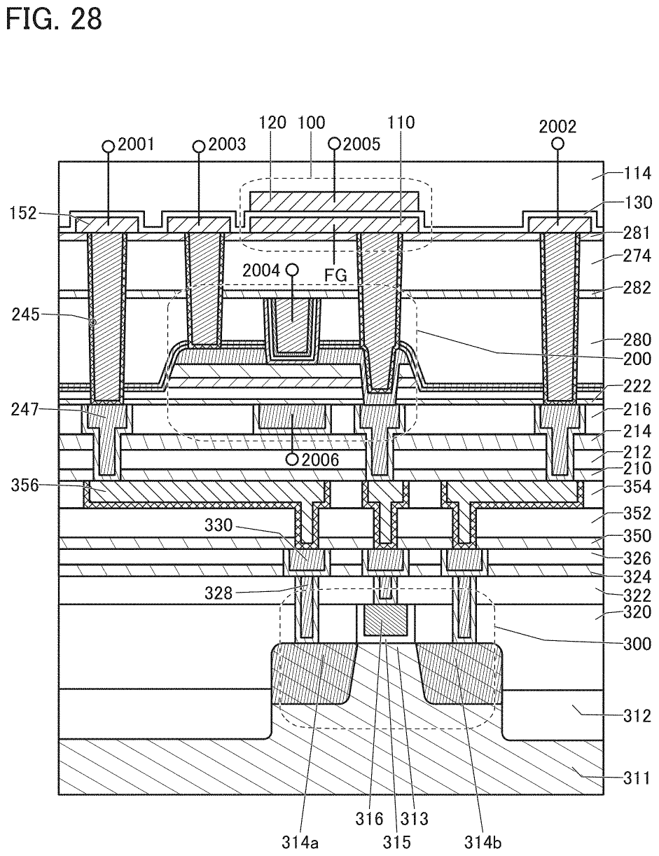

Note that although an example in which the transistor 200 illustrated in FIG. 1 is used in the semiconductor device illustrated in FIG. 26 is described, the semiconductor device described in this embodiment is not limited thereto. In the semiconductor device illustrated in FIG. 26, the transistor 200 illustrated in FIG. 12, the transistor 200 illustrated in FIG. 16, the transistor 200 illustrated in FIG. 17, or the like may be used. For example, a structure may be employed in which the transistor 200 illustrated in FIG. 12 is used as the transistor 200 of the memory device illustrated in FIG. 26 and a depression portion of the conductor 242b is filled with the conductor 244, as illustrated in FIG. 27. In that case, the conductor 245 is preferably in contact with the conductor 244. Alternatively, a structure may be employed in which, for example, the transistor 200 illustrated in FIG. 17 is used as the transistor 200 of the semiconductor device illustrated in FIG. 26 and a depression portion of the conductor 242b is filled with the conductor 245, as illustrated in FIG. 28. In that case, unlike in the structure illustrated in FIG. 26, a structure is preferably employed in which the insulator 276 is not provided on a side surface of the conductor 245. As described here, the structure of the transistor 200 can be set as appropriate.

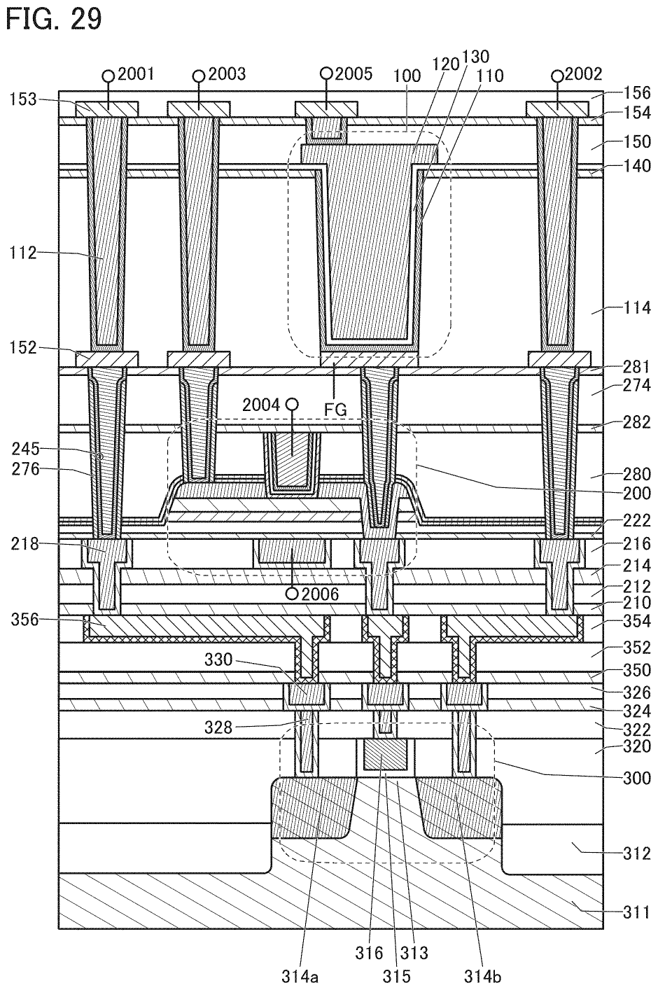

Although FIG. 26 illustrates an example in which a planar capacitor is used as the capacitor 100, the semiconductor device described in this embodiment is not limited thereto. For example, as illustrated in FIG. 29, a cylinder capacitor 100 as in FIG. 20 may be used as the capacitor 100.

Here, the description of FIG. 20 can be referred to for the details of the capacitor 100. Note that a structure is preferable in which the conductor 152 is positioned over the conductor 245 and the conductor 112 is positioned over the conductor 152 as illustrated in FIG. 29. Such a structure can make electrical connection between the conductor 245 and the conductor 112 more surely.

An insulator 154 is preferably positioned over the insulator 150. An insulator that can be used for the insulator 281 can be used for the insulator 154. A conductor 153 is provided in contact with the top surface of the conductor 112. The conductor 153 is in contact with the top surface of the conductor 112 and functions as a terminal of the capacitor 100, the transistor 200, or the transistor 300. In addition, the insulator 156 is positioned over the conductor 153 and the insulator 154.

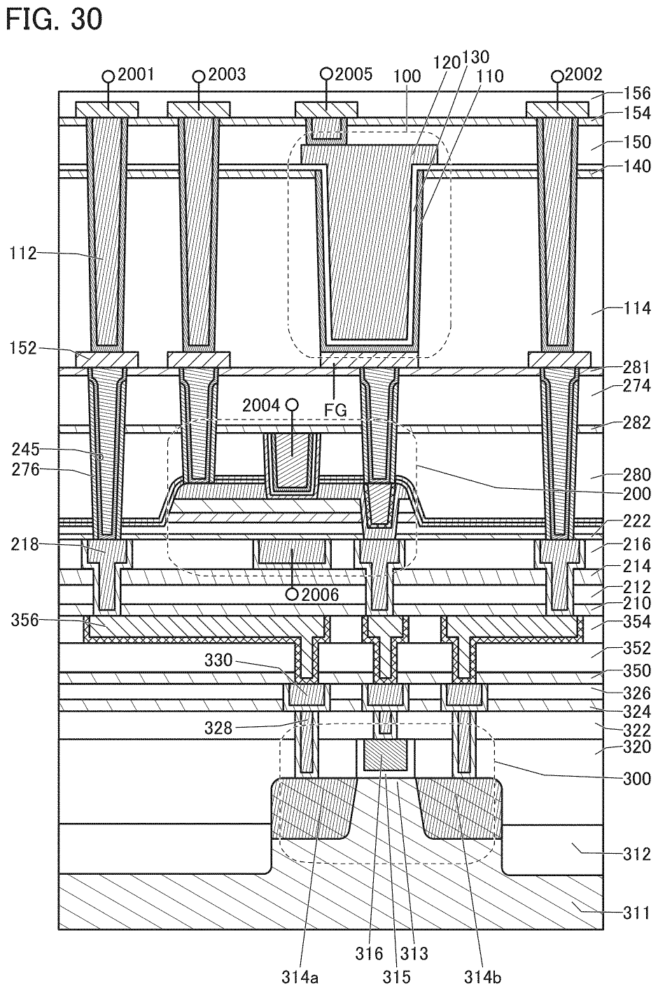

Note that although an example in which the transistor 200 illustrated in FIG. 1 is used in the semiconductor device illustrated in FIG. 29 is described, the semiconductor device described in this embodiment is not limited thereto. In the semiconductor device illustrated in FIG. 29, the transistor 200 illustrated in FIG. 12, the transistor 200 illustrated in FIG. 16, the transistor 200 illustrated in FIG. 17, or the like may be used. For example, a structure may be employed in which the transistor 200 illustrated in FIG. 12 is used as the transistor 200 of the memory device illustrated in FIG. 29 and a depression portion of the conductor 242b is filled with the conductor 244, as illustrated in FIG. 30. In that case, the conductor 245 is preferably in contact with the conductor 244. As described here, the structure of the transistor 200 can be set as appropriate.

This embodiment can be implemented in an appropriate combination with the structures described in the other embodiments and the like.

### Embodiment 3

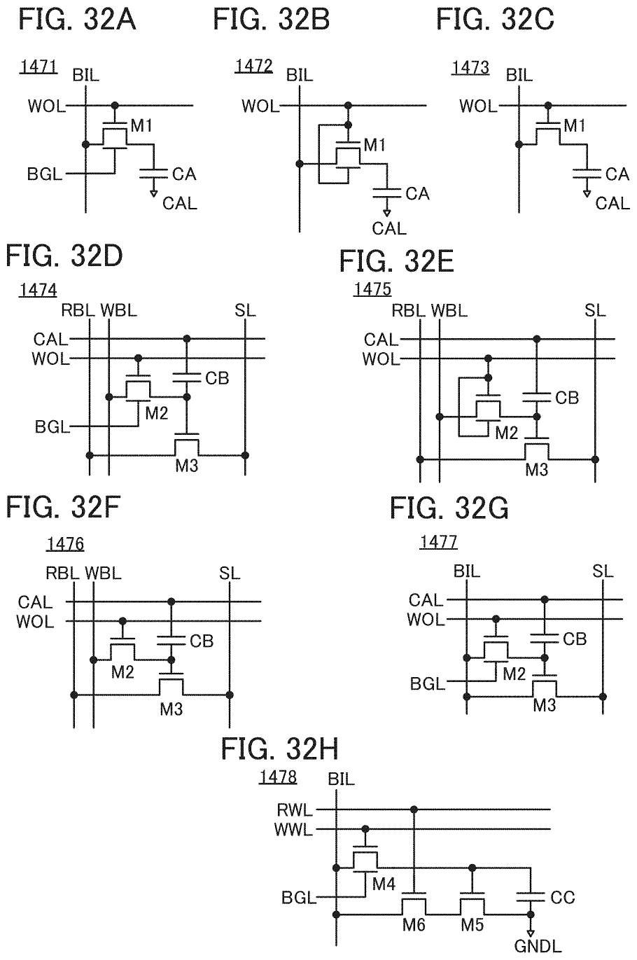

In this embodiment, a memory device of one embodiment of the present invention including a transistor in which an oxide is used for a semiconductor (hereinafter referred to as an OS transistor in some cases) and a capacitor (hereinafter, such a memory device is also referred to as an OS memory device in some cases), will be described with reference to FIG. 31 and FIG. 32. The OS memory device includes at least a capacitor and an OS transistor that controls the charging and discharging of the capacitor. Since the OS transistor has an extremely low off-state current, the OS memory device has excellent retention characteristics and thus can function as a nonvolatile memory.

### <Structure Example of Memory Device>

FIG. 31(A) illustrates a structure example of the OS memory device. A memory device 1400 includes a peripheral circuit 1411 and a memory cell array 1470. The peripheral circuit 1411 includes a row circuit 1420, a column circuit 1430, an output circuit 1440, and a control logic circuit 1460.

The column circuit 1430 includes, for example, a column decoder, a precharge circuit, a sense amplifier, a write circuit, and the like. The precharge circuit has a function of precharging wirings. The sense amplifier has a function of amplifying a data signal read from a memory cell. Note that the wirings are connected to the memory cell included in the memory cell array 1470, and will be described later in detail. The amplified data signal is output as a data signal RDATA to the outside of the memory device 1400 through the output circuit 1440. The row circuit 1420 includes, for example, a row decoder and a word line driver circuit, and can select a row to be accessed.

As power supply voltages from the outside, a low power supply voltage (VSS), a high power supply voltage (VDD) for the peripheral circuit 1411, and a high power supply voltage (VIL) for the memory cell array 1470 are supplied to the memory device 1400. Control signals (CE, WE, and RE), an address signal ADDR, and a data signal WDATA are also input to the memory device 1400 from the outside. The address signal ADDR is input to the row decoder and the column decoder, and WDATA is input to the write circuit.

The control logic circuit 1460 processes the input signals (CE, WE, and RE) input from the outside, and generates control signals for the row decoder and the column decoder. CE is a chip enable signal, WE is a write enable signal, and RE is a read enable signal. Signals processed by the control logic circuit 1460 are not limited thereto, and other control signals may be input as necessary.

The memory cell array 1470 includes a plurality of memory cells MC and a plurality of wirings arranged in a matrix. Note that the number of the wirings that connect the memory cell array 1470 to the row circuit 1420 depends on the structure of the memory cell MC, the number of the memory cells MC in a column, and the like. The number of the wirings that connect the memory cell array 1470 to the column circuit 1430 depends on the structure of the memory cell MC, the number of the memory cells MC in a row, and the like.

Note that FIG. 31(A) illustrates an example in which the peripheral circuit 1411 and the memory cell array 1470 are formed on the same plane; however, this embodiment is not limited thereto. For example, as illustrated in FIG. 31(B), the memory cell array 1470 may be provided to overlap with part of the peripheral circuit 1411. For example, the sense amplifier may be provided below the memory cell array 1470 so that they overlap with each other.

FIG. 32 illustrates configuration examples of a memory cell applicable to the memory cell MC.

### [DOSRAM]

FIGS. 32(A) to 32(C) each illustrate a circuit configuration example of a memory cell of a DRAM. In this specification and the like, a DRAM using a memory cell including one OS transistor and one capacitor is referred to as DOSRAM (Dynamic Oxide Semiconductor Random Access Memory) in some cases. A memory cell 1471 illustrated in FIG. 32(A) includes a transistor M1 and a capacitor CA. Note that the transistor M1 includes a gate (also referred to as a front gate in some cases) and a back gate.

A first terminal of the transistor M1 is connected to a first terminal of the capacitor CA. A second terminal of the transistor M1 is connected to a wiring BIL. The gate of the transistor M1 is connected to a wiring WOL. The back gate of the transistor M1 is connected to a wiring BGL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. In the time of data writing and data reading, a low-level potential is preferably applied to the wiring CAL. The wiring BGL functions as a wiring for applying a potential to the back gate of the transistor M1. Applying a given potential to the wiring BGL can increase or decrease the threshold voltage of the transistor M1.

Here, the memory cell 1471 illustrated in FIG. 32(A) corresponds to the memory device illustrated in FIG. 20. That is, the transistor M1, the capacitor CA, the wiring BIL, the wiring WOL, the wiring BGL, and the wiring CAL correspond to the transistor 200, the capacitor 100, the wiring 1003, the wiring 1004, the wiring 1006, and the wiring 1005, respectively. Note that the transistor 300 illustrated in FIG. 20 corresponds to a transistor provided in the peripheral circuit 1411 of the memory device 1400 illustrated in FIG. 31(B).

The memory cell MC is not limited to the memory cell 1471, and the circuit configuration can be changed. For example, as in a memory cell 1472 illustrated in FIG. 32(B), the back gate of the transistor M1 may be connected not to the wiring BGL but to the wiring WOL in the memory cell MC. Alternatively, for example, the memory cell MC may be a memory cell including a single-gate transistor, that is, the transistor M1 not including a back gate, as in a memory cell 1473 illustrated in FIG. 32(C).

In the case where the semiconductor device described in any of the above embodiments is used in the memory cell 1471 and the like, the transistor 200 can be used as the transistor M1, and the capacitor 100 can be used as the capacitor CA. When an OS transistor is used as the transistor M1, the leakage current of the transistor M1 can be extremely low. That is, with the use of the transistor M1, written data can be retained for a long time, and thus the frequency of the refresh operation for the memory cell can be decreased. In addition, refresh operation of the memory cell can be unnecessary. In addition, since the transistor M1 has an extremely low leakage current, multi-level data or analog data can be retained in the memory cell 1471, the memory cell 1472, and the memory cell 1473.

In the DOSRAM, when the sense amplifier is provided below the memory cell array 1470 so that they overlap with each other as described above, the bit line can be shortened. Thus, the bit line capacitance can be small, and the storage capacitance of the memory cell can be reduced.

### [NOSRAM]

FIGS. 32(D) to 32(H) each illustrate a circuit configuration example of a gain-cell memory cell including two transistors and one capacitor. A memory cell 1474 illustrated in FIG. 32(D) includes a transistor M2, a transistor M3, and a capacitor CB. Note that the transistor M2 includes a front gate (simply referred to as a gate in some cases) and a back gate. In this specification and the like, a memory device including a gain-cell memory cell using an OS transistor as the transistor M2 is referred to as NOSRAM (Nonvolatile Oxide Semiconductor RAM) in some cases.

A first terminal of the transistor M2 is connected to a first terminal of the capacitor CB. A second terminal of the transistor M2 is connected to a wiring WBL. A gate of the transistor M2 is connected to the wiring WOL. A back gate of the transistor M2 is connected to the wiring BGL. A second terminal of the capacitor CB is connected to the wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In the time of data writing, data retaining, and data reading, a low-level potential is preferably applied to the wiring CAL. The wiring BGL functions as a wiring for applying a potential to the back gate of the transistor M2. By application of a given potential to the wiring BGL, the threshold voltage of the transistor M2 can be increased or decreased.

Here, the memory cell 1474 illustrated in FIG. 32(D) corresponds to the memory device illustrated in FIG. 26. That is, the transistor M2, the capacitor CB, the transistor M3, the wiring WBL, the wiring WOL, the wiring BGL, the wiring CAL, the wiring RBL, and the wiring SL correspond to the transistor 200, the capacitor 100, the transistor 300, the wiring 2003, the wiring 2004, the wiring 2006, the wiring 2005, the wiring 2002, and the wiring 2001, respectively.

The memory cell MC is not limited to the memory cell 1474, and the circuit configuration can be changed as appropriate. For example, as in a memory cell 1475 illustrated in FIG. 32(E), the back gate of the transistor M2 may be connected not to the wiring BGL but to the wiring WOL in the memory cell MC. Alternatively, for example, the memory cell MC may be a memory cell including as single-gate transistor, that is, the transistor M2 not including a back gate, as in a memory cell 1476 illustrated in FIG. 32(F). Alternatively, for example, in the memory cell MC, the wiring WBL and the wiring RBL may be combined into one wiring BIL, as in a memory cell 1477 illustrated in FIG. 32(G).

In the case where the semiconductor device described in any of the above embodiments is used in the memory cell 1474 and the like, the transistor 200 can be used as the transistor M2, the transistor 300 can be used as the transistor M3, and the capacitor 100 can be used as the capacitor CB. When an OS transistor is used as the transistor M2, the leakage current of the transistor M2 can be extremely low. That is, with the use of the transistor M2, written data can be retained for a long time, and thus the frequency of the refresh operation for the memory cell can be decreased. In addition, refresh operation of the memory cell can be unnecessary. In addition, since the transistor M2 has an extremely low leakage current, multi-level data or analog data can be retained in the memory cell 1474. The same applies to the memory cells 1475 to 1477.

Note that the transistor M3 may be a transistor containing silicon in a channel formation region (hereinafter, also referred to as a Si transistor in some cases). The conductivity type of the Si transistor may be of either an n-channel type or a p-channel type. The Si transistor has higher field-effect mobility than the OS transistor in some cases. Therefore, a Si transistor may be used as the transistor M3 functioning as a reading transistor. Furthermore, the transistor M2 can be provided to be stacked over the transistor M3 when a Si transistor is used as the transistor M3; therefore, the area occupied by the memory cell can be reduced, leading to high integration of the memory device.

Alternatively, the transistor M3 may be an OS transistor. When an OS transistor is used as each of the transistors M2 and M3, the circuit of the memory cell array 1470 can be formed using only n-channel transistors.

FIG. 32(H) illustrates an example of a gain-cell memory cell including three transistors and one capacitor. A memory cell 1478 illustrated in FIG. 32(H) includes transistors M4 to M6 and a capacitor CC. The capacitor CC is provided as appropriate. The memory cell 1478 is electrically connected to the wiring BIL, a wiring RWL, a wiring WWL, the wiring BGL, and a wiring GNDL. The wiring GNDL is a wiring for supplying a low-level potential. Note that the memory cell 1478 may be electrically connected to the wirings RBL and WBL instead of the wiring BIL.

The transistor M4 is an OS transistor including a back gate that is electrically connected to the wiring BGL. Note that the back gate and the gate of the transistor M4 may be electrically connected to each other. Alternatively, the transistor M4 does not necessarily include the back gate.

Note that each of the transistors M5 and M6 may be an n-channel Si transistor or a p-channel Si transistor. Alternatively, the transistors M4 to M6 may be OS transistors, in which case the circuit of the memory cell array 1470 can be formed using only n-channel transistors.

In the case where the semiconductor device described in any of the above embodiments is used in the memory cell 1478, the transistor 200 can be used as the transistor M4, the transistor 300 can be used as the transistors M5 and M6, and the capacitor 100 can be used as the capacitor CC. When an OS transistor is used as the transistor M4, the leakage current of the transistor M4 can be extremely low.

Note that the structures of the peripheral circuit 1411, the memory cell array 1470, and the like described in this embodiment are not limited to the above. Positions and functions of these circuits, wirings connected to the circuits, circuit elements, and the like can be changed, deleted, or added as needed.

The structure described in this embodiment can be used in an appropriate combination with the structures described in the other embodiments and the like.

### Embodiment 4

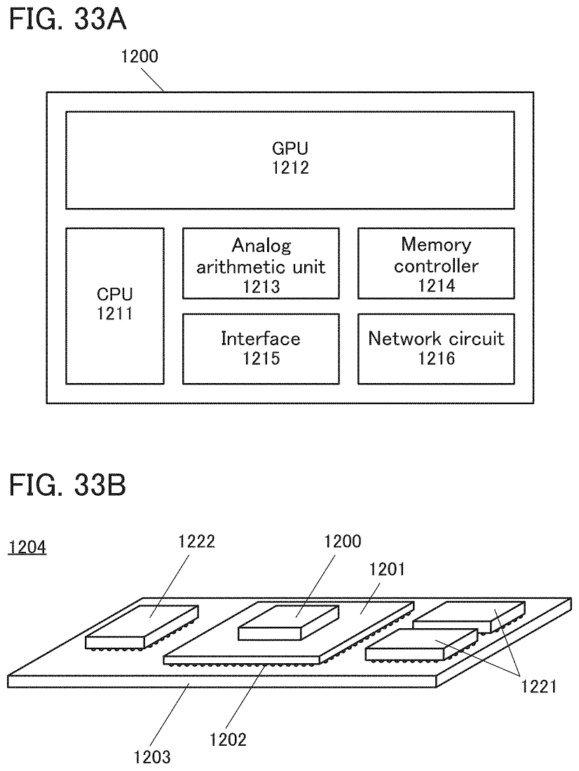

In this embodiment, an example of a chip 1200 on which the semiconductor device of the present invention is mounted will be described with reference to FIG. 33. A plurality of circuits (systems) are mounted on the chip 1200. The technique for integrating a plurality of circuits (systems) on one chip as described above is referred to as system on chip (SoC) in some cases.

As illustrated in FIG. 33(A), the chip 1200 includes a CPU 1211, a GPU (Graphics Processing Unit) 1212, one or more of analog arithmetic units 1213, one or more of memory controllers 1214, one or more of interfaces 1215, one or more of network circuits 1216, and the like.

A bump (not illustrated) is provided on the chip 1200, and as illustrated in FIG. 33(B), the chip 1200 is connected to a first surface of a printed circuit board (PCB) 1201. A plurality of bumps 1202 are provided on the rear side of the first surface of the PCB 1201, and the PCB 1201 is connected to a motherboard 1203.

A memory device such as a DRAM 1221 or a flash memory 1222 may be provided over the motherboard 1203. For example, the DOSRAM described in the above embodiment can be used as the DRAM 1221. For example, the NOSRAM described in the above embodiment can be used as the flash memory 1222.

The CPU 1211 preferably includes a plurality of CPU cores. Furthermore, the GPU 1212 preferably includes a plurality of GPU cores. The CPU 1211 and the GPU 1212 may each include a memory for storing data temporarily. Alternatively, a common memory for the CPU 1211 and the GPU 1212 may be provided in the chip 1200. The NOSRAM or the DOSRAM described above can be used as the memory. The GPU 1212 is suitable for parallel computation of a number of data and thus can be used for image processing or product-sum operation. When an image processing circuit or a product-sum operation circuit including an oxide semiconductor of the present invention is provided in the GPU 1212, image processing and product-sum operation can be performed with low power consumption.

In addition, since the CPU 1211 and the GPU 1212 are provided in the same chip, a wiring between the CPU 1211 and the GPU 1212 can be shortened; accordingly, the data transfer from the CPU 1211 to the GPU 1212, the data transfer between the memories included in the CPU 1211 and the GPU 1212, and the transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the analog arithmetic unit 1213 may include the above-described product-sum operation circuit.

The memory controller 1214 includes a circuit functioning as a controller of the DRAM 1221 and a circuit functioning as the interface of the flash memory 1222.

The interface 1215 includes an interface circuit for connection with an external connection device such as a display device, a speaker, a microphone, a camera, or a controller. Examples of the controller include a mouse, a keyboard, and a game controller. As such an interface, USB (Universal Serial Bus), HDMI (registered trademark) (High-Definition Multimedia Interface), or the like can be used.

The network circuit 1216 includes a network circuit such as a LAN (Local Area Network). Furthermore, a circuit for network security may be included.

The circuits (systems) can be formed in the chip 1200 in the same manufacturing process. Therefore, even when the number of circuits needed for the chip 1200 is increased, there is no need to increase the number of steps in the manufacturing process; thus, the chip 1200 can be manufactured at low cost.

The motherboard 1203 provided with the PCB 1201 on which the chip 1200 including the GPU 1212 is mounted, the DRAM 1221, and the flash memory 1222 can be referred to as a GPU module 1204.

The GPU module 1204 includes the chip 1200 formed using the SoC technology, and thus can have a small size. Furthermore, the GPU module 1204 is excellent in image processing, and thus is suitably used in a portable electronic device such as a smartphone, a tablet terminal, a laptop PC, or a portable (mobile) game console. Furthermore, the product-sum operation circuit using the GPU 1212 can implement an arithmetic operation such as a deep neural network (DNN), a convolutional neural network (CNN), a recurrent neural network (RNN), an autoencoder, a deep Boltzmann machine (DBM), or a deep belief network (DBN); thus, the chip 1200 can be used as an AI chip or the GPU module 1204 can be used as an AI system module.

The structure described in this embodiment can be used in an appropriate combination with the structures described in the other embodiments.

### Embodiment 5

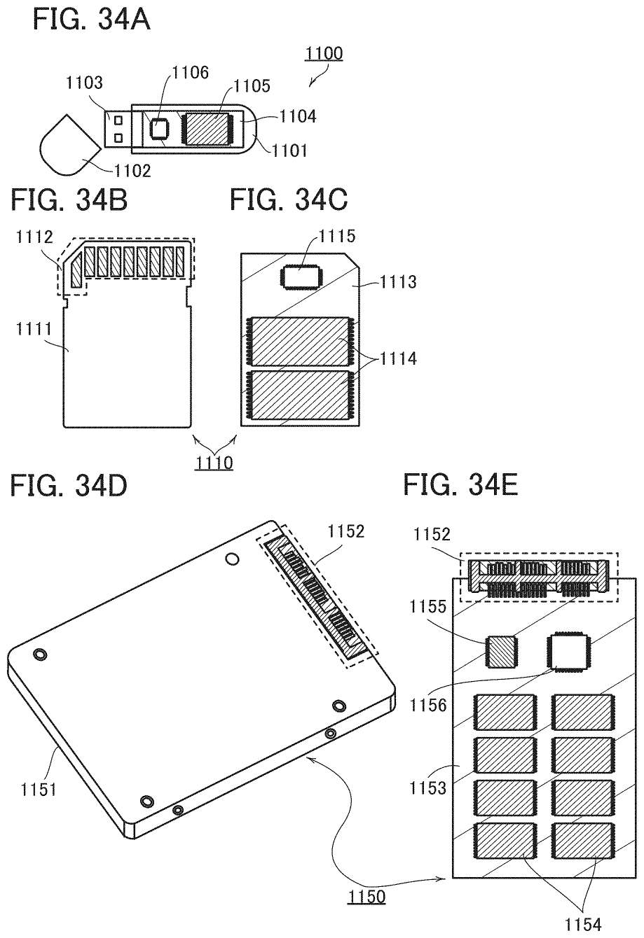

In this embodiment, application examples of the memory device using the semiconductor device described in the above embodiment will be described. The semiconductor device described in the above embodiment can be applied to, for example, memory devices of a variety of electronic devices (e.g., information terminals, computers, smartphones, e-book readers, digital cameras (including video cameras), video recording/reproducing devices, and navigation systems). Here, the computers refer not only to tablet computers, notebook computers, and desktop computers, but also to large computers such as server systems. Alternatively, the semiconductor device described in the above embodiment is applied to removable memory devices such as memory cards (e.g., SD cards), USB memories, and SSDs (solid state drives). FIG. 34 schematically illustrates some structure examples of removable memory devices. The semiconductor device described in the above embodiment is processed into a packaged memory chip and used in a variety of storage devices and removable memories, for example.

FIG. 34(A) is a schematic view of a USB memory. A USB memory 1100 includes a housing 1101, a cap 1102, a USB connector 1103, and a substrate 1104. The substrate 1104 is held in the housing 1101. For example, a memory chip 1105 and a controller chip 1106 are attached to the substrate 1104. The semiconductor device described in the above embodiment can be incorporated in the memory chip 1105 or the like on the substrate 1104.

FIG. 34(B) is a schematic external view of an SD card, and FIG. 34(C) is a schematic view of the internal structure of the SD card. An SD card 1110 includes a housing 1111, a connector 1112, and a substrate 1113. The substrate 1113 is held in the housing 1111. For example, a memory chip 1114 and a controller chip 1115 are attached to the substrate 1113. When the memory chip 1114 is also provided on the rear surface side of the substrate 1113, the capacity of the SD card 1110 can be increased. In addition, a wireless chip with a radio communication function may be provided on the substrate 1113. With this, data can be read from and written in the memory chip 1114 by radio communication between a host device and the SD card 1110. The semiconductor device described in the above embodiment can be incorporated in the memory chip 1114 or the like on the substrate 1113.

FIG. 34(D) is a schematic external view of an SSD, and FIG. 34(E) is a schematic view of the internal structure of the SSD. An SSD 1150 includes a housing 1151, a connector 1152, and a substrate 1153. The substrate 1153 is held in the housing 1151. For example, a memory chip 1154, a memory chip 1155, and a controller chip 1156 are attached to the substrate 1153. The memory chip 1155 is a work memory for the controller chip 1156, and a DOSRAM chip may be used, for example. When the memory chip 1154 is also provided on the rear surface side of the substrate 1153, the capacity of the SSD 1150 can be increased. The semiconductor device described in the above embodiment can be incorporated in the memory chip 1154 or the like on the substrate 1153.

This embodiment can be implemented in an appropriate combination with the structures described in the other embodiments and the like.

### Embodiment 6

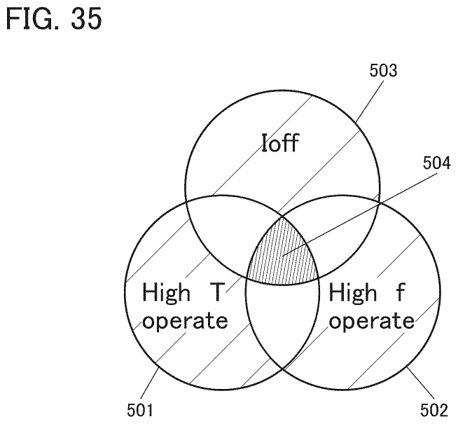

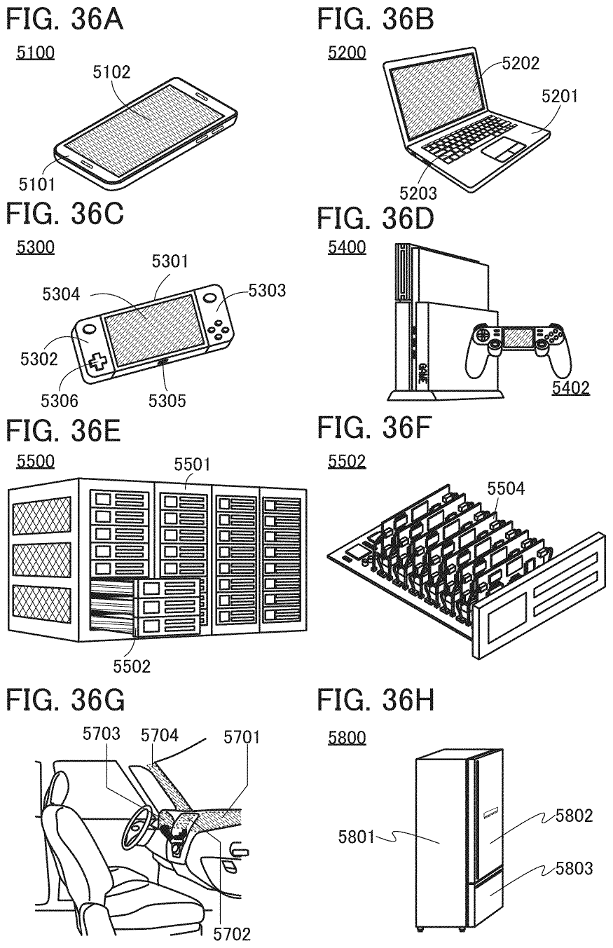

In this embodiment, a product image and specific examples of electronic devices that can be used for the semiconductor device of one embodiment of the present invention are described with reference to FIG. 35 and FIG. 36.

First, FIG. 35 illustrates a product image applicable to the semiconductor device of one embodiment of the present invention. A region 501 illustrated in FIG. 35 represents high temperature characteristics (High T operate), a region 502 represents high frequency characteristics (High f operate), a region 503 represents low off characteristics (Ioff), and a region 504 represents a region where the region 501, the region 502, and the region 503 overlap one another.

Note that when the region 501 is intended to be satisfied, it can be roughly satisfied by using a carbide or a nitride such as silicon carbide or gallium nitride for a channel formation region of a semiconductor device. When the region 502 is intended to be satisfied, it can be roughly satisfied by using a silicide such as single crystal silicon or crystalline silicon for a channel formation region of a semiconductor device. When the region 503 is intended to be satisfied, it can be roughly satisfied by using an oxide semiconductor or a metal oxide for a channel formation region of a semiconductor device.

The semiconductor device of one embodiment of the present invention can be favorably used for a product in the range represented by the region 504, for example.

A conventional product has difficulty in satisfying all of the region 501, the region 502, and the region 503. However, the semiconductor device of one embodiment of the present invention includes a crystalline OS in a channel formation region. In the case where the crystalline OS is included in the channel formation region, a semiconductor device and an electronic device which satisfy high temperature characteristics, high frequency characteristics, and low off characteristics can be provided.

Note that examples of a product in the range represented by the region 504 are an electronic device including a low-power consumption and high-performance CPU, an in-car electronic device required to have high reliability in a high-temperature environment, and the like.

Specifically, the semiconductor device of one embodiment of the present invention can be used for a processor such as a CPU and a GPU or a chip. FIG. 36 illustrates specific examples of electronic devices including a processor such as a CPU and a GPU or a chip of one embodiment of the present invention.

### <Electronic Device and System>

The GPU or the chip of one embodiment of the present invention can be incorporated into a variety of electronic devices. Examples of electronic devices include a digital camera, a digital video camera, a digital photo frame, an e-book reader, a mobile phone, a portable game machine, a portable information terminal, and an audio reproducing device in addition to electronic devices provided with a relatively large screen, such as a television device, a monitor for a desktop or notebook information terminal or the like, digital signage, and a large game machine like a pachinko machine. When the GPU or the chip of one embodiment of the present invention is provided in an electronic device, the electronic device can include artificial intelligence.

The electronic device of one embodiment of the present invention may include an antenna. When a signal is received by the antenna, the electronic device can display a video, data, or the like on the display portion. When the electronic device includes the antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radioactive rays, flow rate, humidity, gradient, oscillation, a smell, or infrared rays).

The electronic device of one embodiment of the present invention can have a variety of functions. For example, the electronic device can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium. FIG. 36 illustrates examples of electronic devices.

### [Information Terminal]

FIG. 36(A) illustrates a mobile phone (smartphone), which is a type of information terminal. An information terminal 5100 includes a housing 5101 and a display portion 5102. As input interfaces, a touch panel is provided in the display portion 5102 and a button is provided in the housing 5101.

The information terminal 5100 can execute an application utilizing artificial intelligence, with the use of the chip of one embodiment of the present invention. Examples of the application utilizing artificial intelligence include an application for interpreting a conversation and displaying its content on the display portion 5102; an application for recognizing letters, figures, and the like input to the touch panel of the display portion 5102 by a user and displaying them on the display portion 5102; and an application for biometric authentication using fingerprints, voice prints, or the like.

FIG. 36(B) illustrates a notebook information terminal 5200. The notebook information terminal 5200 includes a main body 5201 of the information terminal, a display portion 5202, and a keyboard 5203.

As the information terminal 5100 described above, the notebook information terminal 5200 can execute an application utilizing artificial intelligence, with the use of the chip of one embodiment of the present invention. Examples of the application utilizing artificial intelligence include design-support software, text correction software, and software for automatic menu generation. Furthermore, with the use of the notebook information terminal 5200, novel artificial intelligence can be developed.

Note that although the smartphone and the notebook information terminal are respectively illustrated in FIG. 36(A) and FIG. 36(B) as examples of the electronic device, one embodiment of the present invention can be applied to an information terminal other than the smartphone and the notebook information terminal. Examples of an information terminal other than the smartphone and the notebook information terminal include a PDA (Personal Digital Assistant), a desktop information terminal, and a workstation.

### [Game Machine]

FIG. 36(C) illustrates a portable game machine 5300, which is an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not illustrated), a video to be output to the display portion 5304 can be output to another video device (not illustrated). In that case, the housing 5302 and the housing 5303 can each function as an operating unit. Thus, a plurality of players can play a game at the same time. The chip described in the above embodiment can be incorporated into a chip provided on a substrate in the housing 5301, the housing 5302, and the housing 5303, for example.

FIG. 36(D) illustrates a stationary game machine 5400, which is an example of a game machine. A controller 5402 is connected to the stationary game machine 5400 with or without a wire.

Using the GPU or the chip of one embodiment of the present invention in a game machine such as the portable game machine 5300 and the stationary game machine 5400 can achieve a low-power-consumption game machine. Moreover, heat generation from a circuit can be reduced owing to low power consumption; thus, the influence of heat generation on the circuit, the peripheral circuit, and the module can be reduced.

Furthermore, when the GPU or the chip of one embodiment of the present invention is used in the portable game machine 5300, the portable game machine 5300 including artificial intelligence can be obtained.

In general, the progress of a game, the actions and words of game characters, and expressions of a phenomenon and the like in the game are determined by the program in the game; however, the use of artificial intelligence in the portable game machine 5300 enables expressions not limited by the game program. For example, expressions are possible in which questions posed by the player, the progress of the game, time, and the actions and words of game characters are changed.

When a game requiring a plurality of players is played on the portable game machine 5300, the artificial intelligence can create a virtual game player; thus, the game can be played alone with the game player created by the artificial intelligence as an opponent.

Although the portable game machine and the stationary game machine are respectively illustrated in FIG. 36(C) and FIG. 36(D) as examples of a game machine, the game machine using the GPU or the chip of one embodiment of the present invention is not limited thereto. Examples of the game machine using the GPU or the chip of one embodiment of the present invention include an arcade game machine installed in entertainment facilities (a game center, an amusement park, and the like) and a throwing machine for batting practice installed in sports facilities.

### [Large Computer]

The GPU or the chip of one embodiment of the present invention can be used in a large computer.

FIG. 36(E) illustrates a supercomputer 5500 as an example of a large computer. FIG. 36(F) illustrates a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504, and the GPU or the chip described in the above embodiment can be mounted on the substrates.

The supercomputer 5500 is a large computer mainly used for scientific computation. In scientific computation, an enormous amount of arithmetic operation needs to be processed at a high speed; hence, power consumption is high and chips generate a large amount of heat. Using the GPU or the chip of one embodiment of the present invention in the supercomputer 5500 can achieve a low-power-consumption supercomputer. Moreover, heat generation from a circuit can be reduced owing to low power consumption; thus, the influence of heat generation on the circuit, the peripheral circuit, and the module can be reduced.

Although a supercomputer is illustrated as an example of a large computer in FIG. 36(E) and FIG. 36(F), a large computer using the GPU or the chip of one embodiment of the present invention is not limited thereto. Examples of a large computer using the GPU or the chip of one embodiment of the present invention include a computer that provides service (a server) and a large general-purpose computer (a mainframe).

### [Moving Vehicle]

The GPU or the chip of one embodiment of the present invention can be used in an automobile, which is a moving vehicle, and around a driver's seat in the automobile.

FIG. 36(G) illustrates the periphery of a windshield inside an automobile, which is an example of a moving vehicle. FIG. 36(G) illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying a speedometer, a tachometer, a mileage, a fuel meter, a gearshift indicator, air-condition setting, and the like. The content, layout, or the like of the display on the display panels can be changed as appropriate to suit the user's preference, so that the design can be improved. The display panel 5701 to the display panel 5703 can also be used as lighting devices.

The display panel 5704 can compensate for the view obstructed by the pillar (a blind spot) by showing an image taken by an imaging device (not illustrated) provided for the automobile. That is, displaying an image taken by the imaging device provided on the outside of the automobile leads to compensation for the blind spot and enhancement of safety. In addition, showing an image for compensating for the area that cannot be seen makes it possible to confirm the safety more naturally and comfortably. The display panel 5704 can also be used as a lighting device.

Since the GPU or the chip of one embodiment of the present invention can be used as a component of artificial intelligence, the chip can be used in an automatic driving system of the automobile, for example. The chip can also be used for a system for navigation, risk prediction, or the like. The display panel 5701 to the display panel 5704 may display information regarding navigation, risk prediction, or the like.

Although an automobile is described above as an example of a moving vehicle, a moving vehicle is not limited to an automobile. Examples of a moving vehicle include a train, a monorail train, a ship, and a flying object (a helicopter, an unmanned aircraft (a drone), an airplane, and a rocket), and these moving vehicles can include a system utilizing artificial intelligence when equipped with the chip of one embodiment of the present invention.

### [Electrical Appliance]

FIG. 36(H) illustrates an electric refrigerator-freezer 5800, which is an example of an electrical appliance. The electric refrigerator-freezer 5800 includes a housing 5801, a refrigerator door 5802, a freezer door 5803, and the like.

When the chip of one embodiment of the present invention is used in the electric refrigerator-freezer 5800, the electric refrigerator-freezer 5800 including artificial intelligence can be obtained. Utilizing the artificial intelligence enables the electric refrigerator-freezer 5800 to have a function of automatically making a menu based on foods stored in the electric refrigerator-freezer 5800, expiration dates of the foods, or the like, a function of automatically adjusting the temperature to be appropriate for the foods stored in the electric refrigerator-freezer 5800, and the like.

Although the electric refrigerator-freezer is described as an example of an electrical appliance, other examples of an electrical appliance include a vacuum cleaner, a microwave oven, an electronic oven, a rice cooker, a water heater, an IH cooker, a water server, a heating-cooling combination appliance such as an air conditioner, a washing machine, a drying machine, and an audio visual appliance.

The electronic devices, the functions of the electronic devices, application examples of artificial intelligence and its effects, and the like described in this embodiment can be combined as appropriate with the description of another electronic device.

This embodiment can be implemented in an appropriate combination with the structures described in the other embodiments and the like.

### REFERENCE NUMERALS

200: transistor, 205: conductor, 210: insulator, 212: insulator, 214: insulator, 216: insulator, 222: insulator, 224: insulator, 230: oxide, 231: region, 232: region, 234: region, 240: conductor, 241: insulator, 242: conductor, 243: oxide, 245: conductor, 246: conductor, 247: conductor, 248: opening, 249: region, 250: insulator, 252: mask, 256: insulator, 260: conductor, 274: insulator, 276: insulator, 280: insulator, 281: insulator, 282: insulator.

1. A semiconductor device comprising:
a first conductor;
a second conductor;
a third conductor;
a fourth conductor;
a first insulator;
a second insulator; and
a first oxide,
wherein the first insulator is over the first conductor,
wherein the first oxide is over the first insulator,
wherein a first opening that reaches the first conductor is provided in the first insulator and the first oxide,
wherein the second conductor and the third conductor isolated from each other are over the first oxide,
wherein at least part of the third conductor overlaps with the first opening and is in contact with a top surface of the first conductor,
wherein the second insulator is over the first oxide, and
wherein the fourth conductor is over the second insulator.

2. A semiconductor device comprising:
a first conductor;
a second conductor;
a third conductor;
a fourth conductor;
a fifth conductor;
a first insulator;
a second insulator; and
a first oxide,
wherein the first insulator is over the first conductor,
wherein the first oxide is over the first insulator,
wherein a first opening that reaches the first conductor is provided in the first insulator and the first oxide,
wherein the second conductor and the third conductor isolated from each other are over the first oxide,
wherein at least part of the third conductor overlaps with the first opening and is in contact with a top surface of the first conductor,
wherein the second insulator is over the first oxide,
wherein the fourth conductor is over the second insulator, and
wherein the fifth conductor is over the third conductor so as to at least partly overlap with the first opening and the first conductor.

3. The semiconductor device according to claim 2,
wherein a top surface of the fifth conductor is substantially level with a top surface of the third conductor.

4. The semiconductor device according to claim 2,
wherein the fifth conductor is a stacked-layer film of titanium nitride and tungsten over the titanium nitride.

5. The semiconductor device according to claim 1, further comprising:
a second oxide between the first oxide and the second insulator;
a third insulator over the first insulator, the second conductor, and the third conductor; and
a fourth insulator in contact with a top surface of the third insulator, a top surface of the second oxide, a top surface of the second insulator, and a top surface of the fourth conductor,
wherein the second oxide, the second insulator, and the fourth conductor are between the second conductor and the third conductor.

6. The semiconductor device according to claim 5, further comprising:
a fifth insulator between the third insulator and the second conductor and between the third insulator and the third conductor.

7. The semiconductor device according to claim 1, further comprising:
a sixth conductor below the first insulator so as to at least partly overlap with the fourth conductor.

8. The semiconductor device according to claim 1,
wherein the third conductor is in contact with a side surface of the first oxide in the first opening.

9. The semiconductor device according to claim 8,
wherein a thickness of the third conductor in a portion in contact with the side surface of the first oxide is smaller than a thickness of the third conductor in a portion in contact with a top surface of the first oxide.

10. The semiconductor device according to claim 1,
wherein the first oxide comprises In, an element M, and Zn,
wherein the element M is Al, Ga, Y, or Sn.

11. The semiconductor device according to claim 1,
wherein a capacitor is provided below the first conductor, and
wherein one electrode of the capacitor is electrically connected to the first conductor.

12. The semiconductor device according to claim 11,
wherein a transistor formed in a silicon substrate is provided below the capacitor.

13. A method for manufacturing a semiconductor device comprising a first conductor to a fourth conductor, a first insulator to a third insulator, and a first oxide, comprising:
forming the first conductor;
depositing the first insulator and a first oxide film over the first conductor;
forming a first opening that reaches the first conductor in the first insulator and the first oxide film;
depositing a first conductive film over the first oxide film;
processing the first oxide film and the first conductive film into island shapes to form the first oxide and an island-shaped first conductive film;
depositing the third insulator over the island-shaped first conductive film;
forming a second opening that reaches the island-shaped first conductive film in the third insulator;
removing a region of the island-shaped first conductive film overlapping with the second opening to form the second conductor and the third conductor;
depositing a first insulating film and a third conductive film over the first oxide and the third insulator; and
removing part of the first insulating film and part of the third conductive film until a top surface of the third insulator is exposed to form the second insulator and the fourth conductor.

14. A method for manufacturing a semiconductor device comprising a first conductor to a fifth conductor, a first insulator to a third insulator, and a first oxide, comprising:
forming the first conductor;
depositing the first insulator and a first oxide film over the first conductor;
forming a first opening that reaches the first conductor in the first insulator and the first oxide film;
depositing a first conductive film over the first oxide film by a sputtering method;
depositing a second conductive film over the first conductive film by an ALD method or a CVD method;
removing part of the second conductive film until a top surface of the first conductive film is exposed to form the fifth conductor;
processing the first oxide film and the first conductive film into island shapes to form the first oxide and an island-shaped first conductive film;
depositing the third insulator over the first insulator, the first oxide, and the island-shaped first conductive film;
forming a second opening that reaches the island-shaped first conductive film in the third insulator;
removing a region of the island-shaped first conductive film overlapping with the second opening to form the second conductor and the third conductor;
depositing a first insulating film and a third conductive film over the third insulator; and
removing part of the first insulating film and part of the third conductive film until a top surface of the third insulator is exposed to form the second insulator and the fourth conductor.

15. The method for manufacturing a semiconductor device according to claim 14,
wherein the second conductive film is formed by depositing titanium nitride by the ALD method and then depositing tungsten by the CVD method.

16. The method for manufacturing a semiconductor device according to claim 14,
wherein dry etching treatment is performed and then CMP treatment is performed when the part of the second conductive film is removed.

17. The method for manufacturing a semiconductor device according to claim 14,
wherein a second oxide film is deposited in the step of depositing the first insulating film and the third conductive film, and
wherein part of the second oxide film is removed in the step of removing the part of the first insulating film and the part of the third conductive film to form a second oxide.
